(19) United States
(12) Patent Application Publication
(10) Pub. No.: US 2009/0115028 A1
(43) Pub. Date: May 7, 2009

(54) METHOD FOR MANUFACTURING SEMICONDUCTOR SUBSTRATE, SEMICONDUCTOR DEVICE AND ELECTRONIC DEVICE

(75) Inventors: Akihisa SHIMOMURA, Isehara (JP); Fumito ISAKA, Zama (JP); Yoji NAGANO, Atsugi (JP); Junpei MOMO, Sagamihara (JP)

Correspondence Address: ERIC ROBINSON, PMB 955, 21010 SOUTHBANK ST., POTOMAC FALLS, VA, 20165, US

(73) Assignee: SEMICONDUCTOR ENERGY LABORATORY CO., LTD., Atsugi-shi (JP)

(21) Appl. No.: 12/246,569

(22) Filed: Oct. 7, 2008

(30) Foreign Application Priority Data
Nov. 1, 2007 (JP) 2007-285559

(51) Int. Cl. H01L 21/762; H01L 29/06

(52) U.S. Cl. 257/623; 438/458; 257/E21.568; 257/E29.005

(57) ABSTRACT

A semiconductor substrate including a single crystal semiconductor layer with a buffer layer interposed therebetween is manufactured. A semiconductor substrate is doped with hydrogen to form a damaged layer containing a large amount of hydrogen. After the single crystal semiconductor substrate and a supporting substrate are bonded, the semiconductor substrate is heated so that the single crystal semiconductor substrate is separated along a separation plane. The single crystal semiconductor layer is irradiated with a laser beam from the single crystal semiconductor layer side to melt a region in the depth direction from the surface of the laser-irradiated region of the single crystal semiconductor layer. Recrystallization progresses based on the plane orientation of the single crystal semiconductor layer which is solid without being melted; therefore, crystallinity of the single crystal semiconductor layer is recovered and the surface of the single crystal semiconductor layer is planarized.

### BACKGROUND OF THE INVENTION

1. Field of the Invention

The present invention relates to a method for manufacturing a semiconductor substrate over which a single crystal semiconductor layer is fixed with a buffer layer interposed therebetween, a semiconductor device manufactured by the method, and an electronic device including the semiconductor device.

2. Description of the Related Art

In recent years, integrated circuits using an SOI (silicon on insulator) substrate, instead of using a bulk silicon wafer, have been developed. By utilizing characteristics of a thin single crystal silicon layer formed over an insulating layer, semiconductor layers of transistors formed in the integrated circuit can be electrically separated from each other completely. Further, since the fully depleted transistors can be formed, a semiconductor integrated circuit with high added value such as high integration, high speed driving, and low power consumption can be realized.

As an SOI substrate, a SIMOX substrate or a bonded substrate is known. For example, for an SOI structure of SIMOX substrate, oxygen ions are implanted into a single crystal silicon substrate, heat treatment at 1300° C. or higher is conducted to form a buried oxide (BOX) layer, so that a single crystal silicon film is formed on the surface.

As an SOI structure of a bonded substrate, two single crystal silicon substrates (a base substrate and a bond substrate) are bonded to each other with an oxide film interposed therebetween, and one of the two single crystal silicon substrates (the bond substrate) is thinned on its rear side (which is not a surface to be used for bonding), so that a single crystal silicon thin film is formed. There is proposed Smart Cut (registered trademark) employing hydrogen ion implantation (e.g., Reference 1: Japanese Published Patent Application No. H5-211128), because it is difficult to form a uniform and thin single crystal silicon thin film by grinding or polishing.

A method for manufacturing an SOI substrate is described briefly. Hydrogen ions are implanted into a silicon wafer to form an ion-implanted layer at a predetermined depth from the surface. Then, a silicon oxide film is formed by oxidizing another silicon wafer which serves as a base substrate. After that, the silicon wafer into which the hydrogen ions are implanted is bonded to the silicon oxide film of the other silicon wafer, so that the two silicon wafers are bonded. By heat treatment, the silicon wafers are separated from each other by using the ion-implanted layer as a separation plane and thus a substrate in which the thin single crystal silicon layer is attached to the base substrate is formed.

In addition, there is a known method of forming an SOI substrate in which a single crystal silicon layer is attached to a glass substrate (e.g., Reference 2: Japanese Published Patent Application No. H11-097379). In Reference 2, a separation plane is mechanically polished in order to remove a defective layer formed by an ion-implantation method or steps with several nanometers to several tens of nanometers in the separation plane.

The present assignee discloses in Reference 3 (Reference 3: Japanese Published Patent Application No. H11-163363) and Reference 4 (Japanese Published Patent Application No. 2000-012864) methods for manufacturing a semiconductor device in which a highly heat-resistant substrate is used as a supporting substrate, utilizing Smart Cut (registered trademark) and in Reference 5 (Reference 5: Japanese Published Patent Application No. 2000-150905) a method for manufacturing a semiconductor device in which a light-transmitting substrate is used as a supporting substrate, utilizing Smart Cut (registered trademark).

### SUMMARY OF THE INVENTION

Glass substrates are larger and can be obtained at lower cost than silicon wafers. Thus, by using a glass substrate as a supporting substrate, a large-area SOI substrate can be manufactured at low cost. However, the strain point of the glass substrate is equal to or lower than 700° C., and thus the glass substrate has low heat resistance. Therefore, the glass substrate cannot be heated at a temperature which exceeds an allowable temperature limit of the glass substrate, and the process temperature is limited to 700° C. or lower. That is, there is a limitation on a process temperature in a step of removing a crystal defect at a separation plane and a step of planarizing a surface.

In a conventional manner, a crystal defect of a semiconductor layer attached to a silicon wafer can be removed by heating at a temperature of 1000° C. or higher; however, such a high temperature process cannot be utilized for removal of a crystal defect of a semiconductor layer that is attached to a glass substrate having a strain point of 700° C. or lower. That is, a recrystallization method in which crystallinity of a single crystal semiconductor layer that is attached to a glass substrate having a strain point of 700° C. or lower can be recovered to substantially the same as that of a single crystal semiconductor layer before processing, has not been established yet.

The glass substrate is bent more easily than a silicon wafer and has an undulated surface. In particular, it is difficult to perform mechanical polishing on a large-area glass substrate having a side that is longer than 30 cm. Accordingly, from the viewpoint of processing accuracy, yield, and the like, mechanical polishing on a separation plane is not recommended as planarization treatment of a semiconductor layer that is attached to a supporting substrate. Meanwhile, it is required to suppress unevenness on the surface of the separation plane to manufacture semiconductor elements that have high performance. In the case where transistors are manufactured using an SOI substrate, a gate electrode is formed over a semiconductor layer with a gate insulating layer interposed therebetween. Therefore, if there is large unevenness of the semiconductor layer, it is difficult to manufacture a gate insulating layer with high withstand voltage. Therefore, a thick gate insulting layer is needed in order to increase the withstand voltage. Accordingly, if unevenness on the surface of the semiconductor layer is large, there is a decrease in performance of semiconductor elements such as a decrease in field effect mobility, or an increase in threshold voltage.

In this manner, when a substrate such as a glass substrate, which has low heat resistance and is easily bent, is used for a supporting substrate, there is a problem in that it is difficult to reduce surface unevenness of a semiconductor layer that is separated from a silicon wafer and fixed to the supporting substrate.

In view of such problems, an object of the present invention is to provide a method for manufacturing a semiconductor substrate which can provide a high-performance semiconductor element even when a substrate having low heat resistance is used for a supporting substrate.

One feature of a method for manufacturing a semiconductor substrate includes the steps of: preparing a single crystal semiconductor substrate and a supporting substrate; exciting a source gas to generate plasma including ions; adding the ions included in the plasma through one surface of the single crystal semiconductor substrate to form a damaged layer in a region at a predetermined depth from the one surface of the single crystal semiconductor substrate; forming a buffer layer over the one surface of the single crystal semiconductor substrate or a surface of the supporting substrate; closely attaching the single crystal semiconductor substrate and the supporting substrate with the buffer layer interposed therebetween so that the single crystal semiconductor substrate and the supporting substrate are attached to each other by bonding the surface of the buffer layer and the a contact plane with the buffer layer; separating the single crystal semiconductor substrate from the supporting substrate by using the damaged layer as a cleavage plane by heating the single crystal semiconductor substrate, and thus forming a supporting substrate to which the single crystal semiconductor layer separated from the single crystal semiconductor substrate is fixed; irradiating the single crystal semiconductor layer with a laser beam from the single crystal semiconductor substrate side to melt a region in a depth direction from the surface of the single crystal semiconductor layer which is irradiated with the laser beam and to recrystallize the single crystal semiconductor layer.

Here, the “single crystal” means a crystal in which crystal axes are in the same directions in any portion of a sample and which has no crystal grain boundaries between crystals. Note that, in this specification, the single crystal includes a crystal in which crystal axes are in the same direction as described above and which has no grain boundaries even when a crystal defect or a dangling bond is included. In addition, “recrystallization of a single crystal semiconductor layer” means that a semiconductor layer having a single crystal structure goes through a state that is different from the single crystal structure (e.g., a liquid phase state) to have a single crystal structure again. Alternatively, “recrystallization of a single crystal semiconductor layer” also means that a single crystal semiconductor layer is recrystallized to form a single crystal semiconductor layer.

By laser irradiation from the single crystal semiconductor layer side, a certain region can be melted in the thickness direction from the surface of the single crystal semiconductor layer which is irradiated with a laser beam. For example, the single crystal semiconductor layer can be melted, excluding the interface between the single crystal semiconductor layer and the buffer layer and the vicinity of the interface.

In the method for manufacturing a semiconductor substrate according to the present invention, the semiconductor layer is preferably irradiated with a laser beam in an inert atmosphere.

In a method for manufacturing a semiconductor substrate of the present invention, a cross-sectional shape of a laser beam with which a single crystal semiconductor layer is irradiated can be linear, square, or rectangular. By scanning with a laser beam having such a cross-sectional shape, a portion which is melted and recrystallized can be moved. In addition, the melting time of the single crystal semiconductor layer can be extended by conducting laser irradiation to the same surface repeatedly, and the refinement of a single crystal is partly performed repeatedly, thereby obtaining a single crystal semiconductor layer having excellent characteristics.

Note that the single crystal semiconductor layer is irradiated with a laser beam to melt a certain region in the depth direction from the surface of the single crystal semiconductor layer which is irradiated with the laser beam, and thus the following advantageous effects can be obtained.

As one of the advantageous effects of the method for manufacturing a semiconductor substrate according to the present invention, the surface and a certain region in the depth direction of the single crystal semiconductor layer can be melted by laser irradiation from the single crystal semiconductor layer side. In this manner, the surface of the single crystal semiconductor layer, which is an irradiation surface, can have drastically improved planarity due to surface tension effect.

As one of the advantageous effects of the method for manufacturing a semiconductor substrate according to the present invention, the single crystal semiconductor layer is irradiated with a laser beam and heated so that lattice defects in the single crystal semiconductor layer generated in forming a damaged layer in the single crystal semiconductor substrate can be reduced, and thus a more excellent single crystal semiconductor layer can be obtained. In the laser-irradiated region of the single crystal semiconductor layer, the surface and a certain region in the thickness direction of the single crystal semiconductor layer are melted, and recrystallization progress in accordance with plane orientation of the single crystal semiconductor layer which is left without being melted, and thus a single crystal semiconductor layer having excellent characteristics can be obtained.

In the above References 1 to 5, mechanical polishing is performed as a main process for planarization; therefore, the above References 1 to 5 differ widely from the present invention, because using a glass substrate having a strain point of 700° C. or lower, which is an object of the present invention, extension of melting time, and an effect thereof are not assumed at all.

The present invention provides an innovative technique, relating to a method in which a single crystal semiconductor layer is irradiated with a laser beam from the single crystal semiconductor layer side, a surface and a certain region in the depth direction of the single crystal semiconductor layer are melted, recrystallization progresses based on the plane orientation of the single crystal semiconductor layer which is left without being melted to obtain a better single crystal. In addition, the usage method of such a laser beam is not assumed in a conventional technique at all and is an extremely new concept.

By a method for manufacturing a semiconductor substrate according to the present invention, a surface and a certain region in the depth direction of the single crystal semiconductor layer, which has been separated from a single crystal semiconductor substrate, are melted at a process temperature of 700° C. or lower, whereby recrystallization progresses in accordance with plane orientation of the single crystal semiconductor layer which is left without being melted, and thus crystallinity can be improved. In addition, at a process temperature of 700° C. or lower, the single crystal semiconductor layer separated from the single crystal semiconductor substrate can be planarized.

### BRIEF DESCRIPTION OF DRAWINGS

In the accompanying drawings:

FIG. 1 illustrates an example of a structure of a semiconductor substrate;

FIG. 2 illustrates an example of a structure of a single crystal semiconductor substrate;

FIGS. 3A to 3D illustrate a manufacturing method of a semiconductor substrate;

FIGS. 4A to 4C illustrate a manufacturing method of a semiconductor substrate;

FIG. 5 illustrates a structure of a laser irradiation apparatus;

FIGS. 6A and 6B are photographs of signal waveforms input to an oscilloscope;

FIG. 7 is a graph showing a waveform corresponding to an intensity of probe light;

FIG. 8 is a graph showing a Raman shift of a single crystal silicon layer with respect to an energy density of a laser beam;

FIG. 9 is a graph showing a full width at half maximum (FWHM) in Raman spectrum of a single crystal silicon layer with respect to an energy density of a laser beam;

FIGS. 10A to 10C are DFM images of a top layer of a single crystal silicon layer observed by AFM;

FIGS. 11A to 11C are graphs showing surface roughness of a single crystal silicon layer calculated based on the DFM images;

FIG. 12 illustrates an example of a laser irradiation apparatus;

FIG. 13 illustrates an example of a laser irradiation apparatus;

FIG. 14 illustrates a cross section of a supporting substrate;

FIG. 15 illustrates a cross section of a supporting substrate;

FIGS. 16A to 16D are cross-sectional views illustrating a manufacturing method of a semiconductor device;

FIGS. 17A to 17C are cross-sectional views illustrating a manufacturing method of a semiconductor device;

FIG. 18 is a cross-sectional view illustrating a manufacturing method of a semiconductor device;

FIGS. 19A to 19E are cross-sectional views illustrating a manufacturing method of a semiconductor device;

FIG. 20 is a block diagram illustrating an example of a microprocessor;

FIG. 21 is a block diagram illustrating an example of an RFCPU;

FIG. 22A is a plan view of a pixel of a liquid crystal display device and FIG. 22B is a cross-sectional view taken along J-K line in FIG. 22A;

FIG. 23A is a plan view of a pixel of an electroluminescent display device and FIG. 23B is a cross-sectional view taken along J-K line in FIG. 23A;

FIG. 24A illustrates an appearance of a mobile phone, FIG. 24B illustrates an appearance of a digital audio player, and FIG. 24C illustrates an electronic book;

FIGS. 25A to 25C illustrate appearances of a smart phone;

FIGS. 26A to 26H are cross-sectional views illustrating a manufacturing method an SOI substrate;

FIG. 27 illustrates a manufacturing method of a semiconductor substrate according to an aspect of the present invention;

FIG. 28 shows dark-field images of a silicon layer which is irradiated with laser light in an air atmosphere, obtained by an optical microscope;

FIG. 29 shows dark-field images of a silicon layer which is irradiated with laser light in a nitrogen atmosphere, obtained by an optical microscope;

FIGS. 30A, 30B and 30C show observation images of a silicon layer, obtained by SEM;

FIGS. 30A to 30C show observation images of a silicon layer, obtained by SEM;

FIGS. 31A to 31E show DFM images of a silicon layer, obtained by AFM;

FIGS. 32A to 32E show DFM images of a silicon layer, obtained by AFM;

FIG. 33 is a graph of a Raman shift of a silicon layer;

FIG. 34 is a graph of a Raman spectrum of a silicon layer;

FIGS. 35A to 35D are IPF maps obtained from EBSP measurement data:

FIG. 36 is a graph of a concentration of hydrogen ions in a silicon layer;

FIGS. 37A and 37B are graphs of voltage-current characteristics of thin film transistors;

FIGS. 38A to 38D are cross-sectional views illustrating a manufacturing method of a semiconductor device;

FIGS. 39A to 39C are cross-sectional views illustrating a manufacturing method of a semiconductor device;

FIGS. 40A and 40B are cross-sectional views illustrating a manufacturing method of a semiconductor device;

FIG. 41 is an energy diagram of hydrogen ion species;

FIG. 42 is a diagram showing the results of ion mass spectrometry;

FIG. 43 is a diagram showing the results of ion mass spectrometry;

FIG. 44 is a diagram showing the profile (measured values and calculated values) of hydrogen in the depth direction when the accelerating voltage is 80 kV;

FIG. 45 is a diagram showing the profile (measured values, calculated values, and fitting functions) of hydrogen in the depth direction when the accelerating voltage is 80 kV;

FIG. 46 is a diagram showing the profile (measured values, calculated values, and fitting functions) of hydrogen in the depth direction when the accelerating voltage is 60 kV;

FIG. 47 is a diagram showing the profile (measured values, calculated values, and fitting functions) of hydrogen in the depth direction when the accelerating voltage is 40 kV; and

FIG. 48 shows ratios of the fitting parameters (a ratio of a hydrogen element and a ratio of hydrogen ion species).

### DETAILED DESCRIPTION OF THE INVENTION

### Embodiment Mode

Hereinafter, the present invention will be described. It is easily understood by those skilled in the art that the present invention can be carried out in many different modes, and modes and details disclosed herein can be modified in various ways without departing from the spirit and scope of the present invention. Therefore, the present invention should not be interpreted as being limited to the description of the embodiment modes and Examples. Note that components denoted by the same reference numerals in different drawings are the same components; therefore, repetitive descriptions on material, shape, manufacturing method, and the like are omitted.

### Embodiment Mode 1

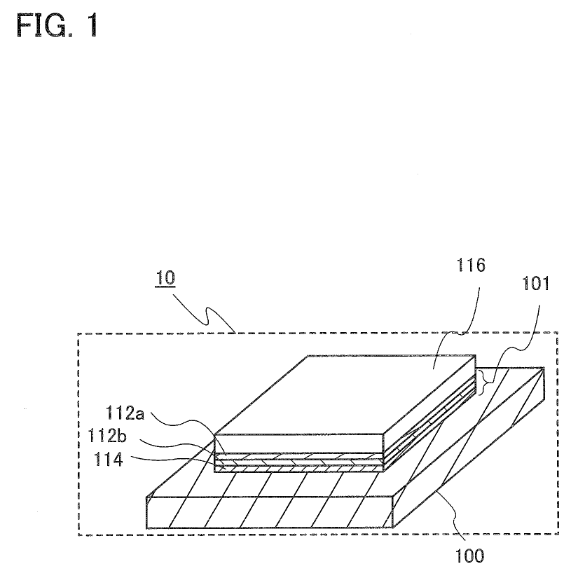

FIG. 1 is a perspective view of an example of a semiconductor substrate structure. In a semiconductor substrate 10, a single crystal semiconductor layer 116 is attached to a supporting substrate 100 with a buffer layer 101 interposed therebetween. The semiconductor substrate 10 is a substrate having a so-called SOI structure and has a single crystal semiconductor layer over an insulating layer.

The buffer layer 101 has a single layer structure or a multilayer structure in which two or more films are stacked. In this embodiment mode, the buffer layer 101 has a three-layer structure in which a bonding layer 114, an insulating film 112b and an insulating film 112 are stacked over the supporting substrate 100. In addition, the insulating film 112a is an insulating film serving as a barrier layer. The barrier layer can prevent an impurity (typically, sodium) of an alkali metal or an alkaline earth metal which may reduce reliability of a semiconductor device from entering the single crystal semiconductor layer 116 from the supporting substrate 100 side in manufacturing a semiconductor substrate or a semiconductor device using the semiconductor substrate. By provision of the barrier layer, the semiconductor device can be prevented from being contaminated by such an impurity and thus the reliability of the semiconductor device can be increased.

The single crystal semiconductor layer 116 is a layer formed by thinning a single crystal semiconductor substrate. A commercially available semiconductor substrate can be used as the single crystal semiconductor substrate. For example, a single crystal semiconductor substrate made of a group 14 element such as a single crystal silicon substrate, a single crystal germanium substrate, or a single crystal silicon-germanium substrate can be used. Alternatively, a compound semiconductor substrate including gallium arsenide, indium phosphide, or the like can be used.

As the supporting substrate 100, a substrate having an insulating surface is used. Specifically, a wide variety of glass substrates used in the electronics industry, such as substrates using aluminosilicate glass, aluminoborosilicate glass, and bariumborosilicate glass can be given, as well as a quartz substrate, a ceramic substrate, and a sapphire substrate. Preferably, a glass substrate is used as the supporting substrate 100. As a glass substrate, a substrate is preferable, which has a coefficient of thermal expansion of higher than or equal to 25×10⁻⁷/° C. and less than or equal to 50×10⁻⁷/° C. (preferably higher than or equal to 30×10⁻⁷/° C. and less than or equal to 40×10⁻⁷/° C.), and a strain point at higher than or equal to 580° C. and lower than or equal to 700° C., preferably higher than or equal to 650° C. and lower than or equal to 690° C. Further, to suppress contamination of a semiconductor device, the glass substrate is preferably a non-alkali glass. As a material of the non-alkali glass substrate, glass materials such as aluminosilicate glass, aluminoborosilicate glass, and bariumborosilicate glass can be given, for example. Further, as the supporting substrate 100, a non-alkali glass substrate (product name: AN100), a non-alkali glass substrate (product name: EAGLE2000 (registered trademark)), or a non-alkali glass substrate (product name: EAGLEXG (registered trademark)) is preferably used.

The physical properties of the non-alkali glass substrate (AN100) are as follows: the specific gravity is 2.51 g/cm³, the Poisson's ratio is 0.22, the Young's modulus is 77 GPa, and the coefficient of thermal expansion is 38×10⁻⁷/° C.

The physical properties of the non-alkali glass substrate (EAGLE2000 (registered trademark)) are as follows: the specific gravity is 2.37 g/cm³, the Poisson's ratio is 0.23, the Young's modulus is 70.9 GPa, and the coefficient of thermal expansion is 31.8×10⁻⁷/° C.

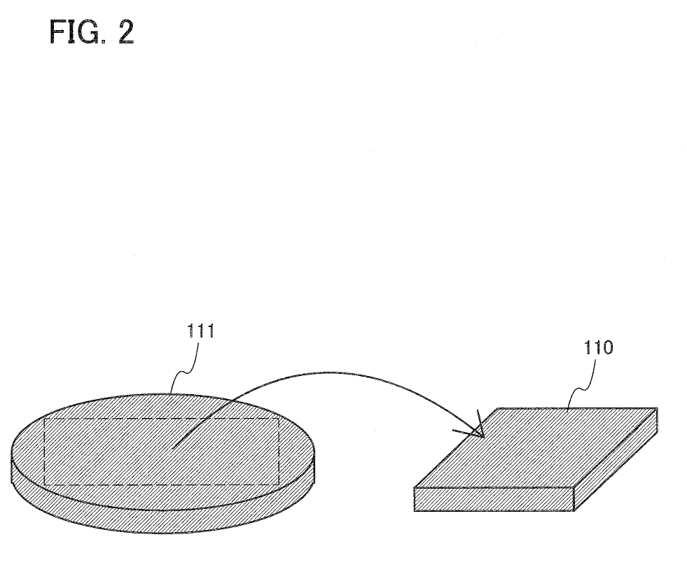

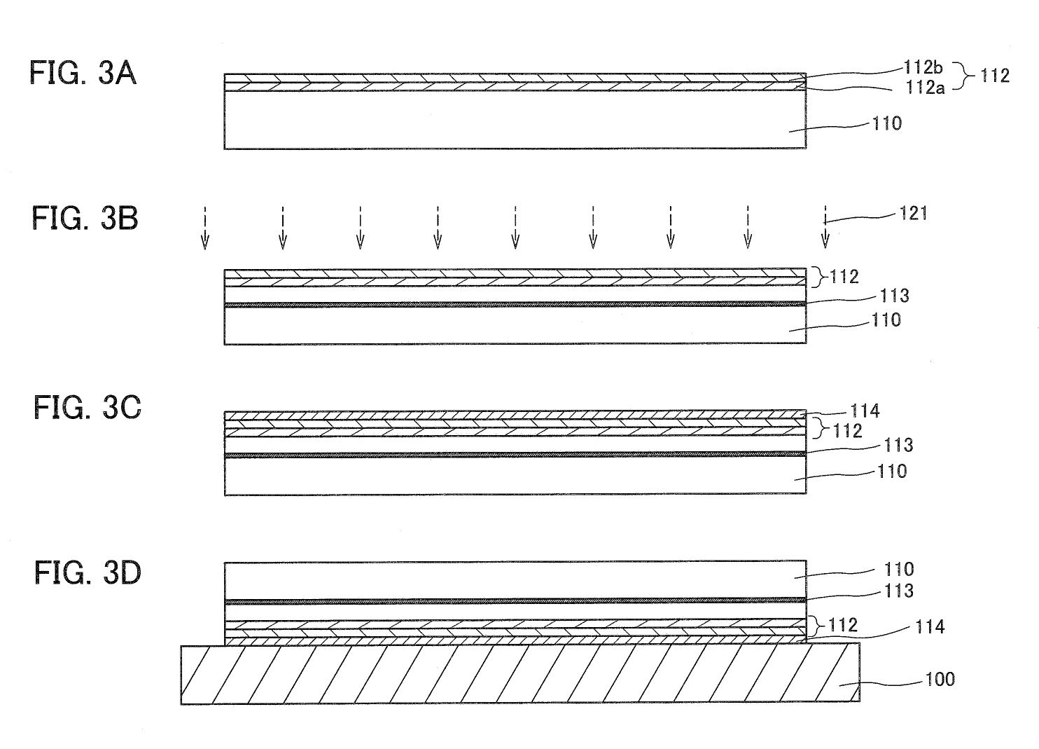

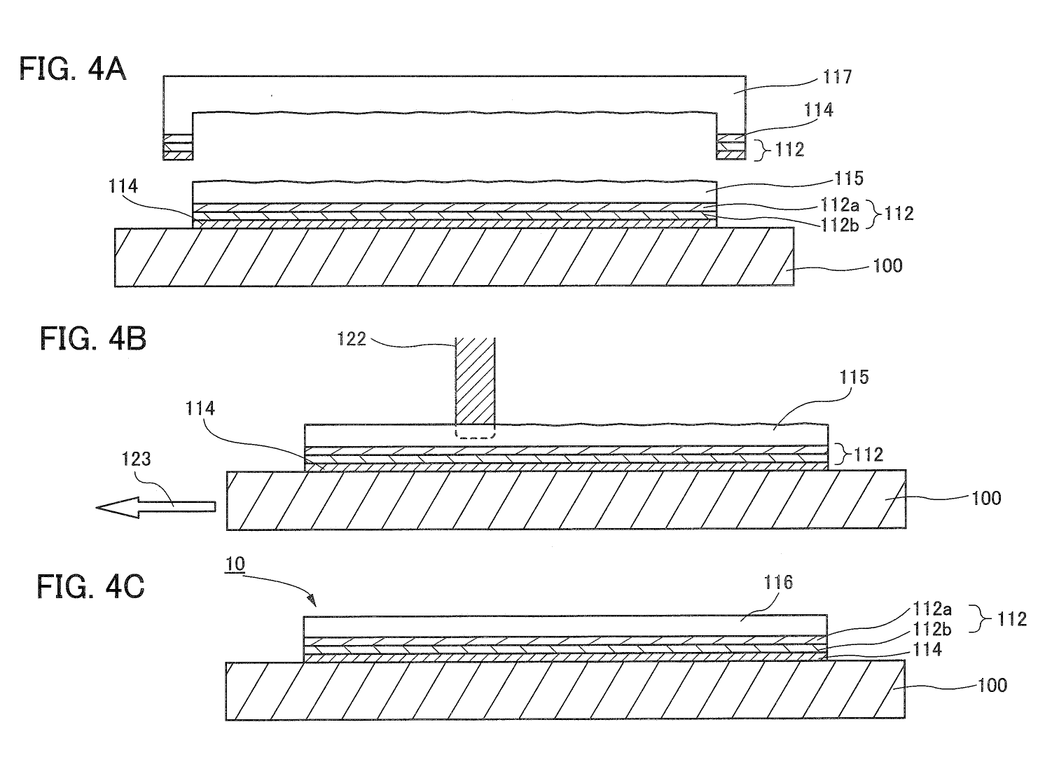

A manufacturing method of the semiconductor substrate 10 illustrated in FIG. 1 is described with reference to FIG. 2, FIGS. 3A to 3D and FIGS. 4A to 4C.

First, a single crystal semiconductor substrate 110 is prepared. The single crystal semiconductor substrate 110 is processed into a desired size and shape. FIG. 2 is an external view illustrating an example of a structure of the single crystal semiconductor substrate 110. When the fact that the shape of the supporting substrate 100 to which the single crystal semiconductor substrate 110 is bonded is rectangular and a light-exposing region of a light exposure apparatus such as a reduced projection exposure apparatus is rectangular is taken into consideration, a shape of the single crystal semiconductor substrate 110 is preferably rectangular as illustrated in FIG. 2. Note that unless otherwise specified, a square shape and an oblong shape are also included in the category of the rectangular shape.

Needless to say, the shape of the single crystal semiconductor substrate 110 is not limited to the shape illustrated n FIG. 2, and the single crystal semiconductor substrate can have a wide variety of shapes. For example, a circular substrate, a polygonal substrate such as a pentagonal substrate or a hexagonal substrate can be used. It is natural that a commercially-available disc-like substrate can be used for the single crystal semiconductor substrate 110.

The rectangular single crystal semiconductor substrate 110 can be formed by cutting a circular, bulk single crystal semiconductor substrate 111 that is commercially available. To cut the substrate, a cutting apparatus such as a dicer or a wire saw, a cutting means such as a laser cutter, a plasma cutter, or an electron beam cutter, or another optional cutting means or the like can be used. Alternatively, before being sliced into a substrate, an ingot for manufacturing semiconductor substrates can be processed into a rectangular solid so that it has a rectangular cross section, and this ingot that is a rectangular solid may be sliced to manufacture the rectangular single crystal semiconductor substrate 110.

Note that in the case of using, as the single crystal semiconductor substrate 110, a substrate made of a group 14 element, which has a diamond structure as a crystal structure like a single crystal silicon substrate, a plane orientation of a main surface thereof may be (100), (110), or (111). By using the single crystal semiconductor substrate 110 with a main surface of (100), the interface state density between the single crystal semiconductor layer 116 and an insulating layer formed on a surface thereof can be lowered, which is suitable for manufacturing a field effect transistor.

In a case where a commercially-available disc-like single crystal silicon substrate is used as the single crystal semiconductor substrate 110, circular substrates which are 5 inches in diameter (125 mm), 6 inches in diameter (150 mm), 8 inches in diameter (200 mm), 12 inches in diameter (300 mm) and 18 inches in diameter (450 mm) are typical. Note that the shape of the substrate is not limited to such a circular shape, and a silicon substrate processed into a rectangular shape can also be used. By use of the large single crystal semiconductor substrate, the method for manufacturing with excellent mass productivity can be provided.

Then, as illustrated in FIG. 3A, the insulating layer 112 is formed over the single crystal semiconductor substrate 110. The insulating layer 112 can have a single-layer structure or a multi-layer structure of two or more layers. The thickness of the insulating layer 112 can be more than or equal to 5 nm and less than or equal to 400 nm. As the insulating layer 112, an insulating film containing silicon or germanium in its composition, such as a silicon oxide film, a silicon nitride film, a silicon oxynitride film, a silicon nitride oxide film, a germanium oxide film, a germanium nitride film, a germanium oxynitride film, or a germanium nitride oxide film can be used. Alternatively, an insulating film made of a metal oxide such as aluminum oxide, tantalum oxide, or hafnium oxide; an insulating film made of a metal nitride such as aluminum nitride; an insulating film made of a metal oxynitride such as an aluminum oxynitride film; or an insulating film made of a metal nitride oxide such as an aluminum nitride oxide film, can be used.

Note that in this specification, an “oxynitride” is a substance that contains more oxygen than nitrogen, and a “nitride oxide” is a substance that contains more nitrogen than oxygen. For example, “silicon oxynitride” means a substance that contains more oxygen than nitrogen and oxygen, nitrogen, silicon, and hydrogen at concentrations ranging from 50 at. % to 70 at. %, 0.5 at. % to 15 at. %, 25 at. % to 35 at. %, and 0.1 at. % to 10 at. %, respectively. Further, “silicon nitride oxide” means a substance that contains more nitrogen than oxygen and includes oxygen, nitrogen, silicon, and hydrogen at concentrations ranging from 5 at. % to 30 at. %, 20 at. % to 55 at. %, 25 at. % to 35 at. %, and 10 at. % to 30 at. %, respectively.

The insulating film for the insulating layer 112 can be formed by a CVD method, a sputtering method, or a method of, for example, oxidizing or nitriding the single crystal semiconductor substrate 110.

The insulating layer 112 preferably includes a barrier layer provided to prevent sodium from entering the single crystal semiconductor layer 116. The barrier layer may be a single layer or a multilayer with two or more layers. For example, in a case where a substrate containing an impurity such as alkali metal or alkaline earth metal which may reduce reliability of a semiconductor device is used as the supporting substrate 100, if the supporting substrate 100 is heated, there is a concern that such an impurity diffuses into the single crystal semiconductor layer 116 from the supporting substrate 100. Therefore, the formation of the barrier layer can prevent an impurity such as an alkali metal or an alkaline earth metal which may reduce reliability of a semiconductor device from entering the single crystal semiconductor layer 116. As such a film serving as the barrier layer, a silicon nitride film, a silicon nitride oxide film, an aluminum nitride film, an aluminum nitride oxide film, or the like can be given. With the provision of such a film, the insulating layer 112 can function as a barrier layer.

For example, in the case of forming the insulating layer 112 having with a single layer structure, a film serving as a barrier layer is formed as the insulating layer 112. In this case, a silicon nitride film, a silicon nitride oxide film, an aluminum nitride film, or an aluminum nitride oxide film can be formed with a thickness of from 5 nm to 200 nm.

In the case of forming a two-layer structure of the insulating layer 112 including one layer of barrier layer, an upper layer is formed of a barrier layer which can block an impurity such as sodium. The upper layer can be formed with a silicon nitride film, a silicon nitride oxide film, an aluminum nitride film, or an aluminum nitride oxide film having a thickness of 5 nm to 200 nm. These films serving as a barrier layer have high blocking effects that prevent diffusion of impurity, but have high internal stress. Therefore, as an insulating film of a lower layer that is in contact with the single crystal semiconductor substrate 110, it is preferable to select a film that has an effect of alleviating the stress of an insulating film of the upper layer. As such an insulating film, a silicon oxide film, a silicon oxynitride film, a thermally oxidized film formed by thermally oxidizing the single crystal semiconductor substrate 110, and the like can be given. The thickness of the insulating film of the lower layer can be from 5 nm to 300 nm.

In this embodiment mode, the insulating layer 112 has a two-layer structure including the insulating film 112a and the insulating film 112b. As combinations of the insulating film 112a that serves as a blocking film and the insulating film 112b in the insulating layer 112, the following can be given as examples. A silicon oxide film and a silicon nitride film, a silicon oxynitride film and a silicon nitride film, a silicon oxide film and a silicon nitride oxide film, a silicon oxynitride film and a silicon nitride oxide film, and the like.

For example, the insulating film 112a of the lower layer can be formed of a silicon oxynitride film that is formed by a plasma-excitation CVD method (hereinafter referred to as “PECVD method”) using SiH₄ and N₂O for process gases. Alternatively, as the insulating film 112a, a silicon oxide film can be formed by a PECVD method using organosilane and oxygen as process gases. Further alternatively, the insulating film 112a may be formed of an oxide film formed by oxidizing the single crystal semiconductor substrate 110.

Organosilane is a compound such as the following: tetraethoxysilane (TEOS, chemical formula: Si(OC₂H₅)₄), tetramethylsilane (TMS, chemical formula: Si(CH₃)₄), tetramethylcyclotetrasiloxane (TMCTS), octamethylcyclotetrasiloxane (OMCTS), hexamethyldisilazane (HMDS), triethoxysilane (SiH(OC₂H₅)₃), trisdimethylaminosilane (SiH(N(CH₃)₂)₃), or the like.

The insulating film 112b of the upper layer can be formed of a silicon nitride oxide film that is formed by a PECVD method using SiH₄, N₂O, NH₃, and H₂ as process gasses, or a silicon nitride film that is formed by a PECVD method using SiH₄, N₂, N₃, and H₂ as process gasses.

For example, in the case of forming the insulating film 112a made of a silicon oxynitride and the insulating film 112b made of silicon nitride oxide by a PECVD method, the single crystal semiconductor substrate 110 is carried into a chamber of a PECVD apparatus. Then, SiH₄ and N₂O are supplied to the chamber as process gasses for forming the insulating film 112a, plasma of these process gases is generated, and a silicon nitride oxide film is formed over the single crystal semiconductor substrate 110. Next, gases introduced into the chamber are switched to gases for a process for forming the insulating film 112b. Here, SiH₄, NH₃, H₂ and N₂O are used. Plasma of a mixed gas of these gases is generated, and a silicon nitride oxide film is formed over the silicon oxynitride film without a break. Also, in the case of using a PECVD apparatus with plural treatment chambers, the silicon oxynitride film and the silicon nitride oxide film can be formed in different chambers. Of course, by switching the gases introduced to the treatment chamber, a silicon oxide film can be formed as the lower layer and a silicon nitride film can be formed as the upper layer.

By forming the insulating film 112a and the insulating film 112b in the above manner, the insulating layer 112 can be formed over the single crystal semiconductor substrate 110 in favorable throughput. Further, because the insulating film 112a and the insulating film 112b can be formed without being exposed to air, contamination of an interface between the insulating film 112a and the insulating film 112b by air can be prevented.

Alternatively, an oxide film formed by oxidizing the single crystal semiconductor substrate 110 can be used as the insulating film 112a. Thermal oxidation treatment for forming this oxide film may be dry oxidation, but adding a gas containing halogen into an oxygen atmosphere is preferable. An oxide film containing halogen can be formed as the insulating film 112a. As the gas containing halogen, one type or plural types of gasses selected from the following can be used: HCl, HF, NF₃, HBr, Cl, ClF, BCl₃, F, Br₂, and the like.

For example, heat treatment is performed at 700° C. or higher, in an atmosphere containing HCl at 0.5% to 10% by volume (preferably 3% by volume) with respect to oxygen. It is preferable that the thermal oxidation is performed at a heating temperature of 950° C. to 1100° C. Treatment time may be 0.1 to 6 hours, preferably 0.5 to 1 hour. The thickness of the oxide film that is formed can be made to be 10 nm to 1000 nm (preferably 50 nm to 200 nm), for example, 100 nm.

By performing oxidation treatment in such a temperature range, a gettering effect by a halogen element can be obtained. As the gettering effect, there is an effect of removing a metal impurity in particular. That is, by the action of chlorine, an impurity such as metal or the like turns into volatile chloride, and then is released into an air phase and removed from the single crystal semiconductor substrate 110. Also, by the halogen element used in the oxidation treatment, a dangling bond on a surface of the single crystal semiconductor substrate 110 is terminated, and localized level density at an interface of the oxide film and the single crystal semiconductor substrate 110 can be reduced.

By this thermal oxidation treatment in an atmosphere containing halogen, the oxide film can contain halogen. By containing a halogen element at a concentration of 1×10¹⁷ atoms/cm³ to 5×10²⁰ atoms/cm³, the oxide film can manifest a function of a protective film that prevents contamination of the single crystal semiconductor layer 116 by capturing an impurity such as a metal, in the semiconductor substrate 10.

The insulating film 112a can be formed so as to contain halogen in a chamber of a PECVD apparatus including a fluoride gas or a fluorine gas, By introducing a process gas for forming the insulating film 112a into such a chamber, the process gas is excited to form plasma and by chemical reaction of active species included in the plasma, the insulating film 112a is formed over the single crystal semiconductor substrate 110.

A fluorine compound gas can be contained in a chamber of a PECVD apparatus by cleaning the chamber by plasma gas etching using a fluoride gas. When a film is formed in a PECVD apparatus, products generated by reaction of a source material are deposited on not only the surface of the substrate but also an inner wall of the reaction chamber, an electrode, a substrate holder, and the like. These deposited products are a cause of particles and dust. Therefore, a cleaning step for removing such deposited products is carried out regularly. As a typical cleaning method of a chamber, a method using plasma gas etching can be given. This is a method in which a fluoride gas such as NF₃ is introduced into a chamber, the fluoride gas is excited to generate plasma so that fluorine radicals are generated, and deposited products are etched so as to be removed. Since the fluoride generated by reaction with the fluorine radicals has a high vapor pressure, the fluoride is removed from the reaction chamber through an exhaust system.

In conducting cleaning by plasma gas etching, a fluoride gas used as a cleaning gas is adsorbed on the inner wall of the chamber and the electrode and various tools provided in the chamber. That is, a fluoride gas can be contained in the chamber. Note that as the method for making the fluoride gas be contained in the chamber, there is a method in which a chamber is cleaned by a fluoride gas and the fluoride gas is left in the chamber.

For example, in the case where a silicon oxynitride film is formed by a PECVD method using SiH₄ and N₂O as the insulating film 112a, SiH₄ and N₂O are supplied to a chamber, these gases are excited to generate plasma, and accordingly the fluoride gas remaining in the reaction chamber is also excited to form fluorine radicals. Thus, the silicon oxynitride film can contain fluorine. Further, a slight amount of fluoride remains in the chamber, and the fluoride is not supplied during formation of the silicon oxynitride film. Therefore, fluorine is introduced in the early stage of the formation of the silicon oxynitride film. In this manner, in the insulating film 112a, the concentration of fluorine can be heightened at an interface between the single crystal semiconductor substrate 110 and the insulating film 112a (the insulating layer 112) or in the vicinity of the interface. That is, in the insulating layer 112 of the semiconductor substrate 10 illustrated in FIG. 1, the fluorine concentration can be heightened at an interface with the single crystal semiconductor layer 116 or in the vicinity of the interface.

Dangling bonds in the semiconductor at the interface with the single crystal semiconductor layer 116 can be terminated with fluorine by making such a region contain fluorine; accordingly, the interface state density between the single crystal semiconductor layer 116 and the insulating layer 112 can be reduced. In addition, even in the case where metal such as sodium diffuses into the insulating layer 112 from the supporting substrate 100, if fluorine exists, the metal can be caught by the fluorine, thereby preventing the single crystal semiconductor layer 116 from being contaminated by the metal.

Instead of the fluoride gas, a fluorine (F₂) gas can also be contained in the reaction chamber. The fluoride is a compound containing fluorine (F) in its composition. As the fluoride gas, a gas selected from OF₂, ClF₃, NF₃, FNO, F₃NO, SF₆, SF₅NO, SOF₂, or the like can be used.

Next, as illustrated in FIG. 3B, an ion beam 121 including ions accelerated by an electric field is added to the single crystal semiconductor substrate 110 through the insulating layer 112, thereby forming a damaged layer 113 in the single crystal semiconductor substrate 110 at a predetermined depth from the surface thereof. The ion beam 121 is generated by exciting a source gas to generate plasma of the source gas, and then extracting ions contained in the plasma by an effect of an electric field.

The depth of the region in which the damaged layer 113 is formed can be adjusted by controlling acceleration energy and incidence angle of the ion beam 121. The acceleration energy can be adjusted by controlling acceleration voltage, dose, or the like. The damaged layer 113 is formed in a region that is at substantially the same depth as the average penetration depth of the ions. The thickness of a semiconductor layer that is separated from the single crystal semiconductor substrate 110 is set depending on the depth to which the ions are added. The depth at which the damaged layer 113 is formed is adjusted such that the single crystal semiconductor layer is formed to a thickness of 20 nm to 500 nm, preferably 20 nm to 200 nm.

In adding the ions to the single crystal semiconductor substrate 110, it is possible to use an ion doping method that does not involve mass separation or an ion implantation method that does. The ion doping method that does not involve mass separation is preferable since a cycle time for forming the damaged layer 113 in the single crystal semiconductor substrate 110 can be shortened by the ion doping method. In this specification, a damaged layer formed in a single crystal semiconductor substrate by an ion implantation method may be referred to as an ion-implanted layer and a damaged layer formed in a single crystal semiconductor substrate by an ion doping method may be referred to as an ion-added layer in some cases.

The single crystal semiconductor substrate 110 is carried into a processing chamber in an ion doping apparatus. Then, a source gas is excited to generate plasma, and ion species are extracted from the plasma and accelerated to generate the ion beam 121. The single crystal semiconductor substrate 110 is irradiated with the ion beam 121; consequently, the ions are introduced to a region at a predetermined depth at a high concentration, and the damaged layer 113 is formed in the single crystal semiconductor substrate 110.

In the case of using hydrogen (H₂) for the source gas, the hydrogen gas can be excited to generate plasma containing H⁺, H₂⁺, and H₃⁺. The ratio of ion species generated from the source gas can be varied by adjusting an excitation method of plasma, pressure of an atmosphere in which plasma is generated, supply quantity of a source gas, or the like. With respect to the total amount of H⁺, H₂⁺, and H₃⁺ included in the ion beam 121, H₃⁺ is preferably included in the ion beam 121 at more than or equal to 50%, and further preferably at more than or equal to 80%.

Since H₃⁺ has a larger number of hydrogen atoms compared to the other hydrogen ion species (H⁺, and H₂⁺) and therefore has a larger mass, in the case of being accelerated with the same energy, H₃⁺ is implanted in a shallower region of the single crystal semiconductor substrate 110 compared to H⁺, and H₂⁺. Therefore, by a high percentage of H₃⁺ contained in the ion beam 121, variation in the average penetration depth of the hydrogen ions becomes small; accordingly, a concentration profile of hydrogen in a depth direction in the single crystal semiconductor substrate 110 becomes steep, and a peak position of the profile can be made to be shallow. Consequently, it is preferable that H₃⁺ is preferably included in the ion beam 121 at more than or equal to 50%, and further preferably at more than or equal to 80%, with respect to the total amount of H⁺, H₂⁺, and H₃⁺ included in the ion beam 121.

In the case of performing ion irradiation by an ion doping method using hydrogen gas, the acceleration voltage can be 10 kV to 200 kV, and the dose can be 1×10¹⁶ ions/cm² to 6×10¹⁶ ions/cm². By adding hydrogen ions under this condition, the damaged layer 113 can be formed in a region in the single crystal semiconductor substrate 110 that is at a depth of 50 nm to 500 nm, although it depends on an ion species contained in the ion beam 121 and the percentage thereof.

For example, in the case in which the single crystal semiconductor substrate 110 is a single crystal silicon substrate, the insulating film 112a is a silicon oxynitride film with a thickness of 50 nm, and the insulating film 112b is a silicon nitride oxide film with a thickness of 50 nm, under a condition in which the source gas is hydrogen, the acceleration voltage is 40 kV, and the dose is 2.2×10¹⁶ ions/cm², a single crystal semiconductor layer with a thickness of about 120 nm can be separated from the single crystal semiconductor substrate 110. Alternatively, when hydrogen ions are added under a condition that is the same as above except for the insulating film 112a being a silicon oxynitride film with a thickness of 100 nm, a single crystal semiconductor layer with a thickness of about 70 nm can be separated from the single crystal semiconductor substrate 110.

For the source gas of the ion beam 121, helium (He) can also be used. Since ion species generated by exciting helium are almost all He⁺, even by an ion doping method that does not involve mass separation, He⁺ can be added into the single crystal semiconductor substrate 110 as the main ions. Accordingly, microvoids can be formed efficiently in the damaged layer 113 by an ion doping method. In the case of performing ion irradiation by an ion doping method using helium, the acceleration voltage can be from 10 kV to 200 kV, and the dose can be from 1×10¹⁶ ions/cm² to 6×10¹⁶ ions/cm².

A halogen gas such as chlorine gas (Cl₂ gas) or fluorine gas (F₂ gas) can be used for the source gas.

After forming the damaged layer 113, the bonding layer 114 is formed over a top surface of the insulating layer 112 as illustrated in FIG. 3C. In a step of forming the bonding layer 114, a heating temperature of the single crystal semiconductor substrate 110 is a temperature at which an element or a molecule added to the damaged layer 113 does not separate out, and the heating temperature is preferably 350° C. or lower. In other words, this heating temperature is a temperature at which gas is not released from the damaged layer 113. Note that the bonding layer 114 can be formed before the ion irradiation step. In this case, a processing temperature for forming the bonding layer 114 can be 350° C. or higher.

The bonding layer 114 is a layer for forming a smooth and hydrophilic bonding plane on the surface of the single crystal semiconductor substrate 110. Therefore, the average surface roughness Ra of the bonding layer 114 is equal to or less than 0.7 nm, and more preferably equal to or less than 0.4 nm. The thickness of the bonding layer 114 can be equal to or greater than 10 nm and equal to or less than 200 nm. The thickness is preferably equal to or greater than 5 nm and equal to or less than 500 nm, and more preferably equal to or greater than 10 nm and equal to or less than 200 nm.

The bonding layer 114 is preferably an insulating film formed by a chemical vapor reaction. For example, a silicon oxide film, a silicon oxynitride film, a silicon nitride oxide film, a silicon nitride film, or the like can be formed as the bonding layer 114. In the case of forming a silicon oxide film by a PECVD method as the bonding layer 114, an organosilane gas and an oxygen (O₂) gas are preferably used as a source gas. Usage of organosilane as a source gas enables formation of a silicon oxide film having a smooth surface at a process temperature of 350° C. or lower. Alternatively, the bonding layer 114 can be formed using a low temperature oxide (LTO) which is formed by a thermal CVD method at a heating temperature of 200° C. or higher and 500° C. or lower. For formation of the LTO, monosilane (SiH₄), disilane (Si₂H₆), or the like can be used as a silicon source gas, and dinitrogen monoxide (N₂O) or the like can be used as an oxygen source gas.

For example, the condition example for forming the bonding layer 114 of a silicon oxide film using TEOS and O₂ as a source gas is such that TEOS is introduced into a chamber at a flow rate of 15 sccm and O₂ is introduced at a flow rate of 750 sccm. The film formation pressure can be 100 Pa, the film formation temperature can be 300° C., the RF power output can be 300 W, and the power frequency can be 13.56 MHz.

The order of the step of FIG. 3B and the step of FIG. 3C can be reversed. In other words, after forming the insulating layer 112 and the bonding layer 114 on the single crystal semiconductor substrate 110, the damaged layer 113 can be formed. In this case, if the insulating layer 112 and the bonding layer 114 can be formed with the same film formation apparatus, it is preferable to sequentially form the insulating layer 112 and the bonding layer 114.

Further alternatively, after the step of FIG. 3B, the step of FIG. 3A and the step of FIG. 3C can be performed. In other words, after forming the damaged layer 113 by doping the single crystal semiconductor substrate 110 with ions, the insulating layer 112 and the bonding layer 114 can be formed. In this case, if the insulating layer 112 and the bonding layer 114 can be formed with the same film formation apparatus, it is preferable to sequentially form the insulating layer 112 and the bonding layer 114. Alternatively, in order to protect the surface of the single crystal semiconductor substrate 110 before forming the damaged layer 113, the single crystal semiconductor substrate 110 can be subjected to oxidation treatment to form an oxide film on the surface and the single crystal semiconductor substrate 110 can be doped with ion species through the oxide film. This oxide film is removed after formation of the damaged layer 113. Alternatively, the insulating layer 112 can be formed with this oxide film left behind.

Next, the single crystal semiconductor substrate 110 provided with the insulating layer 112, the damaged layer 113, and the bonding layer 114, and the supporting substrate 100 are cleaned. This cleaning step can be performed by ultrasonic cleaning with pure water. As the ultrasonic cleaning, megahertz ultrasonic cleaning (megasonic cleaning) is preferable. After the ultrasonic cleaning, one or both of the single crystal semiconductor substrate 110 and the supporting substrate 100 is preferably washed with ozone water. By cleaning of washing with ozone water, an organic substance can be removed, and surface activation which improves a hydrophilic property of the surface of the bonding layer 114 and the supporting substrate 100 can be performed.

As the activation treatment of the surfaces of the bonding layer 114 and the supporting substrate 100, irradiation treatment with an atomic beam or an ion beam, plasma treatment, or radical treatment can be performed as well as the cleaning with ozone water. In the case of utilizing the atomic beam or the ion beam, an inert gas neutral atomic beam or an inert gas ion beam of argon or the like can be used.

FIG. 3D is a cross-sectional view illustrating a bonding step. The supporting substrate 100 and the single crystal semiconductor substrate 110 are brought into a close contact with each other with the bonding layer 114 interposed therebetween. A pressure of about 300 N/cm² to 15000 N/cm² is applied to one part of the edge of the single crystal semiconductor substrate 110. This pressure is preferably 1000 N/cm² to 5000 N/cm². The bonding layer 114 and the supporting substrate 100 start bonding to each other from a pressurized part and the bonding part extends to the whole region. Then, the single crystal semiconductor substrate 110 can be closely attached to the supporting substrate 100. This bonding step can be performed at room temperature without heat treatment; therefore, a substrate with such low heat resistance as to have an allowable temperature limit of 700° C. or lower like a glass substrate can be used as the supporting substrate 100.

After attaching the supporting substrate 100 to the single crystal semiconductor substrate 110, it is preferable to perform heat treatment to increase bonding force at the bonding interface between the supporting substrate 100 and the bonding layer 114. This treatment temperature is set at a temperature which does not cause a crack in the damaged layer 113 and can be in a temperature range of from 200° C. to 450° C. Further, when the single crystal semiconductor substrate 110 is bonded to the supporting substrate 100 while heating at a temperature in the above-described range, the bond force at the bonding interface between the supporting substrate 100 and the bonding layer 114 can be made strong.

Next, heat treatment is performed to cause separation at the damaged layer 113, so that a single crystal semiconductor layer 115 is separated from the single crystal semiconductor substrate 110. FIG. 4A illustrates a separation step of separating the single crystal semiconductor layer 115 from the single crystal semiconductor substrate 110. The element denoted by reference numeral 117 is the single crystal semiconductor substrate 110 from which the single crystal semiconductor layer 115 is separated.

When the heat treatment is performed, the element added by ion doping is separated out into minute voids which are formed in the damaged layer 113 by temperature increase, and the pressure in the minute voids is increased. By pressure increase, the volume of the minute voids in the damaged layer 113 is changed and a crack is generated in the damaged layer 113 so that a separation plane to separate the single crystal semiconductor substrate 110 is generated in the damaged layer 113. Since the bonding layer 114 is bonded to the supporting substrate 100, the single crystal semiconductor layer 115 separated from the single crystal semiconductor substrate 110 is fixed over the supporting substrate 100. The temperature of the heat treatment for separating the single crystal semiconductor layer 115 from the single crystal semiconductor substrate 110 is set at a temperature which does not exceed a strain point of the supporting substrate 100.

This heat treatment can be performed with a rapid thermal annealing (RTA) apparatus, a resistance heating furnace, or a microwave heating apparatus. As the RTA apparatus, a gas rapid thermal annealing (GRTA) apparatus or a lamp rapid thermal annealing (LRTA) apparatus can be used. It is preferable that the temperature of the supporting substrate 100 to which the single crystal semiconductor layer 115 is attached is increased to a temperature in the range of from 550° C. to 650° C. by this heat treatment.

In the case of using a GRTA apparatus, the heating temperature can be in the range of from 550° C. to 650° C., and the treatment time can be in the range of 0.5 minutes to 60 minutes. In the case of using a resistance heating furnace, the heating temperature can be in the range of 200° C. to 650° C., and the treatment time can be in the range of 2 hours to 4 hours. In the case of using a microwave heating apparatus, for example, irradiation of a microwave having a frequency of 2.45 GHz is conducted at 900 W and the treatment time can be in the range of 2 minutes to 20 minutes.

A specific treatment method of heat treatment using a vertical furnace with resistance heating is described. The supporting substrate 100 to which the single crystal semiconductor substrate 110 is attached is placed in a boat for the vertical furnace. This boat is carried into a chamber of the vertical furnace. First, the chamber is exhausted to have a vacuum state in order to suppress oxidation of the single crystal semiconductor substrate 110. The degree of vacuum is approximately 5×10⁻³ Pa. After making the vacuum state, nitrogen is supplied to the chamber so that the chamber has a nitrogen atmosphere that is under atmospheric pressure. During this, the temperature is increased to 200° C.

After making the chamber have a nitrogen atmosphere that is under atmospheric pressure, heating at 200° C. is performed for 2 hours. Then, the temperature is increased to 400° C. in one hour. After the state at a heating temperature of 400° C. stabilizes, the temperature is increased to 600° C. in one hour. After the state at a heating temperature of 600° C. stabilizes, heat treatment at 600° C. is performed for 2 hours. Then, the temperature is decreased to 400° C. in one hour, and after 10 minutes to 30 minutes, the boat is carried out of the chamber. The single crystal semiconductor substrate 117 and the supporting substrate 100 to which the single crystal semiconductor layer 115 is attached that are in the boat are cooled in air atmosphere.

As the heat treatment using the above-described resistance heating furnace, heat treatment for increasing the bond force between the bonding layer 114 and the supporting substrate 100 and heat treatment for causing separation at the damaged layer 113 are sequentially performed. In the case where these two heat treatments are performed with different apparatuses, for example, heat treatment at a treatment temperature of 200° C. is performed for a treatment time of 2 hours in a resistance heating furnace, and the supporting substrate 100 and the single crystal semiconductor substrate 110, which are attached to each other, are carried out from the furnace. Then, heat treatment at a treatment temperature of from 600° C. to 700° C. is performed for a treatment time of from 1 minute to 30 minutes with an RTA apparatus, so that the single crystal semiconductor substrate 110 is separated at the damaged layer 113.

In order that the bonding layer 114 and the supporting substrate 100 are firmly bonded to each other by treatment with such a low temperature of 700° C. or lower, it is preferable that an OH group or a water molecule (H₂O) exist on the surface of the bonding layer 114 and the surface of the supporting substrate. This is because the bonding layer 114 and the supporting substrate 100 start bonding to each other by formation of a covalent bond (covalent bond between an oxygen molecule and a hydrogen molecule) or a hydrogen bond by the OH group or the water molecule.

Accordingly, the surfaces of the bonding layer 114 and the supporting substrate 100 are preferably activated to be hydrophilic. Further, the bonding layer 114 is preferably formed by such a method as to contain oxygen or hydrogen. For example, when a silicon oxide film, a silicon oxynitride film, a silicon nitride oxide film, a silicon nitride film, or the like is formed by a PECVD method at a treatment temperature of 400° C. or lower, the film can contain hydrogen. For formation of the silicon oxide film or the silicon oxynitride film, SiH₄ and N₂O may be used, for example, as a process gas. For formation of the silicon nitride oxide film, SiH₄, NH₃, and N₂O may be used, for example. For formation of the silicon nitride film, SiH₄ and NH₃ may be used, for example. Further, it is also preferable to use a compound including an OH group such as TEOS (chemical formula: Si(OC₂H₅)₄) as a source material in formation by a PECVD method.

Here, treatment at a heating temperature of 700° C. or lower is referred to as low-temperature treatment because the treatment is performed at a temperature equal to or lower than a strain point of a glass substrate. In addition, in contrast to this embodiment mode, in forming an SOI substrate by Smart Cut (registered trademark), heat treatment at 800° C. or higher is performed in order to bond a single crystal silicon layer and a single crystal silicon wafer, and heat treatment at a temperature higher than the strain point of a glass substrate is required.

Note that as illustrated in FIG. 4A, a peripheral portion of the single crystal semiconductor substrate 110 is not bonded to the supporting substrate 100 in many cases. This is thought to be because the peripheral portion of the single crystal semiconductor substrate 110 is chamfered, or the peripheral portion of the bonding layer 114 is damaged or got dirty when the single crystal semiconductor substrate 110 is moved, and thus the damaged layer 113 is difficult to be separated in the peripheral portion of the single crystal semiconductor substrate 110 where the supporting substrate 100 and the bonding layer 114 are not attached. Therefore, the single crystal semiconductor layer 115 which is smaller in size than the single crystal semiconductor substrate 110 is bonded to the supporting substrate 100, and an end portion of the single crystal semiconductor substrate 117 is provided with a projection and the insulating film 112b, the insulating film 112a, and the bonding layer 114, which are not bonded to the supporting substrate 100, are left remaining over the projection.

The crystallinity of the single crystal semiconductor layer 115 closely attached to the supporting substrate 100 is impaired due to formation of the damaged layer 113, separation along the damaged layer 113 or the like. In other words, crystal defects in the single crystal semiconductor substrate 110, which have not seen before processing, are produced in the single crystal semiconductor layer 115. In addition, the surface of the single crystal semiconductor layer 115 is a separation plane from the single crystal semiconductor substrate 110 and thus planarity thereof is impaired. In order that the surface of the single crystal semiconductor layer 115 can be planarized by melting the surface and a certain region in the thickness direction of the single crystal semiconductor layer 115 and recrystallization can be promoted based on plane orientation of the single crystal semiconductor layer which is left without being melted, a laser beam for improving the crystallinity of the single crystal semiconductor layer 115 is delivered to the single crystal semiconductor layer 115 side. FIG. 4B illustrates the laser irradiation process.

In FIG. 4B, the single crystal semiconductor layer 115 is scanned with a laser beam 122 such that the entire surface of the separation plane of the single crystal semiconductor layer 115 is irradiated with the laser beam 122 from the single crystal semiconductor layer 115 side. The scanning of the laser beam 122 is conducted, for example, by moving the supporting substrate to which the single crystal semiconductor layer 115 is fixed, instead of moving the laser beam 122. An arrow 123 denotes the movement direction of the supporting substrate 100.

When the laser beam 122 is delivered, the single crystal semiconductor layer 115 absorbs the laser beam 122, and the temperature of a portion irradiated with the laser beam 122 is increased depending on the energy density of the laser beam 122, and thus partial melting begins to occur from the surface of the single crystal semiconductor layer 115. By movement of the supporting substrate 100, a portion irradiated with the laser beam 122 is moved, and thus the temperature of the melted portion of the single crystal semiconductor layer 115 is decreased. The melted portion is solidified and recrystallized. By irradiation with the laser beam 122 to melt the single crystal semiconductor layer 115 and scanning with the laser beam 122, the entire surface of the single crystal semiconductor layer 115 is irradiated with the laser beam 122. FIG. 4C is a cross-sectional view of the semiconductor substrate 10 after the laser irradiation process. The single crystal semiconductor layer 116 is the single crystal semiconductor layer 115 which is recrystallized. In addition, an appearance view of FIG. 4C is illustrated in FIG. 1.

The single crystal semiconductor layer 116 which has been subjected to laser irradiation process has crystallinity higher than the single crystal semiconductor layer 115, since the single crystal semiconductor layer 116 is obtained by melting and recrystallizing the single crystal semiconductor layer 115. In addition, planarity can be improved by the laser irradiation process. The crystallinity of the single crystal semiconductor layer can be evaluated by observation using an optical microscope, and a Raman shift, a full width at half maximum (FWHM) or the like obtained from a Raman spectroscopic spectrum. In addition, the planarity of the surface of the single crystal semiconductor layer can be evaluated by observation using an atomic force microscope, for example.

As one feature of the present invention, a region of the single crystal semiconductor layer 115 is partially melted with the laser beam from the single crystal semiconductor layer 115 side. In addition, to partially melt the single crystal semiconductor layer 115 means that the depth of the single crystal semiconductor layer 115 that is melted is shallower than that of the interface with the bonding layer 114 (thickness of the single crystal semiconductor layer 115), namely, the surface and a certain region in the thickness direction of the single crystal semiconductor layer 115 are melted. In other words, the “partially melted state” in the single crystal semiconductor layer 115 means that an upper layer of the single crystal semiconductor layer 115 is melted to be in a liquid phase and a bottom layer thereof is solid, without being melted.

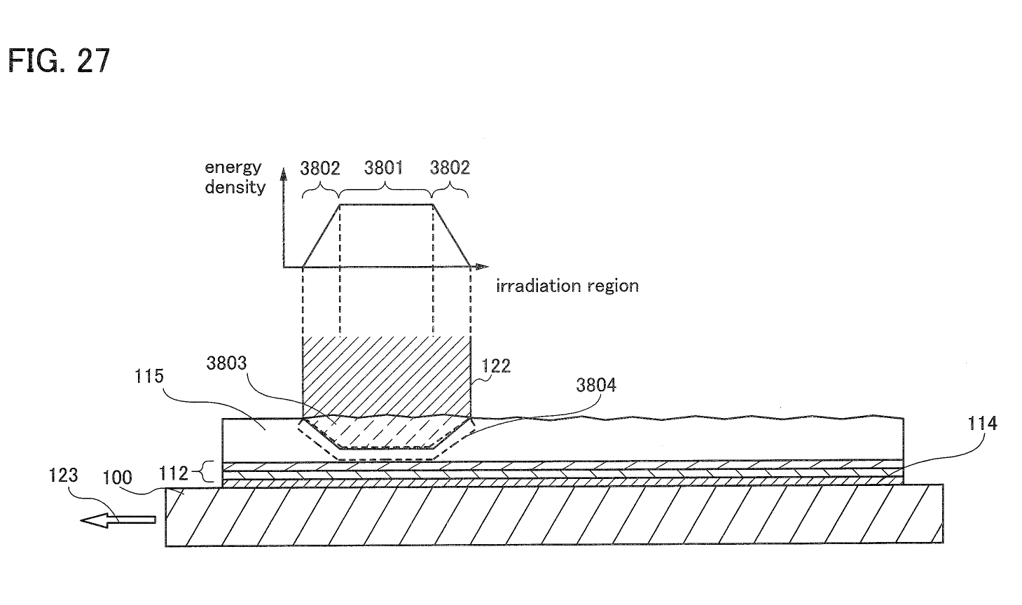

With reference to a schematic view illustrated in FIG. 27, partially melting of the single crystal semiconductor layer 115 which is one feature of the present invention is described. In FIG. 27, the bonding layer 114 and the single crystal semiconductor layer 115 are stacked, and the surface of the single crystal semiconductor layer 115 is irradiated with the laser beam 122. The profile of the laser beam 122 is a top-flat shape obtained by an optical system, and includes a region 3801 having a high energy density and a region 3802 having an energy density descending from the region 3801 having a high energy density toward an edge of the irradiation region of the laser beam 122. Therefore, as for the depth to which the single crystal semiconductor layer 115 is melted in the portion irradiated with the laser beam 122, a part irradiated with the laser beam 122 having the region 3801 having a high energy density is melted deeper from the surface, and a part irradiated with the laser beam 122 having the region 3802 having an energy density descending from the region 3801 having a high energy density toward the edge of the irradiation region of the laser beam 122 is melted depending on the energy density. Note that the melting of the single crystal semiconductor layer 115 by laser irradiation progresses in the depth direction from the surface of the single crystal semiconductor layer 115. In addition, in FIG. 27, a region including a melted layer of the single crystal semiconductor layer 115 is referred to as a liquid-phase region 3803, and a solid-phase layer of the single crystal semiconductor layer 115, which remains solid without being melted, between the liquid-phase region 3803 and the bonding layer 114 is referred to as a solid-phase region 3804.

In FIG. 27, a plurality of projections exist on the surface of the single crystal semiconductor layer 115 due to separation from the single crystal semiconductor substrate, and thus planarity is impaired, before the single crystal semiconductor layer 115 is irradiated with the laser beam 122. By conducting laser irradiation from the single crystal semiconductor layer 115 side, the single crystal semiconductor layer 115 is melted depending on the energy density of the laser beam. By melting of the single crystal semiconductor layer 115, the liquid-phase region 3803 including the melted layer of the single crystal semiconductor layer 115 and the solid-phase region 3804 in which the single crystal semiconductor layer 115 is solid without being melted, are formed. In this manner, the single crystal semiconductor layer 115 is partially melted. Partial melting of the single crystal semiconductor layer 115 may be done such that the liquid-phage region 3803 is formed so as not to reach the interface with the bonding layer 114, in the part irradiated with the laser beam 122 having the region 3801 having a high energy density of the portion irradiated with the laser beam. In other words, the partial melting of the single crystal semiconductor layer 115 may be done such that the solid-phase region 3804 of the single crystal semiconductor layer 115, in which it is not melted, is in contact with the interface with the bonding layer 114, in the part irradiated with the laser beam having a highest energy density. In the partial melting of the single crystal semiconductor layer 115, at least the surface of the single crystal semiconductor layer 115 becomes a liquid because melting progresses from the surface of the single crystal semiconductor layer 115. Therefore, the plurality of projections existing on the surface of the single crystal semiconductor layer 115 are deformed so as to have the minimum surface area by the action of surface tension. Namely, the liquid-phase region 3803 is deformed to have no depressions and projections, i.e., becomes flat, and the liquid portion is solidified and recrystallized, so that the surface of the single crystal semiconductor layer 115 can be planarized.

The surface of the single crystal semiconductor layer 116 is planarized, whereby the thickness of a gate insulating film which is formed over the single crystal semiconductor layer 116 can be thinned to approximately 5 nm to 50 nm. Accordingly, a transistor having high on current can be formed while its gate voltage is suppressed.

As illustrated in FIG. 27, in the partially-melted state in which the liquid-phase region 3803 including the melted layer of the single crystal semiconductor layer 115 and the solid-phase region 3804 in which the single crystal semiconductor layer 115 is solid without being melted are formed, when the liquid-phase region 3803 is solidified from the supporting substrate 100 side, crystals are grown based on the plane orientation of the main surface of the single crystal semiconductor substrate which is a base of the solid-phase region 3804. In this crystal growth, recrystallization progresses from the single crystal semiconductor layer having a crystal state in the solid-phase region 3804 which is not melted. In the liquid-phase region 3803 to be recrystallized, crystals are grown based on the plane orientation of the single crystal semiconductor layer in the solid-phase region 3804 which is not melted by irradiation with the laser beam 122. Therefore, the liquid-phase region 3808 is recrystallized with uniform plane orientation, thus grain boundaries are not produced, and thus the single crystal semiconductor layer 116 which has been irradiated with the laser beam can be a single crystal semiconductor layer having no crystal grain boundaries. Thus, in a case where a single crystal silicon wafer whose main surface has a plane orientation of (100) is used as the single crystal semiconductor substrate 110, the plane orientation of the main surface of the single crystal semiconductor layer 115 is (100), and the plane orientation of the main surface of the single crystal semiconductor layer 116 which is partially melted by laser irradiation and recrystallized, is (100). As a result, planarity of the surface is improved as compared with the single crystal semiconductor layer 115 before the laser irradiation, and the single crystal semiconductor layer which is recrystallized without crystal grain boundaries can be obtained.

If the liquid-phase region 3803 and the solid-phase region 3804 are both melted by the irradiation with the laser beam 122, crystals are grown in disordered crystal orientation in recrystallization of the single crystal semiconductor layer 115 due to disordered nucleation in the single crystal semiconductor layer 115 in the liquid-phase state, and the single crystal semiconductor layer 115 becomes aggregation of micro crystals, which is not preferable.

In such a way, this embodiment mode discloses an innovative technique on a method for obtaining better single crystal by irradiating a single crystal semiconductor layer with a laser beam, and melting a part of the single crystal semiconductor layer to be recrystallized based on the plane orientation of another part of the single crystal semiconductor layer which is not melted. The usage method of such a laser beam is not assumed in a conventional technique and is an extremely new concept.

When the laser beam 122 is delivered, the single crystal semiconductor layer 115 fixed to the supporting substrate 100 may be heated, whereby the temperature of the single crystal semiconductor layer 115 can be increased. The heating temperature of the supporting substrate 100 can be 230° C. or higher and a strain point of the supporting substrate or lower. The heating temperature is preferably 400° C. or higher, more preferably, 450° C. or higher. Specifically, the heating temperature is preferably from 400° C. to 670° C., more preferably, from 450° C. to 650° C.

The single crystal semiconductor layer is heated, and thus micro defects such as crystal defects in the single crystal semiconductor layer can be eliminated, whereby a better single crystal semiconductor layer can be obtained. Thus, by using the semiconductor substrate 10 to which the single crystal semiconductor layer 116 having almost no crystal defects is fixed, a transistor with high on current and high electron field-effect mobility can be formed.

The present inventors have confirmed that the single crystal semiconductor layer 115 is melted by being irradiated with the laser beam 122. Further, the present inventors also have confirmed that the crystallinity of the single crystal semiconductor layer 115 can be improved by irradiation with the laser beam 122 to the same degree as the single crystal semiconductor substrate 110 before the process. Further, the present inventors also have confirmed that planarization of the surface of the single crystal semiconductor layer 115 can be possible.

First, melting of the single crystal semiconductor layer 115 by the laser beam 122 is described.

In this embodiment mode, the glass substrate to which the single crystal silicon layer separated from the single crystal silicon wafer is attached is formed, the single crystal semiconductor layer attached to the glass substrate is irradiated with a laser beam, and the melting time of the single crystal silicon layer is measured by a spectroscopic method. Specifically, a region of the single crystal silicon layer irradiated with a laser beam is irradiated with probe light, and change in intensity of reflected light thereof is measured. It can be determined from the intensity of reflected light whether the single crystal semiconductor layer is in a solid state or in a liquid state. When silicon changes from a solid state into a liquid state, the refractive index thereof is drastically increased and the reflectance of visible light is drastically increased. Thus, a laser beam having a wavelength of a visible light region is used as probe light, and a change in intensity of reflected light of the probe light is measured. Accordingly, a phase change of the single crystal silicon layer from a solid phase to a liquid phase and a phase change from a liquid phase to a solid phase can be detected.

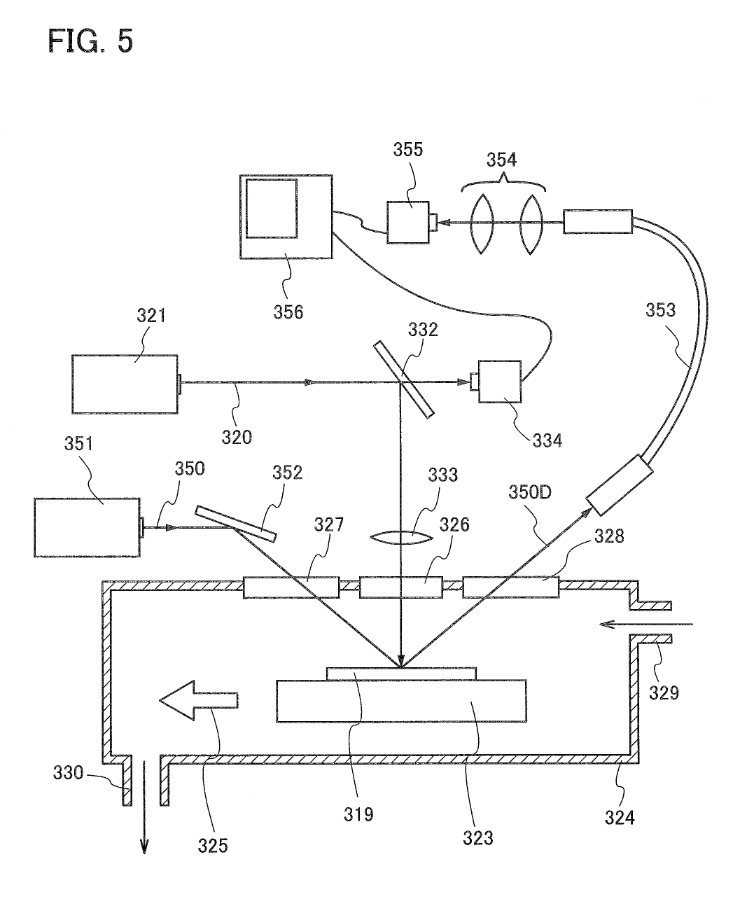

First, a structure of a laser irradiation apparatus used for measurement is described with reference to FIG. 5. FIG. 5 is a drawing for description of the structure of the laser irradiation apparatus used for the measurement. The laser irradiation apparatus includes a laser 321 that emits a laser beam 320 so as to perform a laser irradiation process on an object 319, a laser 321 that emits probe light 350, and a chamber 324 provided with a stage 323 in which an object 319 is arranged.

The stage 323 is provided so that the stage 323 can move inside the chamber 324. An arrow 325 is an arrow that shows a direction of movement of the stage 323. Windows 326 to 328 formed of quartz are provided on the wall of the chamber 324. The window 326 is a window through which the laser beam 320 enters the chamber 324. The window 327 is a window through which the probe light 350 enters the chamber 324, and the window 328 is a window through which the probe light 350 reflected by the object 319 goes to the outside of the chamber 324. In FIG. 5, the probe light 350 that is reflected by the object 319 is denoted by a reference numeral 350D.

In order to control an atmosphere inside the chamber 324, the chamber 324 is provided with a gas supply port 329 connected to a gas supply device and an exhaust port 330 coupled with an exhaust system.

The laser beam 320 which is emitted from the laser 321 is reflected by a half mirror 332, is converged by a lens 333, passes through the window 326, and is delivered to the object 319 over the stage 323. A photodetector 334 is arranged on a transmission side of the half mirror 332. Intensity variation of the laser beam 320 emitted from the laser 321 is detected by the photodetector 334.

The probe light 350 emitted from the laser 351 is reflected by a mirror 352, passes through the window 327, and is delivered to the object 319. A region irradiated with the laser beam 320 is irradiated with the probe light 350. The probe light 350D reflected by the object 319 passes through the window 328 and an optical fiber 353, is made to be a parallel beam by a collimator 354 having a collimator lens, and enters a photodetector 355. Intensity variation of the probe light 350D is detected by the photodetector 355.

The outputs of photodetectors 334 and 355 are connected to an oscilloscope 356. The voltage value (intensity of signal) of an output signal of the photodetector 334 input to the oscilloscope 356 corresponds to the intensity of the laser beam 320, and the voltage value (intensity of signal) of an output signal of the photodetector 355 input to the oscilloscope 356 corresponds to the intensity of the probe light 350D.

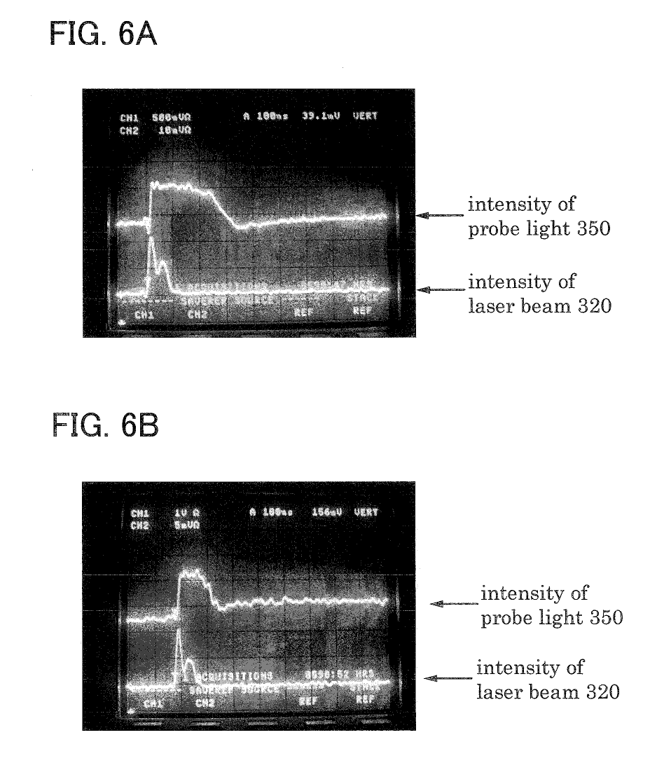

FIGS. 6A and 6B are photographs of signal waveforms of the oscilloscope 356, which show measurement results. In the photographs of FIGS. 6A and 6B, the lower signal waveform is an output signal waveform of the photodetector 334 and shows the intensity variation of the laser beam 320. The upper signal waveform is an output signal waveform of the photodetector 355 and shows the intensity variation of the probe light 350D reflected by the single crystal silicon layer. A horizontal axis of each of FIGS. 6A and 6B denotes time, and the scale is marked in 100 nanoseconds. FIG. 6A shows a signal waveform when the glass substrate is heated to 420° C., while FIG. 6B shows a signal waveform when the glass substrate is not heated and is at room temperature.

For the laser 321 used for the measurement, a XeCl excimer laser that emits a beam having a wavelength of 308 nm is used. The pulse width is 25 nanoseconds, and the repetition rate is 30 Hz. Meanwhile, for the laser 351 for the probe light, an Nd:YVO₄ laser is used, and a 532-nm beam that is a second harmonic of the laser is used for the probe light 350. In addition, a nitrogen gas is supplied from the gas supply port 329, and an atmosphere of the chamber 324 is a nitrogen atmosphere. In addition, heating of the glass substrate to which the single crystal silicon layer is fixed is performed by a heating device which is provided for the stage 323. The energy density of the laser beam 320 when measurement in FIGS. 6A and 6B is performed is 539 mJ/cm², and the single crystal silicon layer is irradiated with one shot of the laser beam 320. Note that, in FIGS. 6A and 6B, although there are two peaks in the output signal of the photodetector 334 corresponding to the laser beam 320, this is caused by the specification of the laser 321 used for the measurement, and one shot of the laser beam 320 is used for irradiation.

As shown in FIGS. 6A and 6B, when irradiation with the laser beam 320 is performed, the intensity of the probe light 350D rises and rapidly increases. In other words, it is observed that the single crystal silicon layer is melted by irradiation with the laser beam 320. The intensity of the probe light 350D rises to the maximum depth of the melted region of the single crystal silicon layer, and a high intensity state is kept for a while. When the intensity of the laser beam 320 decreases, the intensity of the probe light 350D starts decreasing some time later.

That is, FIGS. 6A and 6B show that, when irradiation with the laser beam 320 is performed, the single crystal silicon wafer is melted, a melting state is kept for a while after irradiation with the laser beam 320, and the single crystal silicon wafer starts solidifying some time after, thereby turning to a solid phase state completely.

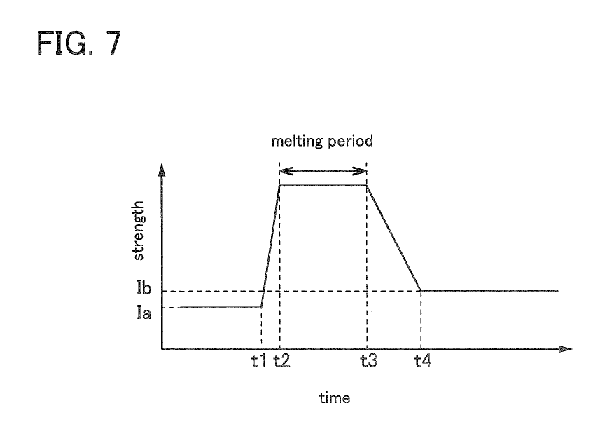

The intensity variation of the probe light 350D and a phase change of the single crystal silicon layer are described with reference to FIG. 7. FIG. 7 is a graph which schematically shows an output signal waveform of the photodetector 355 that is shown by photographs of FIGS. 6A and 6B. The signal strength rapidly increases at time t1, and the time t1 is a time when the single crystal silicon layer starts melting. After the time t1, the period from time t2 to time t3 is substantially constant and is a period when a melting state is kept. In addition, the period from the time t1 to the time t2 is a period when the depth of a melting portion of the single crystal silicon layer is increased and is a melting period. The time t3 when the signal strength starts decreasing is solidification start time when the melting portion starts solidifying.

After the time t3, the signal strength decreases gradually and is substantially constant after time t4. At the time t4, although the surface at which the probe light 350D is reflected is completely solidified, the melting portion remains inside. In addition, since the signal strength Ib after the time t4 is higher than the signal strength Ia before the time t1, it is thought that recovery of a crystal defect due to dislocation or the like progresses while the region irradiated with the laser beam 320 after the time t4 is cooled gradually.

When the signal waveforms of FIGS. 6A and 6B are compared, it is found that melting time in which the melting state is kept can be lengthened by heating. In the case where the heating temperature is 420° C., the melting time is about 250 nanoseconds, and melting time in the case where heating is not performed is about 100 nanoseconds.

The samples used for measurement of phase change of the single crystal semiconductor layer illustrated in FIGS. 6A and 6B are samples which are manufactured through the steps of FIGS. 3A to 4A. A single crystal silicon wafer is used for the single crystal semiconductor substrate 110 and a glass substrate is used for the supporting substrate 100. A two-layer-stacked insulating film is formed over the single crystal silicon wafer as the insulating layer 112 by a PECVD method, and the two-layer-stacked insulating film includes a 100-nm-thick silicon oxynitride film and a 50-nm-thick silicon nitride oxide film. A process gas for the silicon oxynitride film is SiH₄ and N₂O and a process gas for the silicon nitride oxide film is SiH₄, NH₃, N₂O and H₂.

After the two-layer-stacked insulating layer 112 is formed, an ion doping apparatus is used and the single crystal silicon wafer is doped with hydrogen ions to form the damaged layer 113. As a source gas, a 100% hydrogen gas is used, and ionized hydrogen is not mass-separated and is accelerated by electric field to be added into the single crystal semiconductor substrate 110 so that the damaged layer 113 is formed. In addition, the depth at which the damaged layer 113 is formed is adjusted such that the thickness of the single crystal silicon layer separated from the single crystal silicon wafer is 120 nm.

Then, the bonding layer 114 of a 50-nm-thick silicon oxide film is formed over the insulating layer 112 by a PECVD method. As a process gas of the silicon oxide film, TEOS and O₂ are used.

The glass substrate and the single crystal silicon wafer provided with the insulating layer 112, the damaged layer 113 and the bonding layer 114 are subjected to ultrasonic cleaning in pure water, and then to pure water containing ozone. Next, as illustrated in FIG. 4A, the glass substrate and the single crystal silicon wafer are brought into close contact such that the bonding layer 114 and the glass substrate are bonded to each other, and then as illustrated ion FIG. 4A, the single crystal silicon wafer is separated along the damaged layer 113 and the glass substrate to which the single crystal silicon layer is attached is obtained. This glass substrate is used as a sample.

Next, description is made on recovery of crystallinity of the single crystal semiconductor layer 115 to the same degree as the single crystal semiconductor substrate 110 before the process and planarization of the single crystal semiconductor layer 115 by melting the single crystal semiconductor layer 115 by irradiation with the laser beam 122 to be recrystallized. The crystallinity of the single crystal semiconductor layer after the process is evaluated using a Raman spectrometer, and the planarity of the surface is evaluated by images (hereinafter referred to as DFM images) observed with a dynamic force mode (DFM) by an atomic force microscope (AFM), or the measurement values showing surface roughnesses obtained from the DFM images.

The samples used for the measurement are samples formed in the same manner as those in FIGS. 6A and 6B, and is a glass substrate to which the single crystal silicon layer is attached. The apparatus illustrated in FIG. 5 is used for the laser irradiation, and a XeCl excimer laser which emits a beam with a wavelength of 308 nm is used as a laser 321 for recrystallization. The pulse width is 25 nsec and the repetition rate is 30 Hz. In addition, the laser irradiation is conducted when a nitrogen gas is supplied from the gas supply port and thus the atmosphere of the chamber 324 is a nitrogen atmosphere. In addition, heating of the glass substrate to which the single crystal silicon layer is fixed is conducted by a heating device provided for the stage 323. In addition, the movement speed of the stage 323 is adjusted such that 12 shots of laser beams can be delivered to the same region.

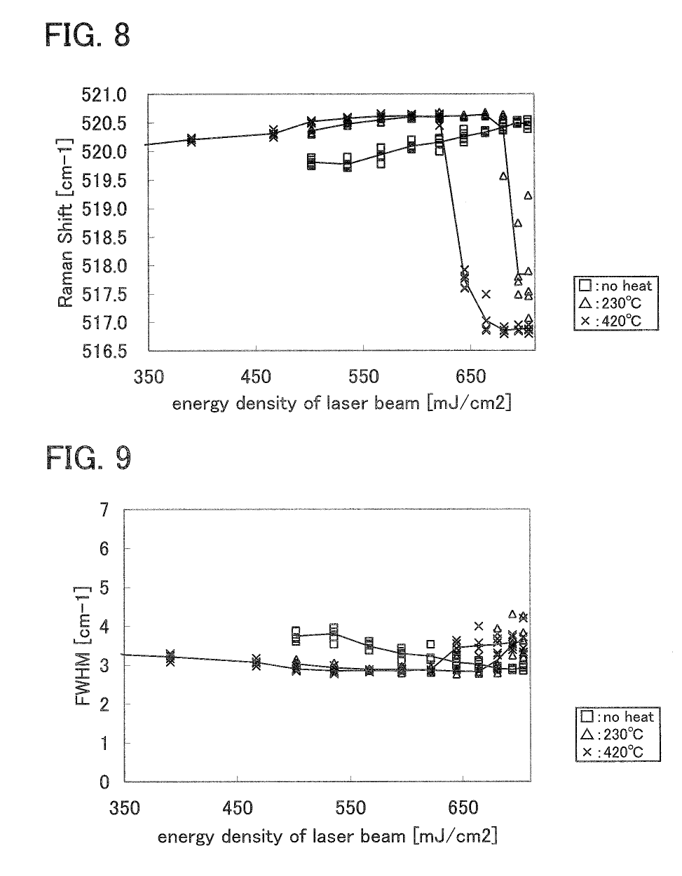

FIG. 8 is a graph showing a Raman shift of a laser beam with respect to an energy density. As the wavenumber of the Raman shift of the silicon layer is closer to 520.6 cm⁻¹ that is the wavenumber of the Raman shift of single crystal silicon, the single crystal silicon layer has a higher crystallinity. FIG. 9 is a graph showing a shift of full width at half maximum (FWHM) of the Raman shift with respect to the energy density of the laser beam. The FWHM of a commercial single crystal silicon wafer is approximately 2.5 cm⁻¹ to 3.0 cm⁻¹, and an object having a value closer to this value can have excellent crystallinity.

FIG. 8 and FIG. 9 show data in the case where the glass substrate to which the single crystal silicon layer is attached is not heated during the laser irradiation process, the case where the glass substrate is heated at 420° C. in the laser irradiation process, and the case where the glass substrate is heated at 230° C. in the laser irradiation process.

From FIG. 8 and FIG. 9, it can be seen that in the case where the substrate is not heated, laser irradiation is conducted with high energy density and the Raman shift can be increased to the same degree as the wavenumber 520.6 cm of the Raman shift and FWHM can be decreased to about 2.5 cm⁻¹ to 3.0 cm⁻¹. Further, it is confirmed that also in the cases where the glass substrate is irradiated while is heated at 420° C. or 230° C., crystallinity in the same degree as the single crystal silicon wafer before the process can be recovered by recrystallization of the single crystal silicon layer. By conducting laser irradiation while heating, the energy density of the laser beam for the laser irradiation can be reduced. Note that when laser irradiation is conducted while heating, the energy density of the laser beam should be controlled so as to partially melt the single crystal semiconductor layer. If the energy density of a laser beam delivered to the single crystal semiconductor layer is higher than the energy density of the laser beam for partially melting, the single crystal semiconductor layer may be melted completely unfortunately. Thus, since crystals are grown in disordered crystal orientation in recrystallization of the semiconductor layer, the Raman shift and FWHM are both shifted to bad states of crystallinity as illustrated in FIG. 8 and FIG. 9. Note that as illustrated in FIG. 8 and FIG. 9, as the heating temperature of the substrate is higher, the single crystal semiconductor layer is easier to be melted completely due to the high energy density of the laser beam. Therefore, in laser irradiation without heating the substrate, even if more or less variation in energy density of the laser beam for irradiation is seen, crystallinity can be increased without causing crystal growth in disordered crystal orientation of the single crystal semiconductor layer.

From the data of FIG. 8 and FIG. 9, in the case where the substrate is not heated, by increasing the energy density of the laser beam, crystallinity of the single crystal semiconductor layer can be increased. Further, irradiation with the laser beam 122 is conducted while the single crystal semiconductor layer 115 is being heated, the energy density of the laser beam required for recovery of the crystallinity of the single crystal semiconductor layer 115 can be reduced. By conducting laser irradiation while the single crystal semiconductor layer is being heated, deterioration of a laser medium of the laser which emits the laser beam 122 can be suppressed, and thus maintenance cost of the laser can be suppressed. Further, for example, when the cross sectional shape of the laser beam is a linear shape or a rectangular shape (a shape including a square shape, an oblong shape and the like), the length of the cross sectional shape can be increased and thus the region which can be irradiated with one time of scanning of the laser beam 122 can be enlarged, and thereby productivity can be improved.

It is thought that one reason why the energy density of the laser beam 122 which is needed for recovery of crystallinity of the single crystal semiconductor layer 115 is reduced by heating of the single crystal semiconductor layer 115 is that the melting time of the single crystal semiconductor layer 115 is increased by heating, and thus the melting time is longer, as shown in FIGS. 6A and 6B. Another reason is thought to be that the time from a state that the single crystal semiconductor layer 115 has a melting portion (a liquid phase portion) to a state that it is completely solidified (solid phase state) by cooling is increased, because heat release is suppressed by heating the substrate in advance.

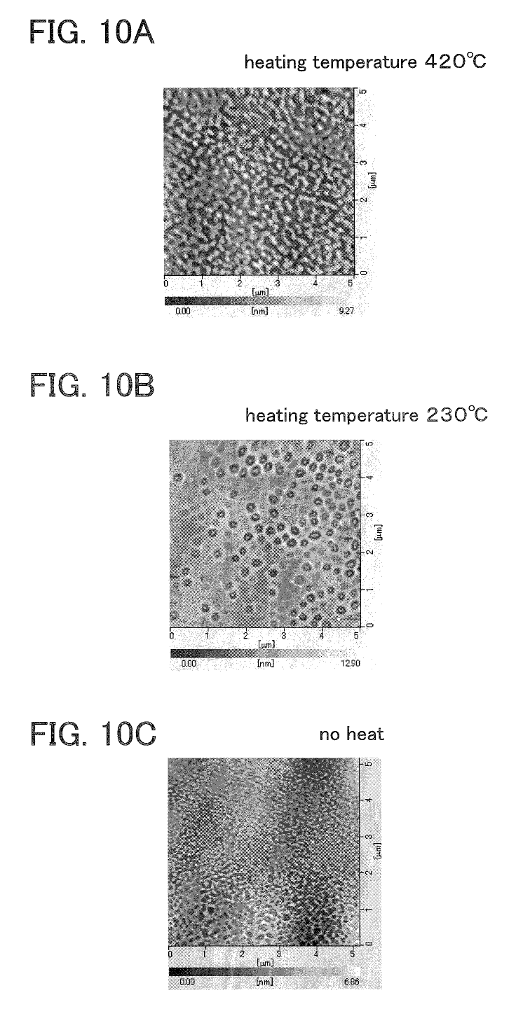

Hereinafter, planarization of the single crystal semiconductor layer by laser irradiation is described. FIGS. 10A to 10C are DFM images of the top layers of the single crystal silicon layers observed by AFM. FIG. 10A is an image in the case where laser irradiation is conducted while the single crystal semiconductor layer is being heated at 420° C., FIG. 10B is an image in the case where laser irradiation is conducted while the single crystal semiconductor layer is being heated at 230° C., and FIG. 10C is an image in the case where laser irradiation is conducted without heating the single crystal semiconductor layer. The observed regions are each 5 μm square.

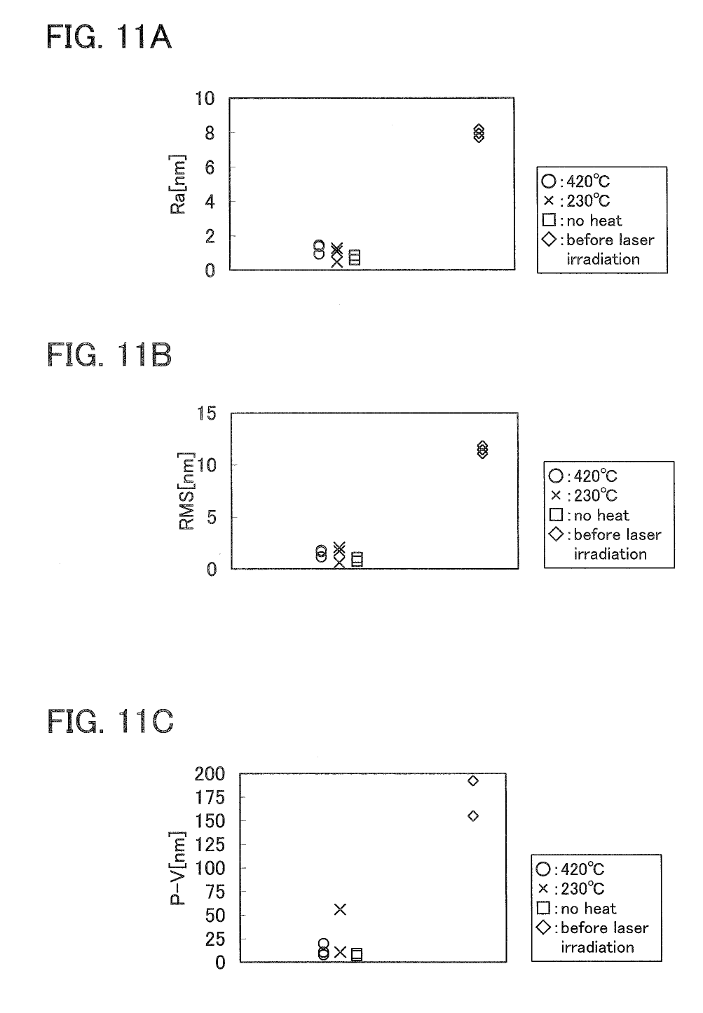

FIGS. 11A to 11C show roughness of the surfaces of the single crystal silicon layers which are calculated from the DFM images obtained by AFM. FIG. 11A shows average surface roughness, Ra, FIG. 11B shows a root mean square of surface roughness, Rms, and FIG. 11C shows the largest difference in height between peak and valley, P−V FIGS. 11A to 11C also show data of single crystal silicon layers before laser irradiation.

As shown in FIGS. 11A to 11C, planarity of a single crystal silicon layer can be improved by being melted by laser irradiation, either when substrate is heated or when the substrate is not heated.

From data of FIGS. 11A to 11C, the surface of the single crystal semiconductor layer 116 which has been recrystallized by being melted with irradiation with the laser beam 122 is planarized and the average roughness of uneven shape in the surface is from 1 nm to 2 nm. In addition, the root mean square of surface roughness of the uneven shape can be from 1 nm to 4 nm. In addition, the largest difference in height between peak and valley, P−V of the uneven shape is from 5 nm to 100 nm. In other words, one advantageous effect of the irradiation with the laser beam 122 is to planarize the single crystal semiconductor layer 115.

As planarization treatment, chemical mechanical polishing (abbreviation: CMP) is known. However, a glass substrate is easily bent and has undulation, and in the case where a glass substrate is used for the supporting substrate 100, it is difficult to perform planarization treatment on the single crystal semiconductor layer 115 by CMP. In this embodiment mode, this planarization treatment is performed by irradiation with the laser beam 122; therefore, without applying force that damages the supporting substrate 100 and without heating the supporting substrate 100 at temperature exceeding a strain point, planarization of the single crystal semiconductor layer 115 is enabled. Accordingly, a glass substrate can be used for the supporting substrate 100. That is, this embodiment mode discloses an innovative usage method of irradiation with a laser beam in a method for manufacturing a semiconductor substrate.

The average surface roughness (Ra) means an average surface roughness obtained by three-dimensionally expanding a centerline average roughness Ra that is defined by JISB0601:2001 (ISO4287:1997) so as to be able to apply the Ra to a measurement surface. In the JISB0601:2001, Ra is defined as a centerline average roughness Ra, but in this specification, Ra means only average roughness. In this case, the average roughness is expressed by an average value from absolute values of deviations between a reference surface and a specific surface, and is obtained from the following expression.

$${R}_{a} = \frac{1}{{S}_{0}} {\int }_{{Y}_{1}}^{{Y}_{2}} {\int }_{{X}_{1}}^{{X}_{2}} \vert f ( X , Y ) - {Z}_{0} \vert d X d Y \qquad [ formula 1 ]$$

The measurement surface is a surface which is shown by the all measurement data, and is calculated by the following expression. In this case, the measurement data consists of three parameters (X, Y, Z), and the range of X (and Y) is from 0 to Xₘₐₓ (and Yₘₐₓ), and the range of Z is from Zₘᵢₙ to Zₘₐₓ.

Z=f(X,Y) [formula 2]

The specific surface is a surface which is an object of roughness measurement, and is a rectangular region within four points represented by the coordinates (X₁, Y₁), (X₁, Y₂), (X₂, Y₁), and (X₂, Y₂). The area of the specific surface is referred to as S₀ when the specific surface is flat ideally. Note that S₀ is calculated from the following expression.

S₀=(X₂−X₁)·(Y₂−Y₁) [formula 3]

The reference surface is a plane surface represented by Z=Z₀ when the mean value of the height of the specific surface is referred to as Z₀. The reference surface is parallel to the XY plane. Note that Z₀ is calculated from the following expression.

$${Z}_{0} = \frac{1}{{S}_{0}} {\int }_{{Y}_{1}}^{{Y}_{2}} {\int }_{{X}_{1}}^{{X}_{2}} f ( X , Y ) d X d Y \qquad [ formula 4 ]$$

The root mean square of surface roughness (Rms) means the root mean square obtained by three-dimensionally expanding the Rms of a cross section curve. The Rms is the square root of the mean value of the square of the deviation from the reference surface to the specific surface, and is obtained from the following expression.

$${R}_{ms} = \sqrt{\frac{1}{{S}_{0}} {\int }_{{Y}_{1}}^{{Y}_{2}} {\int }_{{X}_{1}}^{{X}_{2}} {\{ f ( X , Y ) - {Z}_{0} \}}^{2} d X d Y} \qquad [ formula 5 ]$$

In this embodiment mode, the largest difference in height between peak and valley (P−V) is not used as an evaluation parameter, but it may be used an evaluation parameter. The largest difference in height between peak and valley (P−V) is a difference between the height of the highest peak Zₘₐₓ and the height of the lowest valley Zₘᵢₙ in the specific surface, and is obtained from the following expression.

P−V=Zₘₐₓ−Zₘᵢₙ [Formula 6]

In the largest difference in height between peak and valley (P−V), the peak and the valley mean the peak and the valley obtained by three-dimensionally expanding the peak and the valley defined by JISBO 601:2001(ISO4287:1997). The peak is the highest place of the peaks in the specific surface, while the valley is the lowest place of the peaks in the specific surface.

Measurement conditions of the average surface roughness Ra, the root mean square of surface roughness Rms, and the largest difference in height between peak and valley P−V are described below.

Atomic force microscope (AFM): a scanning probe microscope SPI3800N/SPA500 manufactured by Seiko Instruments Inc.

Measurement mode: dynamic force mode (DFM)

Cantilever: SI-DF40 (made of silicon, a spring constant of 40 N/m to 45 N/m, a resonant frequency of 250 kHz to 390 kHz, and a probe tip of R≦10 nm)

Scan rate: 1.0 Hz

Measured points: 256 points×256 points

Note that DFM refers to a measurement mode in which the shape of a surface of a sample is measured in a state where a cantilever is resonated at a given frequency (a frequency specific to the cantilever), the cantilever intermittently contacts with a sample coming closely and a mode of a surface is shown by the vibration amplitude of the cantilever. In DFM, the surface of the sample and the cantilever are not in contact with each other; thus, measurement is possible without damaging the surface of the sample.

Note that in the evaluation of planarity in this embodiment mode, the measurement area is 20 μm×20 μm or smaller, preferably 5 μm×5 μm to 10 μm×10 μm. It is to be noted that accurate evaluation cannot be made if the measurement area is too small or too large.

As a laser that emits the laser beam 122 as described in this embodiment mode, a laser whose oscillation wavelength is in the range from the ultraviolet region to the visible light region is selected. The wavelength of the laser beam 122 is a wavelength that is absorbed in the single crystal semiconductor layer 115. The wavelength can be determined in consideration of the skin depth of the laser beam, and the like. For example, the wavelength can be in the range of greater or equal to 250 nm and less than or equal to 700 nm.

As the laser, a pulsed laser or a laser which can conduct pulse irradiation is preferably used. In the case of a pulsed laser, a repetition rate of less than 10 MHz, and a pulse width of 10 nanoseconds to 500 nanoseconds can be used. A typical pulsed laser is an excimer laser that emits a beam having a wavelength of 400 nm or less. A laser which can conduct pulse irradiation refers to a laser by which an effect similar to that produced by a pulsed laser can be obtained in a pseudo manner, by intermittently conducting irradiation with a continuous wave laser beam, and conducting laser irradiation selectively at a given frequency. As a laser, for example, a XeCl excimer laser having a repetition rate of 10 Hz to 300 Hz, a pulse width of 25 nanoseconds, and a wavelength of 308 nm can be used. In addition, in laser beam scanning, one shot and another shot (the next shot) may be partially overlapped with each other. By overlapping one shot and another shot in laser irradiation, partial refining of single crystals is repeated, and thereby a single crystal semiconductor layer having excellent characteristics can be obtained.

As the laser which emits the laser beam 122, a pulsed laser having a repetition rate less than 10 MHz is preferably used. In the present invention, if a pulsed laser having a repetition rate more than 10 MHz is used, the pulse interval becomes shorter than a time from melting of the single crystal semiconductor layer 115 to solidification thereof, and thus the single crystal semiconductor layer 115 is always kept melted. In a region irradiated with overlapped laser beams, the single crystal semiconductor layer is completely melted from the top surface to the interface with the bonding layer, to be in a liquid phase, and thereby crystal boundaries may be generated in recrystallization. For this reason, in the present invention, in the case where the surface of the single crystal semiconductor layer is irradiated with overlapped laser beams, the next laser beam is preferably delivered such that the time from melting to solidification of the single crystal semiconductor layer 116 can be extended

The range of the energy density of the laser beam 122 to partially melt the single crystal semiconductor layer 115 is such an energy density that the single crystal semiconductor layer 115 is not completely melted, in consideration of the wavelength of the laser beam 122, the skin depth of the laser beam 122, the thickness of the single crystal semiconductor layer 155 and the like. For example, when the thickness of the single crystal semiconductor layer 115 is large, the energy to completely melt the single crystal semiconductor layer 115 is also large, and thus the range of the energy density of the laser beam 122 can be wide. In addition, when the thickness of the single crystal semiconductor layer 115 is small, the energy to completely melt the single crystal semiconductor layer 115 is also small, and thus the energy density of the laser beam 122 is preferably small. Note that when the single crystal semiconductor layer 115 is irradiated with the laser beam 122 while being heated, the upper limit of the range of the energy density needed for partially melting is preferably small, because completely melting of the single crystal semiconductor layer 115 can be prevented.

It is confirmed that effects of crystallinity recovery and planarization of the single crystal semiconductor layer 115 can be exhibited even if the atmosphere for irradiation with the laser beam 122 is in an air atmosphere which is not subjected to atmosphere control or in an inert gas atmosphere that contains less oxygen. In addition, it is confirmed that an inert gas atmosphere is more preferable than an air atmosphere. An inert atmosphere such as nitrogen can improve more planarity of the single crystal semiconductor layer 116 than an air atmosphere, and provides a wide range of the energy density of the laser beam 122 to achieve reduction of defective crystals and planarity.

In order to perform irradiation with the laser beam 122 in an inert gas atmosphere, irradiation with the laser beam 122 is performed in an airtight chamber. By supply of an inert gas into this chamber, irradiation with the laser beam 122 can be performed in an inert gas atmosphere. When a chamber is not used, a surface of the single crystal semiconductor layer 115 is irradiated with the laser beam 122 while an inert gas is blown onto the irradiated surface. Accordingly, irradiation with the laser beam 122 in an inert gas atmosphere can be achieved.

An inert gas can be nitrogen (N₂) or a noble gas such as argon or xenon. In addition, the oxygen concentration of the inert gas is preferably 10 ppm or less.

It is preferable that the laser beam 122 be made to pass through an optical system so that the laser beam 122 has a linear or rectangular cross-sectional shape. The laser beam preferably has a linear or rectangular cross-sectional shape having the width in the scanning direction of 10 μm or larger Accordingly, irradiation with the laser beam 122 can be performed with high throughput. In the present invention, a surface and a certain region in the depth direction of the single crystal semiconductor layer separated from the single crystal semiconductor substrate are melted and recrystallization progresses based on the plane orientation of the single crystal semiconductor layer which is left without being melted. Even if the energy density of the laser beam varies, it is acceptable as long as the melted portion of the single crystal semiconductor layer which is irradiated with the highest energy density does not reach the interface with the bonding layer.

Before the single crystal semiconductor layer 115 is irradiated with the laser beam 122, it is preferable that an oxide film, such as a film that is naturally oxidized, which is formed on the surface of the single crystal semiconductor layer 115 be removed. This is because an effect of planarization is not sufficiently obtained even when the single crystal semiconductor layer 115 is irradiated with the laser beam 122 in a state that an oxide film remains on the surface of the single crystal semiconductor layer 115. The oxide film can be removed by treating the single crystal semiconductor layer 115 with hydrofluoric acid solution. Treatment with hydrofluoric acid is performed until when the surface of the single crystal semiconductor layer 115 has water repellency. It can be confirmed that the oxide film is removed from the single crystal semiconductor layer 115 by confirmation of water repellency.

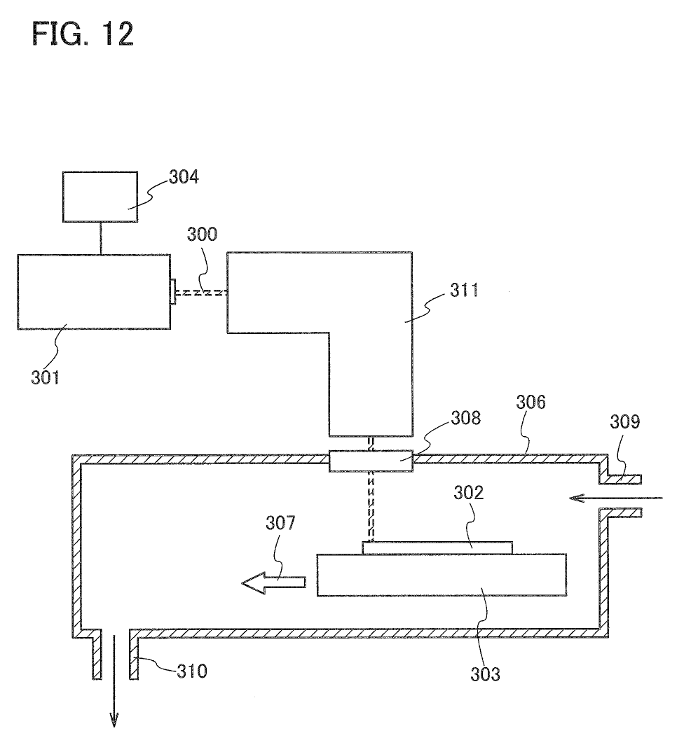

Next, a laser irradiation apparatus by which the single crystal semiconductor layer 115 is irradiated with the laser beam 122 while is being heated is described with reference to a drawing. FIG. 12 illustrates an example of a structure of a laser irradiation apparatus.

As illustrated in FIG. 12, the laser irradiation apparatus includes a laser 301 that emits a laser beam 300 and a stage 303 for arranging an object 302. A controller 304 is connected to the laser 301. By the control of the controller 304, energy of the laser beam 300 emitted from the laser 301, repetition rate, or the like can be changed. The stage 303 is provided with a heating device such as a resistance heating device or the like, and the object 302 can be heated.

The stage 303 is provided in the chamber 306 so that the stage 303 can move inside the chamber 306. An arrow 307 is an arrow that shows a direction of movement of the stage 303.

A window 308 through which the laser beam 300 goes into the chamber 306 is provided for the wall of the chamber 306. The window 308 is formed using a material having high transmittance with respect to the laser beam 300, for example quartz. In order to control an atmosphere inside the chamber 306, the chamber 306 is provided with a gas supply port 309 connected to a gas supply device and an exhaust port 310 coupled with an exhaust system.

An optical system 311 including a lens, a mirror or the like is arranged between the laser 301 and the stage 303. The optical system 311 is provided outside the chamber 306. The energy distribution of the laser beam 300 emitted from the laser 301 is uniformed by the optical system 311, and the cross-sectional shape thereof is processed into a linear shape or a rectangular shape. The laser beam 300 which have passed through the optical system 311 passes through the window 308, enters the inside of the chamber 306, and is delivered on the object 302 over the stage 303. While the object 302 is heated by a heating device of the stage 303, and the stage 303 is moved, the object 302 is irradiated with the laser beam 300. By supplying an inert gas such as a nitrogen gas through the gas supply port 309, irradiation with the laser beam 300 can be conducted in an inert gas atmosphere.

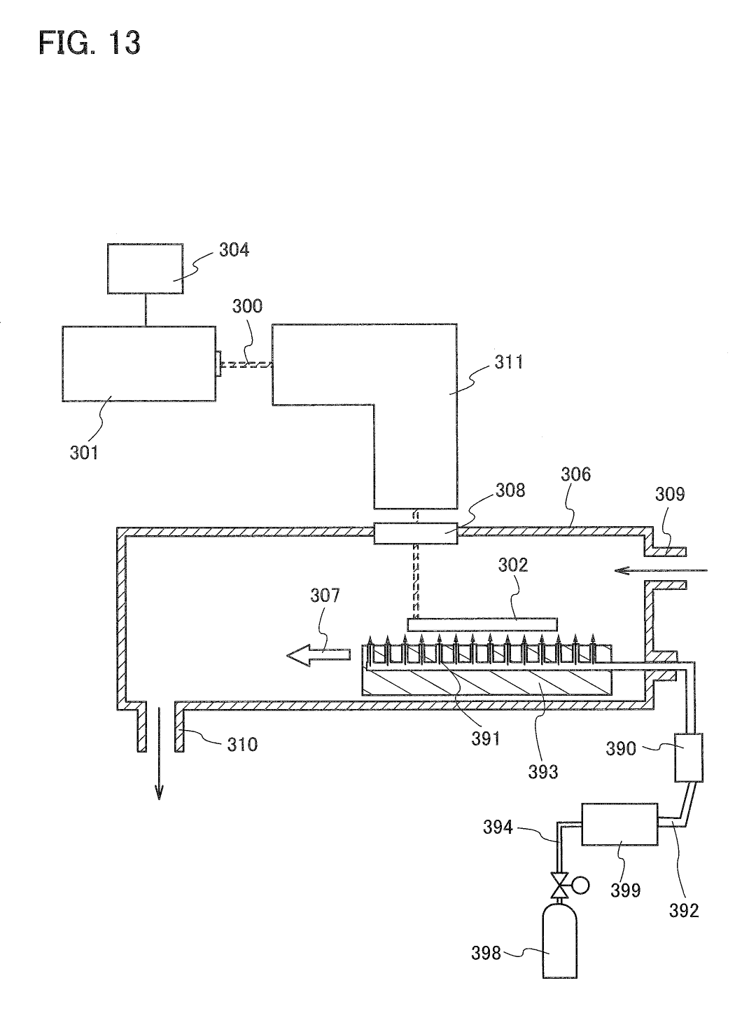

The laser irradiation apparatus illustrated in FIG. 12 is a non-limiting example, and a laser irradiation apparatus illustrated in FIG. 13 may be used. In FIG. 13, the same reference numerals are used for the same parts as those in FIG. 12. In FIG. 13, a stage 393 is exemplified, by which a supporting substrate that is an object 302 is floated and transferred. A large glass substrate has a problem in that the substrate warps due to its weight, and thus a gas flow is applied to transfer the substrate. A nitrogen gas which is stored in a gas storage device 398 is supplied to openings provided in the stage 393 by a gas supply apparatus 399. With the gas supply apparatus 399, a flow rate and pressure of the nitrogen gas are adjusted, and the nitrogen gas is supplied so that the object 302 is floated. The nitrogen gas passes through a gas heating apparatus 390 and is heated, and is supplied to the openings provided in the stage 393. Although not illustrated here, other plural gas supply apparatuses than the gas supply apparatus 399 are provided, and openings connected to the gas supply apparatuses are provided separately for the stage 393, and flow rates to the openings are adjusted, thereby moving the object 302. By blowing a gas to the object 302, the object 302 is cooled, and thus preferably, by using a gas heated by passing through the gas heating apparatus 390, the object 302 is floated or moved. In addition, gases blown from the openings may be heated by heating the stage 393.

The laser irradiation illustrated in FIG. 4B can be conducted in the following manner. First, the single crystal semiconductor layer 115 is treated with a hydrofluoric acid solution diluted at a rate of 1:100 (=hydrofluoric acid:water) for 110 seconds so that the oxide film on the surface is removed. Next, the supporting substrate 100 to which the single crystal semiconductor layer 115 is attached is arranged on the stage of the laser irradiation apparatus. The single crystal semiconductor layer 115 is heated to a temperature of from 230° C. to 650° C. by a heating means such as a resistant heating device provided on the stage. For example, the heating temperature is 420° C. As the laser of the laser beam 122, a XeCl excimer laser (wavelength: 308 nm, pulse width: 25 nanoseconds, repetition rate: 60 Hz) is used. By an optical system, the laser beam 122 is shaped into a linear shape with a cross section of 300 mm×0.34 mm. The single crystal semiconductor layer 115 is scanned and irradiated with the laser beam 122. Scanning with the laser beam 122 is performed by moving the stage of the laser irradiation apparatus. The movement speed of the stage corresponds to the scan speed of the laser beam. By adjusting the scan speed of the laser beam 122, 1 to 20 shots of the laser beam 122 can be delivered to the same region of the single crystal semiconductor layer 115. The number of the shots is preferably 1 to 10. In other words, by conducting the laser irradiation in such a manner that one shot and another shot (next shot) are partially overlapped with each other, partial refining of single crystals is repeated, and thereby a single crystal semiconductor layer having excellent characteristics can be obtained.

Before the single crystal semiconductor layer 115 is irradiated with the laser beam 122, the single crystal semiconductor layer 115 can be etched. It is preferable that the damaged layer 113 which remains on the separation plane of the single crystal semiconductor layer 115 be removed by this etching. The damaged layer 113 is removed, whereby an effect of surface planarization and an effect of single recrystallization by irradiation with the laser beam 122 can be obtained more.

For this etching, a dry etching method or a wet etching method can be used. In a dry etching method, for the etching gas, a chloride gas such as boron chloride, silicon chloride, or carbon tetrachloride; a chlorine gas; a fluoride gas such as sulfur fluoride or nitrogen fluoride; an oxygen gas; or the like can be used. In a wet etching method, a tetramethylammonium hydroxide (abbreviation: TMAH) solution can be used for an etchant.

After the single crystal semiconductor layer 115 is irradiated with the laser beam 122, the single crystal semiconductor layer 116 may be etched to be thin. The thickness of the single crystal semiconductor layer 116 can be set in accordance with characteristics of an element formed from the single crystal semiconductor layer 116. In order to form a thin gate insulating layer with favorable step coverage on the surface of the single crystal semiconductor layer 116 which is attached to the supporting substrate 100, the single crystal semiconductor layer 116 preferably has a thickness of 50 nm or less and the thickness may be from 5 nm to 50 nm.

As etching for thinning the single crystal semiconductor layer 116, a dry etching method or a wet etching method can be used. In a dry etching method, for the etching gas, a chloride gas such as boron chloride, silicon chloride, or carbon tetrachloride; a chlorine gas; a fluoride gas such as sulfur fluoride or nitrogen fluoride; an oxygen gas; or the like can be used. In a wet etching method, a tetramethylammonium hydroxide (abbreviation: TMAH) solution can be used for an etchant.

Since the steps from FIGS. 3A to 3D and FIGS. 4A to 4C can be performed at temperature of 700° C. or lower, a glass substrate having an allowable temperature limit of 700° C. or lower can be used for the supporting substrate 100. Therefore, an inexpensive glass substrate can be used, whereby a material cost of the semiconductor substrate 10 can be reduced.

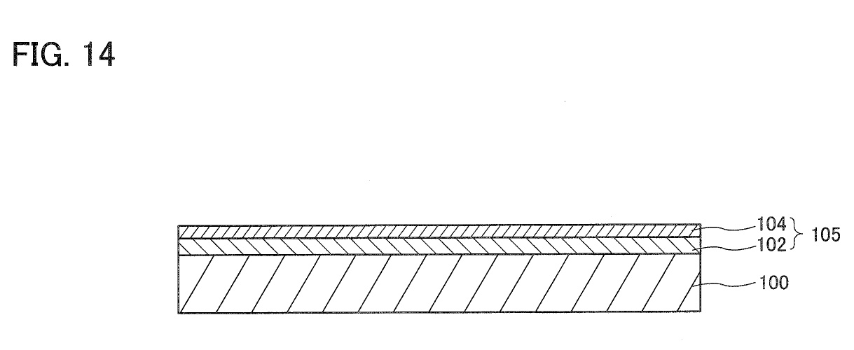

Note that the buffer layer 101 can also be formed over the supporting substrate 100. Further, an insulating layer can be formed in contact with the surface of the supporting substrate 100. FIG. 14 illustrates a cross section of the supporting substrate 100 and a multilayer film is formed as the buffer layer 101. The buffer layer 101 includes the insulating layer 112 in contact with the surface of the supporting substrate 100 and the bonding layer 114 over the insulating layer 112. It is natural that either the insulating layer 112 or the bonding layer 114 can be formed over the supporting substrate 100. The insulating layer 112 can be formed with a single layer of insulating film or a multilayer of two or more insulating films by a PECVD method. When the barrier layer is formed as the insulating layer 112, a barrier layer including a silicon nitride oxide film or a silicon nitride film is formed to be in contact with the supporting substrate 100, and a silicon oxide film or a silicon oxynitride film is formed over the barrier layer. By such a stacked structure, the single crystal semiconductor layer 116 can be prevented effectively from being contaminated with impurities.

Note that a plurality of single crystal semiconductor layers 116 can be attached to one supporting substrate 100 by the method described in this embodiment mode. A plurality of single crystal semiconductor substrates 110 having the structure illustrated in FIG. 3C are attached to the supporting substrate 100. Then, the steps illustrated in FIGS. 4A to 4C are conducted so that a semiconductor substrate 20 including the supporting substrate 100 to which the plurality of single crystal semiconductor layers 116 are attached can be manufactured.

For the supporting substrate 100, a glass substrate of 300 mm or more×300 mm or more is preferably used in order to form the semiconductor substrate 20. As a large area glass substrate, a mother glass substrate which is developed for production of liquid crystal panel is preferred. As the mother glass substrate, for example, the substrate having any of the following sizes is known: the third generation (550 mm×650 mm), the three-point-five generation (600 mm×720 mm), the fourth generation (680 mm×880 mm or 730 mm×920 mm), the fifth generation (1100 mm×1300 mm), the sixth generation (1500 mm×1850 mm), the seventh generation (1870 mm×2200 mm), the eighth generation (2200 mm×2400 mm), and the like.

A large area substrate such as a mother glass substrate is used for the supporting substrate 100, whereby an SOI substrate can have a large area. If the SOI substrate can have a large area, a plurality of chips such as ICs, LSIs or the like can be formed from one piece of SOI substrate and the number of chips formed from one piece of the substrate is increased, whereby productivity can be drastically improved.

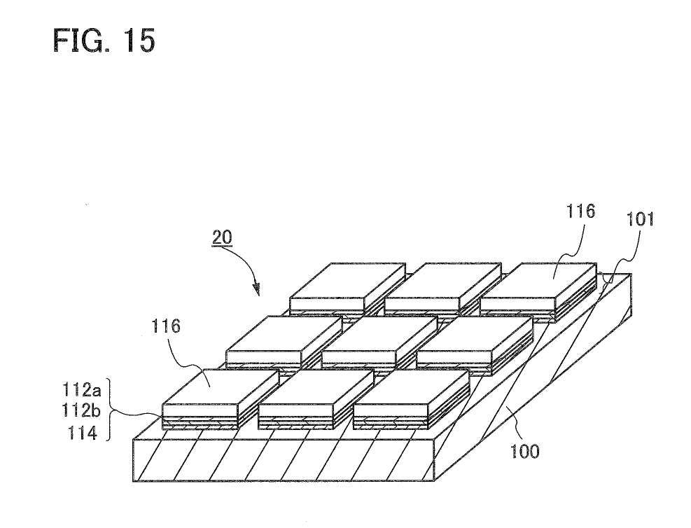

Like the semiconductor substrate 20 illustrated in FIG. 15, when a supporting substrate which easily warps and is fragile, e.g., a glass substrate, is used, it is extremely difficult to planarize the plurality of single crystal semiconductor layers attached to one supporting substrate by polishing. In this embodiment mode, the planarization is conducted by irradiation with the laser beam 122, and thereby, the supporting substrate 100 is not applied with a force to damage the baser substrate and is not heated at a temperature higher than its strain point, and further, the single crystal semiconductor layers 115 fixed on the one supporting substrate 100 can be planarized. In other words, the laser irradiation process is extremely important in manufacturing the semiconductor substrate 20 to which plural single crystal semiconductor layers are attached as illustrated in FIG. 15. Namely, this embodiment mode discloses an innovative usage method of laser irradiation.

This embodiment mode can be carried out in combination with any structure of the other embodiment modes and examples.

### Embodiment Mode 2

A single crystal semiconductor substrate 117 from which a single crystal semiconductor layer 115 has been separated can be reused as the single crystal semiconductor substrate 110 by being subjected to reprocessing treatment. In this embodiment mode, the reprocessing treatment is described.

As shown in FIG. 4A, a portion which is not attached to the supporting substrate 100 is left remaining at the periphery of the single crystal semiconductor substrate 117. Portions of the insulating film 112b, the insulating film 112a, and the bonding layer 114 which are not attached to the supporting substrate 100 remain in this portion.

First, etching treatment is performed to remove the insulating film 112a, the insulating film 112a, and the bonding layer 114. For example, when these films are formed from silicon oxide, silicon oxynitride, or silicon nitride oxide, the insulating film 112b, the insulating film 112a, and the bonding layer 114 can be removed by wet etching treatment using a hydrofluoric acid solution.

Next, the single crystal semiconductor substrate 117 is etched, thereby removing this peripheral projecting portion and the surface from which the single crystal semiconductor layer 115 has been separated. The etching treatment for the single crystal semiconductor substrate 117 is preferably wet etching treatment, and tetramethylammonium hydroxide (abbr.: TMAH) can be used as an etchant.

After the single crystal semiconductor substrate 117 is subjected to etching treatment, the surface thereof is polished and planarized. For the polishing treatment, mechanical polishing, chemical mechanical polishing (abbr.: CMP) can be used. In order to smooth the surface of the single crystal semiconductor substrate, it is preferable that the surface be polished by about 1 μm to 10 μm. After the polishing, hydrofluoric acid cleaning or RCA cleaning is performed because abrasive particles and the like are left on the surface of the single crystal semiconductor substrate.

Through the above-mentioned process, the single crystal semiconductor substrate 117 can be reused as the single crystal semiconductor substrate 110 which is shown in FIG. 2. By reuse of the single crystal semiconductor substrate 117, material cost of the semiconductor substrate 10 can be reduced.

This embodiment mode can be carried out in combination with any structure of the other embodiment modes and examples.

### Embodiment Mode 3

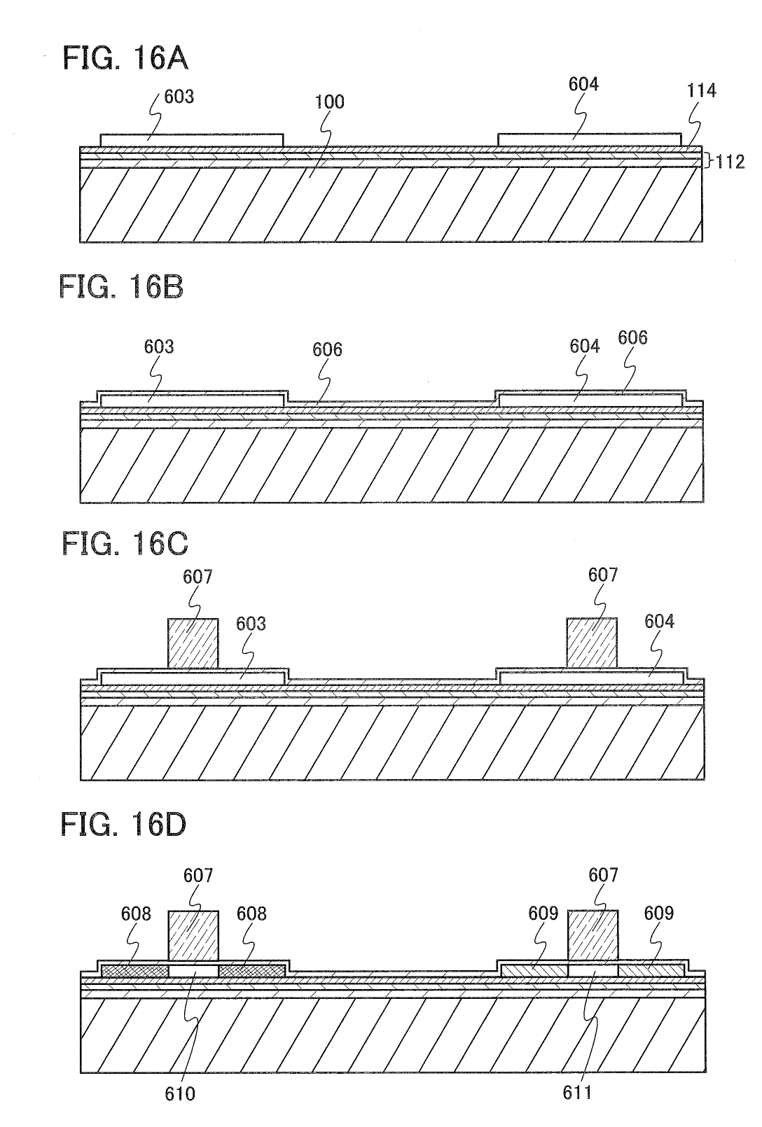

As an example of a manufacturing method of a semiconductor device using the semiconductor substrate 10, a manufacturing method of transistors will be described in Embodiment Mode 3, with reference to cross-sectional views of FIGS. 16A to 16D, FIGS. 17A to 17C, and FIGS. 18A and 18B. By combining a plurality of transistors, a variety of types of semiconductor devices are manufactured. In this embodiment mode, an n-channel transistor and a p-channel transistor can be manufactured at the same time.

As illustrated in FIG. 16A, a single crystal semiconductor layer over the supporting substrate 100 is processed (patterned) into a desired shape by etching, so that a semiconductor film 603 and a semiconductor film 604 are formed. A p-channel transistor is formed using the semiconductor film 603, and an n-channel transistor is formed using the semiconductor film 604.

To control threshold voltages, a p-type impurity element such as boron, aluminum, or gallium or an n-type impurity element such as phosphorus or arsenic may be added to the semiconductor film 603 and the semiconductor film 604. For example, in the case of adding boron as an impurity element imparting p-type conductivity, boron may be added at a concentration of greater than or equal to 5×10¹⁶ cm⁻³ and less than or equal to 1×10¹⁷ cm⁻³. The addition of the impurity element for controlling the threshold voltages may be performed on the single crystal semiconductor layer 116 or on the semiconductor film 603 and the semiconductor film 604. Alternatively, the addition of the impurity element for controlling the threshold voltages may be performed on the single crystal semiconductor substrate 110. Further alternatively, the addition of the impurity element may be performed on the single crystal semiconductor substrate 110, and then the addition of the impurity element may be further performed on the single crystal semiconductor layer 116 or on the semiconductor film 603 and the semiconductor film 604 for finely adjusting the threshold voltages.

For example, taking as an example the case of using weak p-type single crystal silicon substrate as the single crystal semiconductor substrate 110, an example of a method for adding such an impurity element is described. First, before etching the single crystal semiconductor layer 116, boron is added to the entire single crystal semiconductor layer 116. This addition of boron aims at adjusting the threshold voltage of a p-channel transistor. Using B₂H₆ as a dopant gas, boron is added at a concentration of 1×10¹⁶/cm³ to 1×10¹⁷/cm³. The concentration of boron is determined in consideration of the activation rate or the like. For example, the concentration of boron can be 6×10¹⁶/cm³. Next, the single crystal semiconductor layer 116 is etched to form the semiconductor film 603 and the semiconductor film 604. Then, boron is added to only the semiconductor film 604. The second addition of boron aims at adjusting the threshold voltage of an n-channel transistor. Using B₂H₆ as a dopant gas, boron is added at a concentration of 1×10¹⁶/cm³ to 1×10¹⁷/cm³. For example, the concentration of boron can be 6×10¹⁶/cm³.

Note that in the case where a substrate having a conductivity type or resistance suitable for the threshold voltage of either of the p-channel transistor or the n-channel transistor can be used as the single crystal semiconductor substrate 110, the required number of steps for adding an impurity element for controlling the threshold voltage can be one; at that time, an impurity element for controlling the threshold voltage may be added to one of the semiconductor film 603 and the semiconductor film 604.

As illustrated in FIG. 16B, a gate insulating film 606 is formed to cover the semiconductor film 603 and the semiconductor film 604. The gate insulating film 606 can be formed with a single layer or a multiple layer with two or mores of a silicon oxide film, a silicon oxynitride film, a silicon nitride oxide film, and/or a silicon nitride film by a PECVD method at a process temperature of 350° C. or lower. In addition, the gate insulating film 606 can be formed with an oxide film or a nitride film obtained by oxidizing or nitriding surfaces of the semiconductor film 603 and the semiconductor film 604 by high-density plasma treatment. The high-density plasma treatment is performed using, for example, a mixed gas of a rare gas such as He, Ar, Kr, or Xe and oxygen, nitrogen oxide, ammonia, nitrogen, hydrogen, or the like. In this case, when excitation of the plasma is performed by introduction of a microwave, high density plasma with a low electron temperature can be generated. The surfaces of the semiconductor films are oxidized or nitrided by oxygen radicals (OH radicals may be included) or nitrogen radicals (NH radicals may be included) which are generated by such high-density plasma, whereby an insulating film is formed to a thickness of 1 nm to 20 nm, preferably 5 nm to 10 nm so as to be in contact with the semiconductor films. The insulating film with a thickness of 5 nm to 10 nm is used as the gate insulating film 606.

Then, after forming a conductive film over the gate insulating film 606 as illustrated in FIG. 16C, the conductive film is processed (patterned) into a predetermined shape, thereby forming an electrode 607 over each of the semiconductor film 603 and the semiconductor film 604. The conductive film can be formed by a CVD method, a sputtering method, or the like. For the conductive film, tantalum (Ta), tungsten (W), titanium (Ti), molybdenum (Mo), aluminum (Al), copper (Cu), chromium (Cr), niobium (Nb), or the like may be used. Alternatively, an alloy containing the above-described metal as a main component or a compound containing the above-described metal can also be used. Further alternatively, the conductive film may be formed using a semiconductor such as polycrystalline silicon which is formed by addition of an impurity element imparting a conductivity type, such as phosphorus, to a semiconductor film.

As a combination of two conductive films, tantalum nitride or tantalum (Ta) can be used for a first layer, and tungsten (W) can be used for a second layer. Moreover, the following combinations are given: tungsten nitride and tungsten, molybdenum nitride and molybdenum, aluminum and tantalum, aluminum and titanium, and the like. Since tungsten and tantalum nitride have high heat resistance, heat treatment for thermal activation can be performed after the two conductive films are formed. Alternatively, as a combination of the two conductive films, for example, silicon doped with an impurity imparting n-type conductivity and nickel silicide, Si doped with an impurity imparting n-type conductivity and WSix, or the like can be used.

In addition, although each of the electrodes 607 is formed of a single-layer conductive film in this embodiment mode, this embodiment mode is not limited to this structure. The electrodes 607 may be formed by stacking plural conductive films. In the case of a three-layer structure in which three or more conductive films are stacked, a stacked-layer structure of a molybdenum film, an aluminum film, and a molybdenum film may be employed.

As masks used for forming the electrodes 607, instead of resist, silicon oxide, silicon nitride oxide, or the like may be used. Although, in this case, a step of etching silicon oxide, silicon nitride oxide, or the like is added, the reduction in film thickness of the masks at the time of etching is less than that in the case of using a resist mask; accordingly, the electrodes 607 each having a desired width can be formed. Alternatively, the electrodes 607 may be formed selectively by a droplet discharge method without using the masks.

Note that a droplet discharge method means a method in which droplets containing a predetermined composition are discharged or ejected from fine pores to form a predetermined pattern, and includes an ink-jet method and the like.

After forming the conductive film, the conductive film is etched by an inductively coupled plasma (ICP) etching method to form the electrodes 607. The conductive film can be etched into a desired tapered shape by appropriately controlling the etching condition (e.g., the amount of electric power applied to a coiled electrode layer, the amount of electric power applied to an electrode layer on the substrate side, or the electrode temperature on the substrate side). Further, angles and the like of the taper shapes can also be controlled by the shape of the masks. Note that as an etching gas, a chlorine-based gas such as chlorine, boron chloride, silicon chloride or carbon tetrachloride; a fluorine-based gas such as carbon tetrafluoride, sulfur fluoride, or nitrogen fluoride; or oxygen can be used as appropriate.

Next, as illustrated in FIG. 16D, an impurity element imparting one conductivity type is added to the semiconductor film 603 and the semiconductor film 604 with use of the electrodes 607 as masks. In this embodiment mode, an impurity element imparting p-type conductivity (e.g., boron) is added to the semiconductor film 603, and an impurity element imparting n-type conductivity (e.g., phosphorus or arsenic) is added to the semiconductor film 604. In this step, impurity regions to be a source region and a drain region are formed in the semiconductor film 603, and impurity regions serving as high-resistant regions are formed in the semiconductor film 604.

Note that when the impurity element imparting p-type conductivity is added to the semiconductor film 603, the semiconductor film 604 is covered with a mask or the like so that the impurity element imparting p-type conductivity is not added to the semiconductor film 604. On the other hand, when the impurity element imparting n-type conductivity is added to the semiconductor film 604, the semiconductor film 603 is covered with a mask or the like so that the impurity element imparting n-type conductivity is not added to the semiconductor film 603. Alternatively, after adding an impurity element imparting one of p-type and n-type conductivity to the semiconductor film 603 and the semiconductor film 604, an impurity element imparting the other conductivity may be added to one of the semiconductor film 603 and the semiconductor film 604 selectively at higher concentration than the previously added impurity element. By this adding step of impurity element, p-type high-concentration impurity regions 608 are formed in the semiconductor film 603, and n-type low-concentration impurity regions 609 are formed in the semiconductor film 604. The regions overlapped with the electrodes 607 in the semiconductor film 603 and the semiconductor film 604 are a channel formation region 610 and a channel formation region 611.

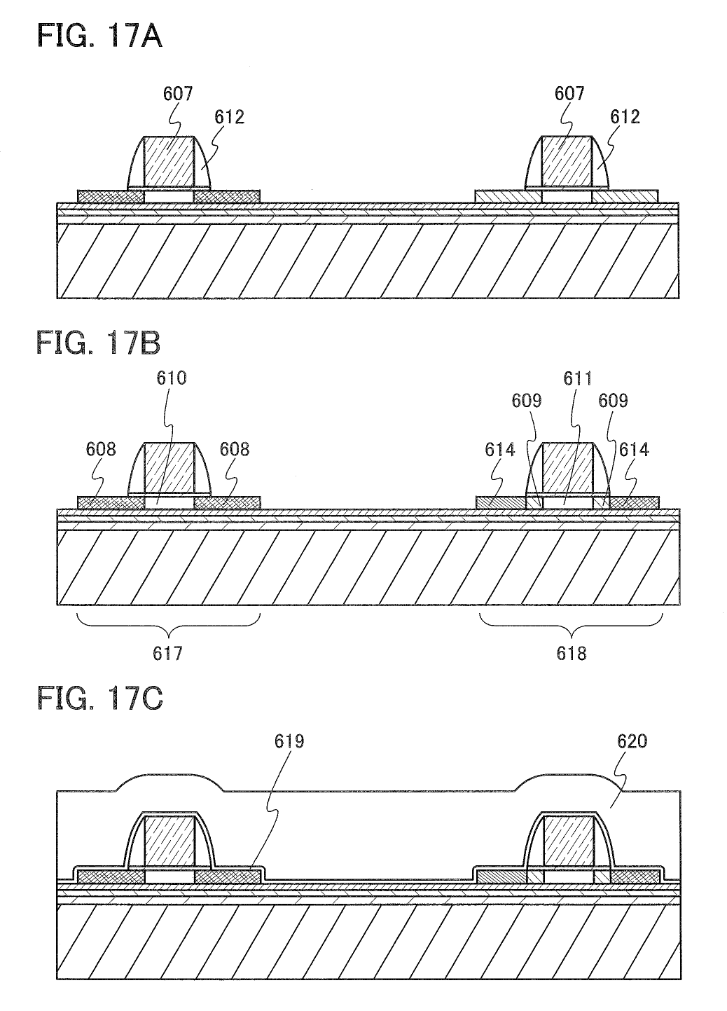

Next, as illustrated in FIG. 17A, sidewalls 612 are formed on side surfaces of the electrodes 607. For example, the sidewalls 612 can be formed in such a manner that an insulating film is newly formed so as to cover the gate insulating films 606 and the electrodes 607, and the newly-formed insulating film is partially etched by anisotropic etching in which etching is performed mainly in a perpendicular direction. The newly-formed insulating film is partially etched by the above-described anisotropic etching, whereby the sidewalls 612 are formed on the side surfaces of the electrodes 607. Note that the gate insulating film 606 is also partially etched by this anisotropic etching. The insulating film for forming the sidewalls 612 can be formed as a single layer or a stack of two or more layers of a film including an organic material such as an organic resin or a film of silicon, silicon oxide, or silicon nitride oxide by a PECVD method, a sputtering method, or the like. In this embodiment mode, the insulating film is formed of a silicon oxide film with a thickness of 100 nm by a PECVD method. In addition, as an etching gas of the silicon oxide film, a mixed gas of CHF₃ and helium can be used. It is to be noted that the steps for formation of the sidewalls 612 are not limited to the steps given here.

As illustrated in FIG. 17B, an impurity element imparting n-type conductivity is added to the semiconductor film 604 by using the electrode 607 and the sidewalls 612 as masks. This step is a step for forming impurity regions serving as a source region and a drain region in the semiconductor film 604. In this step, the impurity element imparting n-type conductivity is added to the semiconductor film 604 while the semiconductor film 603 is covered with a mask or the like.

In the above-described addition of the impurity element, the electrode 607 and the sidewalls 612 serve as masks; accordingly, a pair of n-type high-concentration impurity regions 614 are formed in the semiconductor film 604 in a self-alignment manner. Then, the mask covering the semiconductor film 603 is removed, and then heat treatment is performed to activate the impurity element imparting p-type conductivity added to the semiconductor film 603 and the impurity element imparting n-type conductivity added to the semiconductor film 604. Through the sequence of the steps illustrated in FIGS. 16A to 16D and FIGS. 17A and 17B, a p-channel transistor 617 and an n-channel transistor 618 are formed.

In order to reduce the resistance of the source and drain, a silicide layer may be formed by siliciding the p-type high-concentration impurity regions 608 in the semiconductor film 603 and the pair of n-type high-concentration impurity regions 614 in the semiconductor film 604. The siliciding is performed by placing a metal in contact with the semiconductor film 603 and the semiconductor film 604 and causing reaction between the metal and silicon in the semiconductor films through heat treatment; in this manner, a silicide compound is generated. As the metal, cobalt or nickel is preferable, or the following can be used: titanium (Ti), tungsten (W), molybdenum (Mo), zirconium (Zr), hafnium (Hf), tantalum (Ta), vanadium (V), neodymium (Nd), chromium (Cr), platinum (Pt), palladium (Pd), or the like. In the case where the semiconductor film 603 and the semiconductor film 604 are thin, the silicide reaction may proceed to the bottom of the semiconductor film 603 and the semiconductor film 604 in this region. As the heat treatment for forming a silicide, a resistance heating furnace, an RTA apparatus, a microwave heating apparatus, or a laser irradiation apparatus can be used.

Next, as illustrated in FIG. 17C, an insulating film 619 is formed to cover the p-channel transistor 617 and the n-channel transistor 618. As the insulating film 619, an insulating film containing hydrogen is formed. In this embodiment mode, a silicon nitride oxide film with a thickness of about 600 nm is formed by a PECVD method using monosilane, ammonia, and N₂O as a source gas. The insulating film 619 is made to contain hydrogen because hydrogen can be diffused from the insulating film 619 so that dangling bonds in the semiconductor film 603 and the semiconductor film 604 can be terminated. The formation of the insulating film 619 can prevent impurities such as an alkali metal and an alkaline earth metal from entering the p-channel transistor 617 and the n-channel transistor 618. Specifically, it is preferable to use silicon nitride, silicon nitride oxide, aluminum nitride, aluminum oxide, silicon oxide, or the like for the insulating film 619.

Next, an insulating film 620 is formed over the insulating film 619 so as to cover the p-channel transistor 617 and the n-channel transistor 618. An organic material having heat resistance, such as polyimide, acrylic, benzocyclobutene, polyamide, or epoxy can be used for the insulating film 620. In addition to such organic materials, it is also possible to use a low-dielectric constant material (a low-k material), a siloxane resin, silicon oxide, silicon nitride, silicon nitride oxide, PSG (phosphosilicate glass), BPSG (borophosphosilicate glass), alumina, or the like. A siloxane resin may include as a substituent at least one of fluorine, an alkyl group, and an aryl group, as well as hydrogen. Alternatively, the insulating film 620 may be formed by stacking plural insulating films formed of these materials. The insulating film 620 may have its surface planarized by a CMP method or the like.

Note that the siloxane-based resin corresponds to a resin including a Si—O—Si bond formed using a siloxane-based material as a starting material. The siloxane-based resin may include as a substituent at least one of fluorine, an alkyl group, and aromatic hydrocarbon, as well as hydrogen.

For the formation of the insulating film 620, the following method can be used depending on the material of the insulating film 620: a CVD method, a sputtering method, an SOG method, a spin coating method, a dip coating method, a spray coating method, a droplet discharge method (e.g., an inkjet method, screen printing, or offset printing), a doctor knife, a roll coater, a curtain coater, a knife coater, or the like.

Next, heat treatment at about 400° C. to 450° C. (e.g., 410° C.) is performed in a nitrogen atmosphere for 1 hour, so that hydrogen is made to diffuse from the insulating film 619 and dangling bonds in the semiconductor film 603 and the semiconductor film 604 are terminated with hydrogen. Since the single crystal semiconductor layer 116 has a much lower defect density than a polycrystalline silicon film which is formed by crystallizing an amorphous silicon film, this termination treatment with hydrogen can be performed in short time.

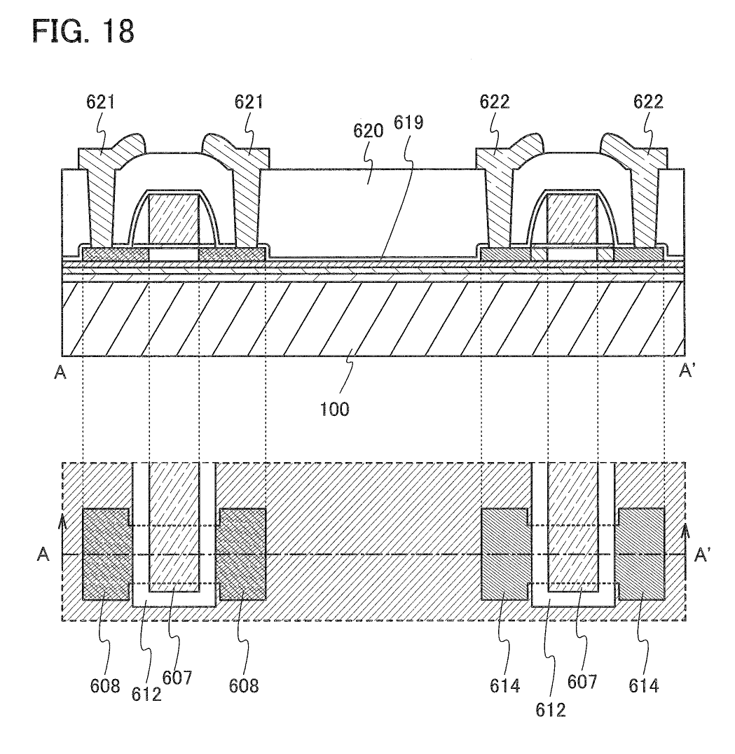

Next, as illustrated in FIG. 18, contact holes are formed in the insulating film 619 and the insulating film 620 so that the semiconductor film 603 and the semiconductor film 604 are partially exposed. The formation of the contact holes can be performed by a dry etching method using a mixed gas of CHF₃ and He; however, the present invention is not limited to this. Then, conductive films 621 and conductive films 622 are formed to be in contact with the semiconductor film 603 and the semiconductor film 604, respectively through the contact holes. The conductive films 621 are connected to the p-type high-concentration impurity regions 608 of the p-channel transistor 617. The conductive films 622 are connected to the pair of n-type high-concentration impurity regions 614 of the n-channel transistor 618.

The conductive films 621 and the conductive films 622 can be formed by a CVD method, a sputtering method, or the like. Specifically, the following can be used for the conductive films 621 and the conductive films 622: aluminum (Al), tungsten (W), titanium (Ti), tantalum (Ta), molybdenum (Mo), nickel (Ni), platinum (Pt), copper (Cu), gold (Au), silver (Ag), manganese (Mn), neodymium (Nd), carbon (C), silicon (Si), or the like. Alternatively, an alloy containing the above-described metal as a main component or a compound containing the above-described metal can also be used. The conductive films 621 and the conductive films 622 can be formed of a single layer or a plurality of layers using a film formed of the above-described metal.

As an example of an alloy containing aluminum as its main component, an alloy containing aluminum as its main component and also containing nickel is given. Further, an alloy which contains aluminum as its main component and contains nickel and one or both of carbon and silicon can also be given. Since aluminum and aluminum silicon have low resistance and are inexpensive, aluminum and aluminum silicon are suitable as materials for forming the conductive films 621 and the conductive films 622. In particular, when the shape of an aluminum silicon (Al—Si) film is processed by etching, generation of hillocks in resist baking for forming an etching mask can be prevented more than in the case where an aluminum film is used. Instead of silicon (Si), Cu may be mixed into an aluminum film at about 0.5%.

For example, a stacked structure including a barrier film, an aluminum silicon (Al—Si) film, and a barrier film or a stacked structure including a barrier film, an aluminum silicon (Al—Si) film, a titanium nitride film, and a barrier film may be used for the conductive films 621 and the conductive films 622. Note that the barrier film refers to a film formed using titanium, a nitride of titanium, molybdenum, or a nitride of molybdenum. When barrier films are formed to sandwich an aluminum silicon (Al—Si) film therebetween, generation of hillocks of aluminum or aluminum silicon can be prevented more effectively. Moreover, when the barrier film is formed using titanium that is a highly-reducible element, even if a thin oxide film is formed over the semiconductor film 603 and the semiconductor film 604, the oxide film is reduced by the titanium contained in the barrier film, whereby preferable contact between the conductive films 621 and 622 and the semiconductor films 603 and 604 can be obtained. Further, it is also possible to stack a plurality of barrier films. In that case, for example, a five-layer structure in which titanium, titanium nitride, aluminum silicon, titanium, and titanium nitride are stacked from the lowest layer can be used for the conductive films 621 and the conductive films 622.

For the conductive films 621 and the conductive films 622, tungsten silicide formed by a chemical vapor deposition method using a WF₆ gas and a SiH₄ gas may be used. Alternatively, tungsten formed by hydrogen reduction of WF₆ may be used for the conductive films 621 and the conductive films 622.

In FIG. 18, a top view of the p-channel transistor 617 and the n-channel transistor 618 and a cross-sectional view taken along a line A-A′ of the top view are illustrated. Note that the conductive films 621, the conductive films 622, the insulating film 619, and the insulating film 620 are omitted in the top view of FIG. 18.

Although the case where each of the p-channel transistor 617 and the n-channel transistor 618 has one electrode 607 functioning as a gate is described in this embodiment mode, the present invention is not limited to this structure. The transistor manufactured in the present invention may have a multi-gate structure in which a plurality of electrodes functioning as gates are included and electrically connected to one another. Moreover, the transistors may have a gate planar structure.

Note that since a semiconductor layer included in the semiconductor substrate of the present invention is a sliced layer of a single crystal semiconductor substrate, its orientation does not vary. Consequently, variation in electric characteristics such as threshold voltage and mobility of a plurality of transistors manufactured using a semiconductor substrate can be made to be small. Further, since there are almost no crystal grain boundaries, a leakage current due to a crystal grain boundary can be suppressed, as well as realize power saving of a semiconductor device. Accordingly, a highly reliable semiconductor device can be manufactured.

In the case of manufacturing a transistor from a polycrystalline semiconductor film obtained by laser crystallization, it has been necessary to decide a layout of the semiconductor film of the transistor taking into consideration a scanning direction of a laser beam, in order to obtain high mobility. However, there is no such need for the semiconductor substrate of the present invention, and there are little restrictions in designing a semiconductor device.

This embodiment mode can be carried out in combination with any structure in the other embodiment modes and examples.

### Embodiment Mode 4

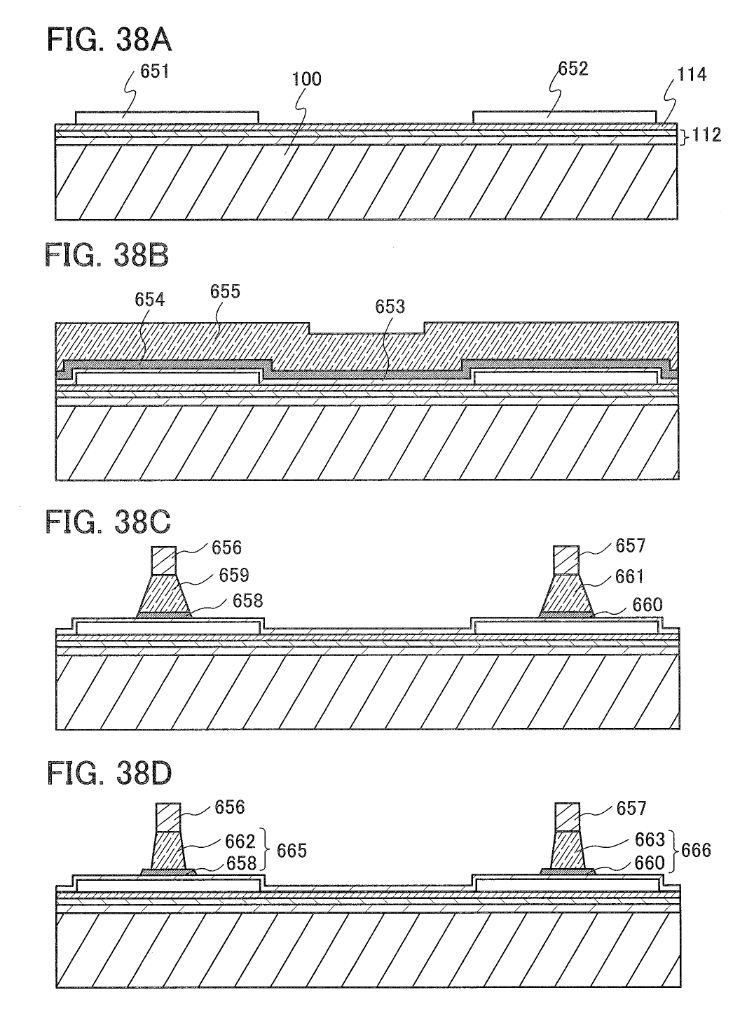

As an example of a manufacturing method of a semiconductor device using the semiconductor substrate 10, a manufacturing method of transistors will be described in Embodiment Mode 4, which is different from that in Embodiment Mode 3, with reference to cross-sectional views of FIGS. 38A to 38D, FIGS. 39A to 39C, and FIGS. 40A and 40B. In this embodiment mode, an n-channel transistor and a p-channel transistor can be manufactured at the same time.

As illustrated in FIG. 38A, a single crystal semiconductor layer over the supporting substrate 100 is processed (patterned) to have a desired shape by etching, so that a semiconductor film 651 and a semiconductor film 652 are formed. A p-channel transistor is formed using the semiconductor film 651, and an n-channel transistor is formed using the semiconductor film 652.

To control threshold voltages, a p-type impurity element such as boron, aluminum, or gallium or an n-type impurity element such as phosphorus or arsenic may be added to the semiconductor film 651 and the semiconductor film 652. For example, in the case of adding boron as an impurity element imparting p-type conductivity, boron may be added at a concentration of greater than or equal to 5×10¹⁶ cm⁻³ and less than or equal to 1×10¹⁷ cm⁻³. The addition of the impurity element for controlling the threshold voltages may be performed on the single crystal semiconductor layer 116 or on the semiconductor film 651 and the semiconductor film 652. Alternatively, the addition of the impurity element for controlling the threshold voltages may be performed on the single crystal semiconductor substrate 110. Further alternatively, the addition of the impurity element may be performed on the single crystal semiconductor substrates 110, and then the addition of the impurity element may be further performed on the single crystal semiconductor layer 116 or on the semiconductor film 651 and the semiconductor film 652 for finely adjusting the threshold voltages.

Taking as an example the case of using weak p-type single crystal silicon substrates as the single crystal semiconductor substrate 110, an example of a method for adding such an impurity element is described. First, before etching the single crystal semiconductor layer 116, boron is added to the entire single crystal semiconductor layer 116. This addition of boron aims at adjusting the threshold voltage of a p-channel transistor. Using B₂H₆ as a dopant gas, boron is added at a concentration of 1×10¹⁶/cm³ to 1×10¹⁷/cm³. The concentration of boron is determined in consideration of the activation rate or the like. For example, the concentration of boron can be 6×10¹⁶/cm³. Next, the single crystal semiconductor layer 116 is etched to form the semiconductor film 603 and the semiconductor film 604. Then, boron is added to only the semiconductor film 604. The second addition of boron aims at adjusting the threshold voltage of an n-channel transistor. Using B₂H₆ as a dopant gas, boron is added at a concentration of 1×10¹⁶/cm³ to 1×10¹⁷/cm³. For example, the concentration of boron can be 6×10¹⁶/cm³.

Next, as illustrated in FIG. 38B, a gate insulating layer 653, a conductive layer 654 and a conductive layer 655 which form a gate electrode are sequentially formed over a semiconductor film 651 and a semiconductor film 652.

The gate insulating layer 653 is formed as a single layer film or a stacked layer film using an insulating layer such as a silicon oxide layer, a silicon oxynitride layer, a silicon nitride layer, or a silicon nitride oxide layer by a CVD method, a sputtering method, an atomic layer epitaxy (ALE) method, or the like.

Alternatively, the gate insulating layer 653 may be formed in such a manner that plasma treatment is performed on the semiconductor film 651 and the semiconductor film 652 to oxidize or nitride surfaces thereof. Plasma treatment in this case also includes that with plasma excited using microwaves (a typical frequency is 2.45 GHz). For example, treatment with plasma that is excited by microwaves and has an electron density of 1×10¹¹/cm³ to 1×10¹³/cm³ and an electron temperature of 0.5 eV to 1.5 eV is also included. Oxidation treatment or nitridation treatment of the surface of the semiconductor layer with such plasma treatment makes it possible to form a thin and dense film. In addition, since the surface of the semiconductor layer is directly oxidized, a film which has good interface characteristics can be obtained. In addition, the gate insulating layer 653 may be formed by conducting plasma treatment using a microwave to a film formed by a CVD method, a sputtering method or an ALE method.

Since the gate insulating layer 653 forms the interface with the semiconductor layers, the gate insulating layer 653 is preferably formed so that a silicon oxide layer or a silicon oxynitride layer is located at the interface. This is because, if a film in which the amount of nitrogen is higher than that of oxygen such as a silicon nitride layer or a silicon nitride oxide layer is formed, problems of interface characteristics such as generation of trap levels might be caused.

The conductive layer which forms the gate electrode is formed as a single layer film or a stacked layer film using an element selected from tantalum, tantalum nitride, tungsten, titanium, molybdenum, aluminum, copper, chromium, or niobium, an alloy material or a compound material containing the element as its main component, or a semiconductor material typified by polycrystalline silicon doped with an impurity element such as phosphorus, by a CVD method or a sputtering method. When the conductive layer is formed as a stacked layer film, it can be formed using different conductive materials or can be formed using the same conductive material. In this embodiment mode, an example is described in which the conductive layer of the gate electrode is formed with a two-layer structure including the conductive layer 654 and the conductive layer 655.

If the conductive layer for forming the gate electrode has a two-layer structure of the conductive layer 654 and the conductive layer 655, a stacked layer film of a tantalum nitride layer and a tungsten layer, a tungsten nitride layer and a tungsten layer, or a molybdenum nitride layer and a molybdenum layer can be formed, for example. Note that a stacked layer film of a tantalum nitride layer and a tungsten layer is preferable because etching rates of both layers are easily differentiated from each other and high selectivity can be obtained. Note that, in for the two-layer films which are exemplified, the first mentioned film is preferably formed over the gate insulating layer 653. In this embodiment mode, the first conductive layer 654 is formed with a thickness of from 20 nm to 100 nm. The conductive layer 655 is formed with a thickness of 100 nm to 400 nm. The gate electrode can also have a stacked structure of three or more layers; in that case, it is preferable to employ a stacked structure of a molybdenum layer, an aluminum layer, and a molybdenum layer.

Next, a resist mask 656 and a resist mask 657 are selectively formed over the conductive layer 655. Then, first etching treatment and second etching treatment are performed using the resist mask 656 and the resist mask 657.

First, by the first etching treatment using the resist mask 656 and the resist mask 657, the conductive layer 654 and the conductive layer 655 are selectively etched, and thus a conductive layer 658 and a conductive layer 659 are formed over the semiconductor film 651 and a conductive layer 660 and a conductive layer 661 are formed over a semiconductor film 652 (FIG. 38C).

Next, by the second etching using the resist mask 656 and the resist mask 657, end portions of the conductive layer 659 and the conductive layer 661 are etched, and thus a conductive layer 662 and a conductive layer 663 are formed (FIG. 38D). The second conductive layers 662 and 663 are formed so as to have smaller widths (lengths parallel to a direction in which carriers flow through channel formation regions (a direction in which a source region and a drain region are connected)) than those of the first conductive layers 658 and 660. In this manner, a two-layer of gate electrode 665 including the conductive layer 658 and the conductive layer 662 and a two-layer of gate electrode 666 including the conductive layer 660 and the conductive layer 663 are formed.

Although an etching method employed for the first etching treatment and the second etching treatment may be selected as appropriate, a dry etching apparatus using a high-density plasma source such as ECR (electron cyclotron resonance) or ICP (inductive coupled plasma) may be used in order to increase the etching rate. With appropriate control of the etching condition of the first etching treatment and the second etching treatment, side surfaces of the conductive layers 658 and 660 and the conductive layers 662 and 663 can each have a desired tapered shape. After formed desired gate electrodes 665 and 666, the resist masks 656 and 657 may be removed.

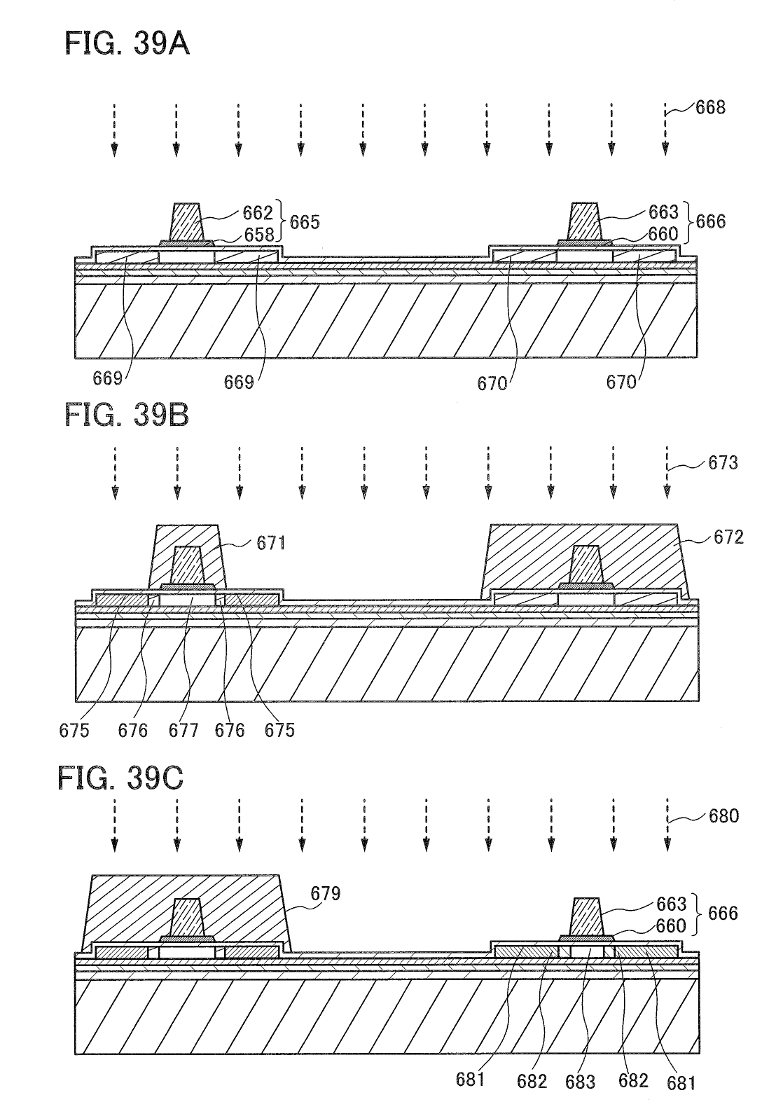

Next, an impurity element 668 is added to the semiconductor film 651 and the semiconductor film 652 using the gate electrode 665 and the gate electrode 666 as masks. In the semiconductor film 651, a pair of impurity regions 669 is formed in a self-alignment manner using the conductive layer 658 and the conductive layer 662 as masks. As well, in the semiconductor film 652, a pair of impurity regions 670 is formed in a self-alignment manner using the conductive layer 660 and the conductive layer 663 as masks (FIG. 39A).

As the impurity element 668, a p-type impurity element such as boron, aluminum, or gallium, or an n-type impurity element such as phosphorus or arsenic is added. At this time, in order to form a high-resistant region of the n-channel transistor, phosphorus of an n-type impurity element is added as an impurity element 668. In addition, phosphorus is added such that it is included in the impurity region 669 at a concentration of about 1×10¹⁷ atoms/cm³ to 5×10¹⁸ atoms/cm³.

Then, in order to form impurity regions serving as source and drain regions of the n-channel transistor, a resist mask 671 is formed to partially cover the semiconductor film 651 and a resist mask 672 is selectively formed to cover the semiconductor film 652. Then, a pair of impurity region 675 is formed in the semiconductor film 651 by addition of an impurity element 673 to the semiconductor film 651 using the resist mask 671 as a mask (FIG. 39B).

As the impurity element 673, phosphorus of an n-type impurity element is added to the semiconductor film 651, and the concentration of added phosphorus is 5×10¹⁹ atoms/cm³ to 5×10²⁰ atoms/cm³. The n-type impurity regions 675 each serve as a source region or a drain region. The impurity regions 675 are formed in regions not overlapping with the conductive layer 658 and the conductive layer 662.

In addition, in the semiconductor film 651, the impurity regions 676 are regions of the impurity regions 669 which are not doped with the impurity element 673. The concentration of the impurity element included in the impurity region 676 is higher than that in the impurity region 675 and serves as a high-resistant region or an LDD region. In the semiconductor film 651, a channel formation region 677 overlapping the conductive layer 658 and the conductive layer 662 is formed.

An LDD region means a region to which an impurity element is added at a low concentration and which is formed between a channel formation region and a source or drain region that is formed by adding the impurity element at a high concentration. When an LDD region is provided, there is an advantageous effect in that an electric field in the vicinity of a drain region is reduced to prevent deterioration due to hot carrier injection. Further, a structure in which an LDD region overlaps with a gate electrode with a gate insulating layer interposed therebetween (also called a “gate-drain overlapped LDD (GOLD) structure”) may also be employed in order to prevent deterioration of an on-current value due to hot carrier.

Next, after removing the resist mask 671 and the resist mask 672, a resist mask 679 is formed to cover the semiconductor film 651 so that a source region and a drain region of a p-channel transistor can be formed. Then, an impurity element 680 is added using the resist mask 679, the conductive layer 660 and the conductive layer 663 as masks, so that a pair of impurity regions 681, a pair of impurity regions 682 and a channel formation region 683 are formed in the semiconductor film 652 (FIG. 39C).

As the impurity element 680, a p-type impurity element such as boron, aluminum or gallium can be used. Here, boron that is a p-type impurity element is added so as to be contained at a concentration of about 1×10²⁰ atoms/cm³ to 5×10²¹ atoms/cm³.

In the semiconductor film 652, the impurity region 681 is formed in a region not overlapping with the conductive layer 660 and the conductive layer 663, and serves as a source region or a drain region. Here, boron that is a p-type impurity element is added so as to be contained in the impurity regions 681 at a concentration of about 1×10²⁰ atoms/cm³ to 5×10²¹ atoms/cm³.

The impurity region 682 is formed in a region overlapping with the conductive layer 660 but not overlapping with the conductive layer 663, and the impurity region 682 is formed by the impurity element 680 which have passed through the conductive layer 660 and has been introduced to the impurity region 670. The impurity region 670 has an n-type conductivity and thus, an impurity element 673 is added such that the impurity region 682 can have a p-type conductivity. By adjusting the concentration of the impurity element 673 included in the impurity region 682, the impurity region 682 can serve as a source region or a drain region, or can serve as an LDD region.

In the semiconductor film 652, the channel formation region 683 is formed in a region overlapping with the conductive layer 660 and the conductive layer 663.

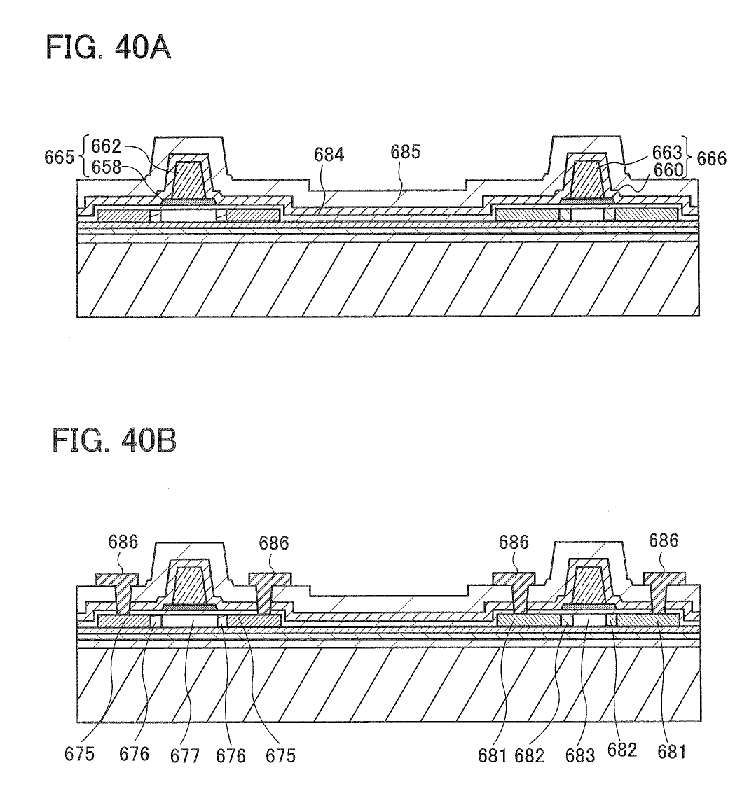

An interlayer insulating layer is formed. The interlayer insulating layer can be formed as a single layer film or a stacked layer film; in this embodiment mode, the interlayer insulating layer has a two-layer structure of an insulating layer 684 and an insulating layer 685 (see FIG. 40A).

As the interlayer insulating layer, a silicon oxide layer, a silicon oxynitride layer, a silicon nitride layer, a silicon nitride oxide layer, or the like can be formed by a CVD method or a sputtering method. Further, the interlayer insulating film can also be formed by an application method such as a spin coating method, using an organic material such as polyimide, polyamide, polyvinylphenol, benzocyclobutene, acrylic, or epoxy, a siloxane material such as a siloxane resin, an oxazole resin, or the like. It is to be noted that a siloxane material is a material including a Si—O—Si bond. Siloxane is composed of a skeleton structure formed by the bond of silicon (Si) and oxygen (O). As the substituent, an organic group including at least hydrogen (such as an alkyl group or aromatic hydrocarbon) is used. In addition, a fluoro group may be contained in the organic group. An organic group containing at least hydrogen and a fluoro group may also be used as a substituent.

For example, a silicon nitride oxide layer is formed to a thickness of 100 nm as the insulating layer 684, and a silicon oxynitride layer is formed to a thickness of 900 nm as the insulating layer 685. In addition, the insulating layer 684 and the insulating layer 685 are successively formed by a plasma CVD method. The interlayer insulating layer may also have a stacked structure including three or more layers. Alternatively, a stacked structure of a silicon oxide layer, a silicon oxynitride layer, or a silicon nitride layer and an insulating layer formed using an organic material such as polyimide, polyamide, polyvinyl phenol, benzocyclobutene, acrylic, or epoxy; a siloxane material such as a siloxane resin; or an oxazole resin can be employed.

Next, contact holes are formed in the interlayer insulating layer (in this embodiment mode, the insulating layers 684 and 685), and conductive layers 686 that function as source electrodes and drain electrodes are formed in the contact holes (see FIG. 40B).

The contact holes are selectively formed in the insulating layer 684 and the insulating layer 685 so as to reach the impurity region 675 formed in the semiconductor film 651, and the impurity region 681 formed in the semiconductor film 652.

As the conductive layers 686, a single layer film formed of one element selected from aluminum, tungsten, titanium, tantalum, molybdenum, nickel, or neodymium, or an alloy containing a plurality of above elements; or a stacked layer film including such layers can be used. For example, a conductive layer that is formed using an alloy that contains a plurality of the elements given above can be formed using an aluminum alloy that contains titanium, an aluminum alloy that contains neodymium, or the like. If the conductive layers 686 are each a stacked layer film, a structure can be employed in which an aluminum layer or an aluminum alloy layer as described above is sandwiched between titanium layers, for example.

As illustrated in FIG. 40B, the n-channel transistor and the p-channel transistor can be manufactured using a single crystal semiconductor substrate.

This embodiment mode can be carried out in combination with any structure of the other embodiment modes and examples.

### Embodiment Mode 5

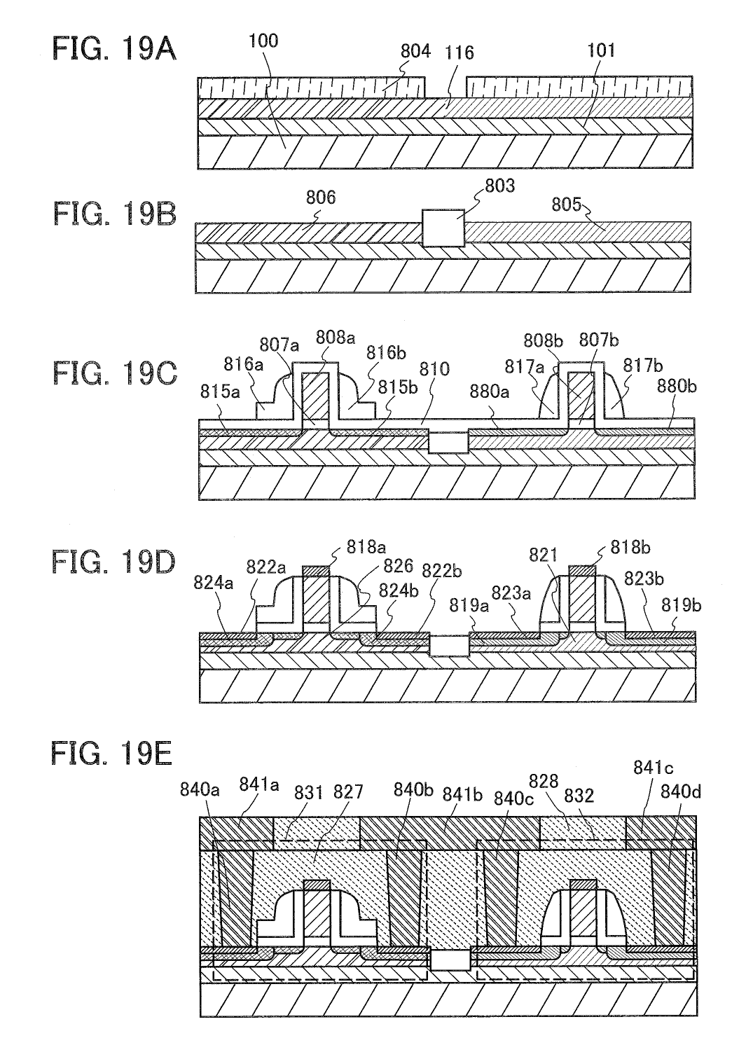

As an example of a manufacturing method of a semiconductor device using the semiconductor substrate 10, a manufacturing method of transistors will be described in Embodiment Mode 5, with reference to FIGS. 19A to 19E. By combining a plurality of transistors, a variety of types of semiconductor devices are manufactured. In this embodiment mode, an n-channel thin film transistor and a p-channel transistor can be manufactured at the same time.

As illustrated in FIG. 19A, a semiconductor substrate in which a buffer layer 101 and a single crystal semiconductor layer 116 are formed over a supporting substrate 100 is prepared. The buffer layer 101 has a three-layer structure and includes an insulating film 112b serving as a barrier layer. In addition, although an example in which the semiconductor substrate 10 having the structure shown in FIG. 1 is used is described in this embodiment mode, a semiconductor substrate having another structure shown in this specification can also be used.

The single crystal semiconductor layer 116 has an impurity region (a channel-doped region) to which a p-type impurity element such as boron, aluminum, or gallium or an n-type impurity element such as phosphorus or arsenic is preferably added in accordance with a formation region of an n-channel field-effect transistor or a p-channel field-effect transistor.

Etching is conducted using a protective layer 804 as a mask, and the exposed single crystal semiconductor layer 116 and the buffer layer 101 under that are partially removed. Then, a silicon oxide film is deposited using organosilane by a PECVD method. A silicon oxide film is formed thick enough to embed the single crystal semiconductor layer 116 under the silicon oxide film. Next, after removing the silicon oxide film formed over the single crystal semiconductor layer 116 by polishing, the protective layer 804 is removed such that an insulating layer 803 for element separation is left. By the insulating layer 803 for element separation, the single crystal semiconductor layer 116 is divided into an element region 805 and an element region 806 (FIG. 19B).

Then, a first insulating film is formed, gate electrode layers 808a, 808b are formed over the first insulating film, the first insulating film is etched using the gate electrode layers 808a and 808b as masks to form gate insulating layers 807a and 807b.

The gate insulating layers 807a and 807b may be formed with a silicon oxide film or a stacked structure of a silicon oxide film a silicon nitride film. A silicon oxynitride layer, a silicon nitride oxide layer or the like can be used as the gate insulating layers. The gate insulating layers 807a and 807b may be formed by depositing an insulating film by a plasma CVD method or a low pressure CVD method or may be formed by solid phase oxidation or solid phase nitridation by plasma treatment. This is because a gate insulating layer which is formed using a semiconductor layer that is oxidized or nitrided by plasma treatment is dense and has high withstand voltage and is excellent in reliability. For example, dinitrogen monoxide (N₂O) is diluted with Ar at a flow rate of 1 to 3, and 3 to 5 kW of microwave (2.45 GHz) power is applied at a pressure of 10 to 30 Pa to oxidize or nitride the surface of the single crystal semiconductor layer 116 (element regions 805, 806). By this treatment, an insulating film having a thickness of 1 nm to 10 nm (preferably 2 nm to 6 nm) is formed. Further, dinitrogen monoxide (N₂O) and silane (SiH₄) are introduced and 3 to 5 kW of microwave (2.45 GHz) power is applied at a pressure of 10 to 30 Pa to form a silicon oxynitride film as a gate insulating film by a PECVD method. By combination of solid-phase reaction and vapor deposition, a gate insulating layer having low interface state density and excellent withstand voltage can be formed.

As the gate insulating layers 807a and 807b, a high permittivity material such as zirconium dioxide, hafnium oxide, titanium dioxide, tantalum pentoxide, or the like may be used. By using a high permittivity material for the gate insulating layer 807, gate leakage current can be reduced.

The gate electrode layers 808a and 808b can be formed by a sputtering method, an evaporation method, a CVD method, or the like. The gate electrode layers 808a and 808b may be formed using an element such as tantalum (Ta), tungsten (W), titanium (Ti), molybdenum (Mo), aluminum (Al), copper (Cu), chromium (Cr), or neodymium (Nd), or an alloy material or a compound material containing these elements as its main component. Moreover, a semiconductor film typified by a polycrystalline silicon film which is doped with an impurity element such as phosphorus or an AgPdCu alloy may be used as the gate electrode layers 808a and 808b.

Next, a second insulating film 810 is formed to cover the gate electrode layers 808a and 808b, and sidewall insulating layers 816a, 816b, 817a and 817b having a sidewall structure are formed. The width of the sidewall insulating layers 816a and 816b in a region to serve as a p-channel field effect transistor (pFET) is larger than that of the sidewall insulating layers 817a and 817b in a region to serve as an n-channel field effect transistor (nFET). Arsenic (As) or the like is added to the region to serve as the n-channel field effect transistor to form first impurity regions 820a and 820b having a shallow junction depth, while boron (B) or the like is added to the region to serve as the p-channel field effect transistor to form second impurity regions 815a and 815b having a shallow junction depth (FIG. 19C).

Then, the second insulating film 810 is partially etched to expose the top surface of the gate electrode layers 808a and 808b, the first impurity regions 820a and 820b and the second impurity regions 815a and 815b. Then, As or the like is added to the region to serve as the n-channel field effect transistor to form third impurity regions 819a and 819b having a deep junction depth, while B or the like is added to the region to serve as the p-channel field effect transistor to form fourth impurity regions 824a and 824b having a deep junction depth. Then, heat treatment for activation is conducted. A cobalt film is formed as a metal film to form a silicide. Then, heat treatment such as RTA is conducted (at 500° C. for 1 minute), and silicon in contact with the cobalt film is silicided to form silicides 822a, 822b, 823a and 823b. After that, the cobalt film is selectively removed. Then, heat treatment is conducted at a temperature higher than the heat treatment for siliciding to reduce resistance of the silicide portion (FIG. 19D). A channel formation region 826 is formed in the element region 806 and a channel formation region 821 is formed in the element region 805.

Next, an interlayer insulating layer 827 is formed, and contact holes (openings) are formed using a resist mask, in the interlayer insulating layer 827, which reach the third impurity regions 819a and 819b having a deep junction depth and the fourth impurity regions 824a and 824b having a deep junction depth. Etching may be performed once or a plurality of times depending on a selection ratio between materials to be used.

A method and a condition of the etching may be set as appropriate depending on the materials of the interlayer insulating layer 827 to be provided with contact holes. Wet etching, dry etching, or both of them can be used as appropriate. In this embodiment mode, a dry etching method is used. Note that an etching gas can be selected as appropriate from among a chlorine-based gas typified by Cl₂, BCl_{3 , SiCl}₄, or CCl₄; a fluorine-based gas typified by CF₄, SF₆, or NF₃; and O₂. Further, an inert gas may be added to an etching gas to be used. As an inert element to be added, one or a plurality of elements selected from He, Ne, Ar, Kr, and Xe can be used. A hydrofluoric acid-based solution such as a mixed solution of ammonium hydrogen fluoride and ammonium fluoride may be used as an etchant of wet etching.

Next, a conductive film is formed so as to cover the contact holes, and the conductive layer is etched to form wiring layers each functioning as a source electrode layer or a drain electrode layer that is electrically connected with a portion of the source region or the drain region. The wiring layers can be formed by forming a conductive layer by PVD, CVD, an evaporation method, or the like and then etching the conductive layer into a desired shape. In addition, a conductive layer can be selectively formed in a predetermined position by a droplet discharge method, a printing method, an electrolytic plating method, or the like. A reflow method or a damascene method may also be used. As a material for the wiring layers, metal such as Ag, Au, Cu, Ni, Pt, Pd, Ir, Rh, W, Al, Ta, Mo, Cd, Zn, Fe, Ti, Zr, or Ba; Si or Ge; or an alloy or nitride thereof can be used. Further, a stacked layer structure thereof may also be used.

In this embodiment mode, the wiring layers 840a, 840b, 840c and 840d are formed as embedded wiring layers to fill contact holes formed in the interlayer insulating layer 827. The wiring layers 840a, 840b, 840c, and 840d, which are the embedded wiring layers, are formed by forming a conductive film having an enough thickness to fill the contact holes and leaving the conductive film only in contact hole portions and removing an unnecessary part of the conductive film.

As lead wiring layers, an insulating layer 828 and wiring layers 841a, 841b, and 841c are formed over the wiring layers 840a, 840b, 840c, and 840d which are embedded.

Through the above-described steps, an n-channel field-effect transistor 832 can be formed using the element region 806 of the single crystal semiconductor layer 116 bonded to the supporting substrate 100 and a p-channel field-effect transistor 831 can be formed using the element region 805 of the single crystal semiconductor layer 116 bonded to the supporting substrate 100 (see FIG. 19E). Note that in this embodiment mode, the n-channel field-effect transistor 832 and the p-channel field-effect transistor 831 are electrically connected by a wiring layer 842b.

In this manner, a CMOS structure is formed by a complementary combination of the n-channel field-effect transistor 832 and the p-channel field-effect transistor 831.

A semiconductor device such as a microprocessor can be manufactured by stacking a wiring, an element and the like over the CMOS structure. A microprocessor includes an arithmetic logic unit (also referred to as ALU), an ALU controller, an instruction decoder, an interrupt controller, a timing controller, a register, a register controller, a bus interface (Bus I/F), a read only memory (ROM), and a memory interface (ROM I/F).

A microprocessor has an integrated circuit having a CMOS structure, and thus low power consumption can be achieved as well as processing speed can be increased.

The structure of the thin film transistor is not limited to that described in this embodiment mode, and may have a single gate structure, in which one channel formation region is formed, a double gate structure, in which two channel formation region are formed, or a triple gate structure, in which three channel formation regions are formed.

This embodiment mode can be carried out in combination with any structure in the other embodiment modes and examples.

### Embodiment Mode 6

Although Embodiment Modes 3 to 5 describe the method of manufacturing a transistor as an example of a method of manufacturing a semiconductor device, a semiconductor device can be manufactured so as to have high added value by forming a variety of semiconductor elements such as a capacitor and a resistor using a substrate having a semiconductor film, together with the transistor. In this embodiment mode, a specific mode of a semiconductor device will be described with reference to drawings.

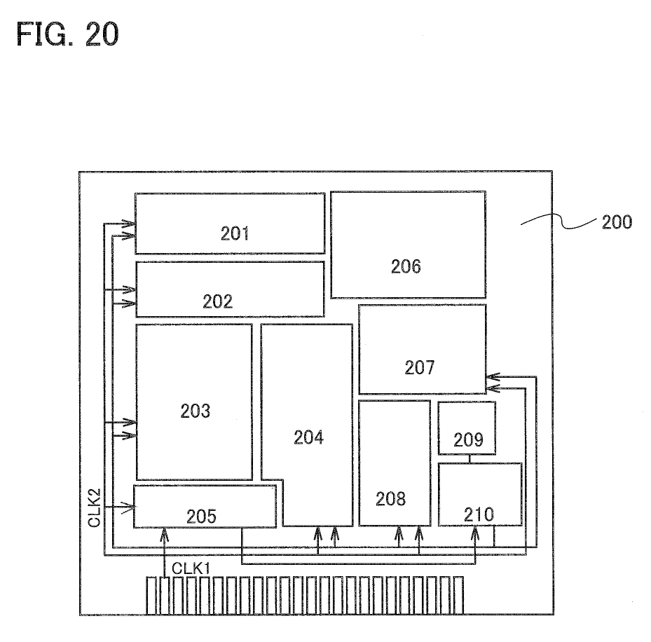

First, as an example of a semiconductor device, a microprocessor will be described. FIG. 20 is a block diagram illustrating a structural example of a microprocessor 200.

The microprocessor 200 includes an arithmetic logic unit (ALU) 201, an ALU controller 202, an instruction decoder 203, an interrupt controller 204, a timing controller 205, a register 206, a register controller 207, a bus interface (bus I/F) 208, a read only memory (ROM) 209, and a memory interface 210.

An instruction input to the microprocessor 200 via the bus interface 208 is input to the instruction decoder 203 and decoded, and then input to the ALU controller 202, the interrupt controller 204, the register controller 207, and the timing controller 205. The ALU controller 202, the interrupt controller 204, the register controller 207, and the timing controller 205 perform various controls based on the decoded instruction.

The ALU controller 202 generates a signal for controlling an operation of the ALU 201. The interrupt controller 204 is a circuit that processes an interruption request from an external input/output device or a peripheral circuit during program execution of the microprocessor 200, and the interrupt controller 204 judges priority of the interruption request or a masked state and processes the interruption request. The register controller 207 generates an address of the register 206 and performs reading and writing from/to the register 206 depending on a state of the microprocessor 200. The timing controller 205 generates signals controlling timing of operation of the ALU 201, the ALU controller 202, the instruction decoder 203, the interrupt controller 204, and the register controller 207. For example, the timing controller 205 is provided with an internal clock generator that generates an internal clock signal CLK2 based on a reference clock signal CLK1. As illustrated in FIG. 20, the internal clock signal CLK2 is input to another circuit.

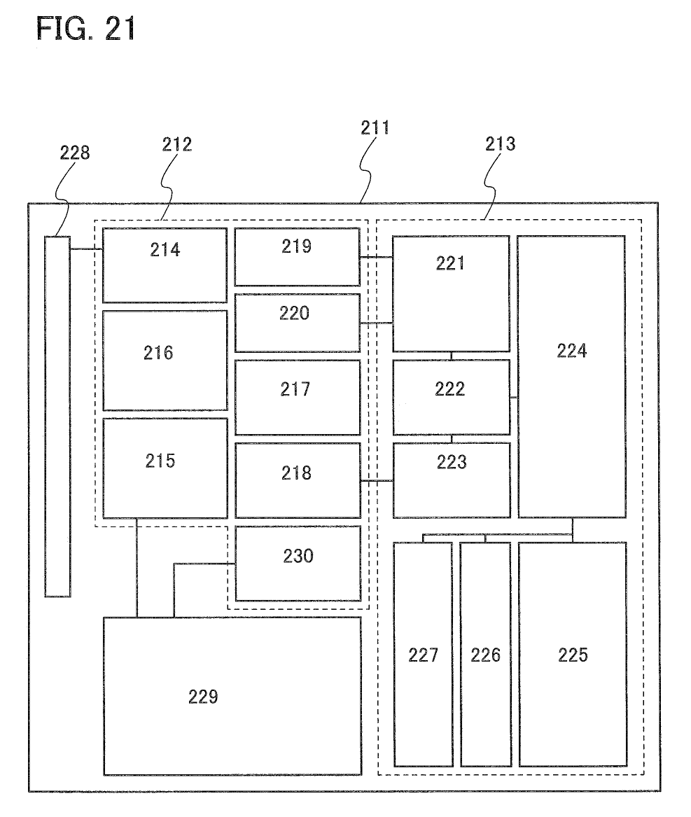

Next, an example of a semiconductor device provided with a function for performing transmission/reception of data without contact and an arithmetic function is described. FIG. 21 is a block diagram illustrating a structural example of such a semiconductor device. A semiconductor device 211 illustrated in FIG. 21 functions as an arithmetic processing unit that operates by transmitting/receiving a signal to/from an external device through wireless communication.

As illustrated in FIG. 21, the semiconductor device 211 includes an analog circuit portion 212 and a digital circuit portion 213. The analog circuit portion 212 includes a resonance circuit 214 having a resonant capacitor, a rectification circuit 215, a constant-voltage circuit 216, a reset circuit 217, an oscillation circuit 218, a demodulation circuit 219, and a modulation circuit 220. Further, the digital circuit portion 213 includes an RF interface 221, a control register 222, a clock controller 223, an interface 224, a central processing unit (CPU) 225, a random access memory (RAM) 226, and a read only memory (ROM) 227.

A summary of the operation of the semiconductor device 211 is as follows. An induced electromotive force is generated in the resonance circuit 214 using a signal received by an antenna 228. The induced electromotive force passes through the rectification circuit 215 and is stored in a capacitor 229. This capacitor 229 is preferably a capacitor such as a ceramic capacitor or an electric double layer capacitor. The capacitor 229 does not always have to be integrated with a substrate included in the semiconductor device 211, and it may be mounted to the semiconductor device 211 as a different component.

The reset circuit 217 generates a signal that resets and initializes the digital circuit portion 213. For example, a signal that rises up lagging behind a rise in power supply voltage is generated as a reset signal. The oscillation circuit 218 changes the frequency and duty ratio of a clock signal depending on a control signal generated in the constant-voltage circuit 216. The demodulation circuit 219 is a circuit that demodulates a reception signal, and the modulation circuit 220 is a circuit that modulates data to be transmitted.

For example, the demodulation circuit 219 is formed using a low-pass filter and binarizes an amplitude-modulated (ASK) received signal based on variation of amplitude. Since the modulation circuit 220 varies the amplitude of an amplitude-modulated (ASK) transmission signal and transmits the data, the modulation circuit 220 changes the amplitude of a communication signal by changing a resonance point of the resonance circuit 214.

The clock controller 223 generates a control signal for changing the frequency and duty ratio of a clock signal depending on power supply voltage or current consumption in the CPU 225. Monitoring of the power supply voltage is performed in a power supply management circuit 230.

A signal input to the semiconductor device 211 from the antenna 228 is demodulated in the demodulation circuit 219, and then separated into a control command, data, and the like in the RF interface 221. The control command is stored in the control register 222. In the control command, instructions for reading data that is stored in the ROM 227, writing data in the RAM 226, performing an arithmetic calculation in the CPU 225, and the like are included.

The CPU 225 accesses the ROM 227, the RAM 226, and the control register 222 via the interface 224. The interface 224 has a function of generating an access signal corresponding to any of the ROM 227, the RAM 226, and the control register 222, based on an address requested by the CPU 225.

As an arithmetic method of the CPU 225, a method may be employed in which an operating system (OS) is stored in the ROM 227 and a program is read and executed at the time of starting operation. Alternatively, a method may be employed in which a dedicated circuit is provided as an arithmetic circuit and an arithmetic process is performed using hardware. In a method of using both hardware and software, part of an arithmetic process is performed in a dedicated arithmetic circuit, and then the rest of the arithmetic process is performed using a program in the CPU 225.

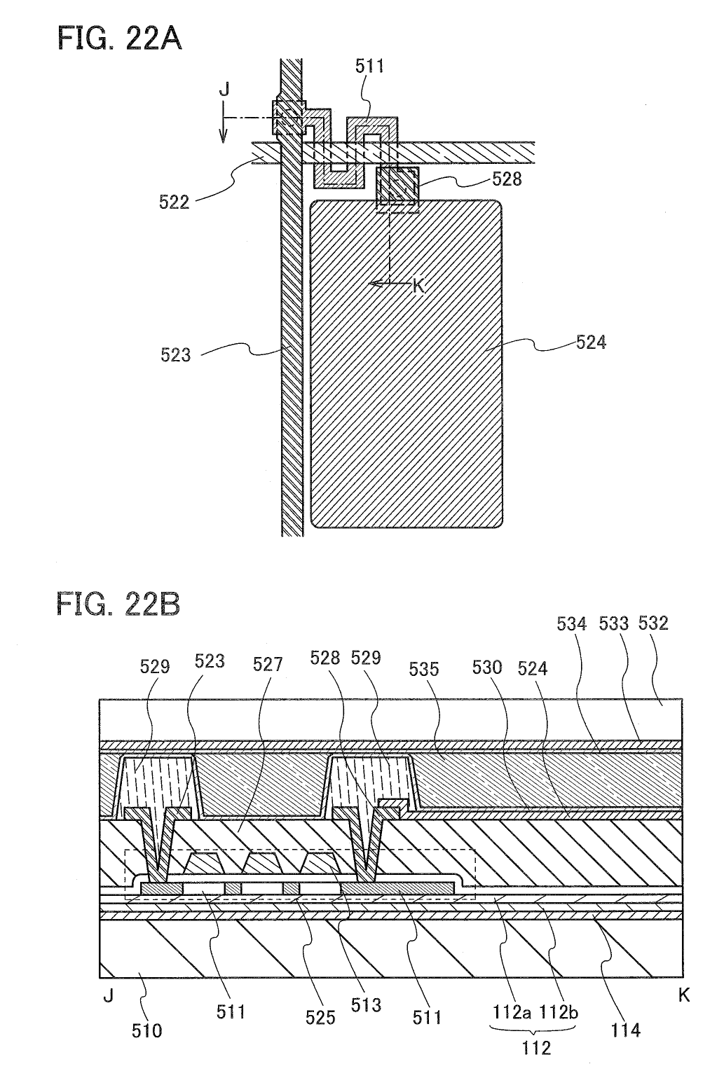

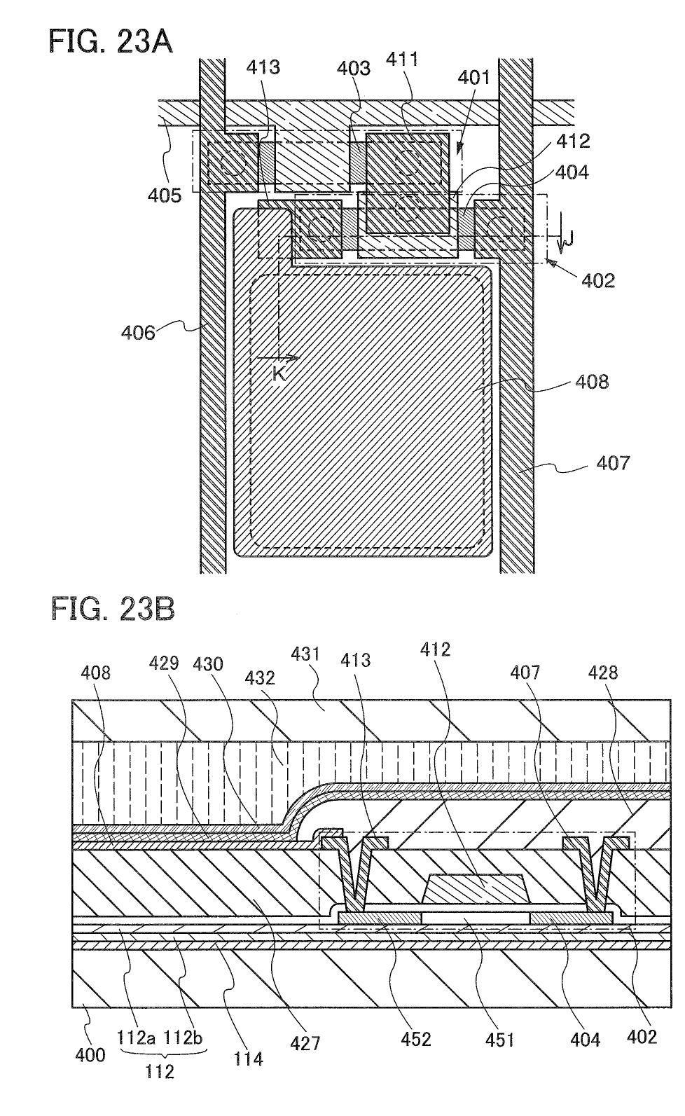

Next, a display device is described as a structural example of a semiconductor device, with reference to FIGS. 22A and 22B, and FIGS. 23A and 23B.

FIGS. 22A and 22B are diagrams illustrating a structural example of a liquid crystal display device. FIG. 22A is a plan view of a pixel of the liquid crystal display device, and FIG. 22B is a cross-sectional view of the diagram of FIG. 22A along a section line J-K. In FIG. 22A, a semiconductor layer 511 is a layer formed from the single crystal semiconductor layer 116, and forms a transistor 525 of the pixel. The pixel includes the semiconductor layer 511; a scan line 522 that crosses the semiconductor layer 511; a signal line 523 that crosses the scan line 522; a pixel electrode 524; and an electrode 528 that is electrically connected to the pixel electrode 524 and the semiconductor layer 511. The semiconductor layer 511 is a layer that is the semiconductor layer 511 attached to an SOI substrate, and forms a pixel transistor 525.

As illustrated in FIG. 22B, the bonding layer 114, the insulating layer 112 including the insulating film 112b and the insulating film 112a, and the semiconductor layer 511 are stacked over a substrate 510. The substrate 510 is a separated supporting substrate 100. The semiconductor layer 511 is a layer formed by element separation of the single crystal semiconductor layer 116 by etching. In the semiconductor layer 511, a channel formation region 512 and an n-type impurity region 513 are formed. A gate electrode of the transistor 525 is included in the scan line 522, and one of a source electrode and a drain electrode is included in the signal line 523.

Over an interlayer insulating film 527, the signal line 523, the pixel electrode 524, and the electrode 528 are provided. Over the interlayer insulating film 527, a columnar spacer 529 is formed, and an orientation film 530 is formed so as to cover the signal line 523, the pixel electrode 524, the electrode 528, and the columnar spacer 529. Over a counter substrate 532, a counter electrode 533 and an orientation film 534 that covers the counter electrode 533 are formed. The columnar spacer 529 is formed to maintain a space between the substrate 510 and the counter substrate 532. In the space formed by the columnar spacer 529, a liquid crystal layer 535 is formed. At connection portions of the signal line 523 and the electrode 528 with the impurity region 513, because there are steps formed in the interlayer insulating film 527 due to formation of contact holes, orientation of liquid crystals in the liquid crystal layer 535 in these connection portions becomes disordered easily. Accordingly, the columnar spacer 529 is formed at these step portions to prevent orientation disorder of liquid crystal.

Next, an electroluminescent display device (hereinafter referred to as an “EL display device”) will be described. FIGS. 23A and 23B are diagrams for describing an EL display device. FIG. 23A is a plan view of a pixel of the EL display device, and FIG. 23B is a cross-sectional view of the pixel. As illustrated in FIG. 23A, the pixel includes a selection transistor 401, a display control transistor 402, a scan line 405, a signal line 406, a current supply line 407, and a pixel electrode 408. Each pixel is provided with a light-emitting element with a structure in which a layer containing an electroluminescent material (EL layer) is interposed between a pair of electrodes. One of the electrodes of the light-emitting element is the pixel electrode 408.

The selection transistor 401 includes the semiconductor layer 403 that is made of the single crystal semiconductor layer 116. In the selection transistor 401, a gate electrode is included in the scan line 405, one of source and drain electrodes is included in the signal line 406, and the other of the source and drain electrodes is formed as an electrode 411. In the display control transistor 402, a gate electrode 412 is electrically connected to the electrode 411, and one of source and drain electrodes is formed as an electrode 413 that is electrically connected to the pixel electrode 408, and the other of the source and drain electrodes is included in the current supply line 407.

The display control transistor 402 is a p-channel transistor, and includes the semiconductor layer 404 that is made of the single crystal semiconductor layer 116. As illustrated in FIG. 23B, in the semiconductor layer 404, a channel formation region 451 and a p-type impurity region 452 are formed. An interlayer insulating film 427 is formed so as to cover the gate electrode 412 of the display control transistor 402. Over the interlayer insulating film 427, the signal line 406, the current supply line 407, the electrodes 411 and 413, and the like are formed. In addition, over the interlayer insulating film 427, the pixel electrode 408 that is electrically connected to the electrode 413 is formed. A peripheral portion of the pixel electrode 408 is surrounded by an insulating partition layer 428. An EL layer 429 is formed over the pixel electrode 408, and a counter electrode 430 is formed over the EL layer 429. A counter substrate 431 is provided as a reinforcing plate, and the counter substrate 431 is fixed to a substrate 400 with a resin layer 432. The substrate 400 is a separated supporting substrate 100.

Accordingly, a wide variety of electronic devices can be manufactured using the semiconductor substrate 10. The electronic devices include cameras such as video cameras and digital cameras; navigation systems; sound reproduction systems (a car audio system, audio components, and the like); computers; game machines; mobile information terminals (mobile computers, mobile phones, mobile game machines, electronic books, and the like); display devices that display image data, such as image reproduction devices provided with a recording medium (specifically, digital versatile disc (DVD)); and the like.

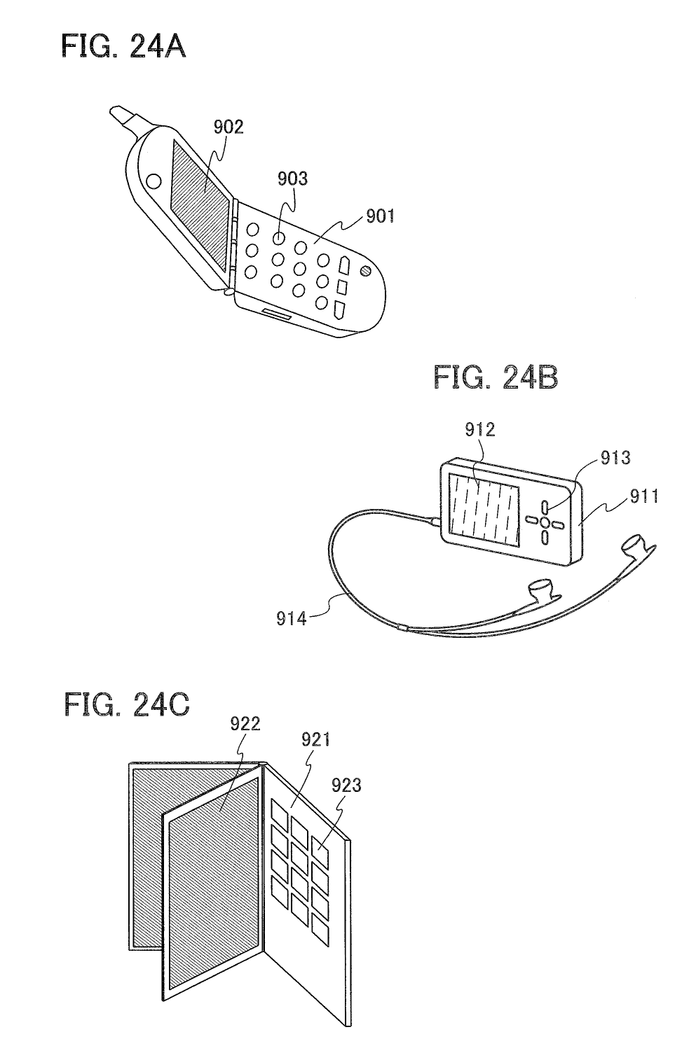

With reference to FIGS. 24A to 24C, specific modes of the electronic devices are described. FIG. 24A is an external view illustrating an example of a mobile phone 901. This mobile phone 901 has a structure in which a display portion 902, an operation switch 903, and the like are included. By applying the liquid crystal display device described in FIGS. 22A and 22B or the EL display device described in FIGS. 23A and 23B to the display portion 902, the display portion 902 can display excellent image quality with little display unevenness.

FIG. 24B is an external view illustrating a structural example of a digital audio player 911. The digital audio player 911 includes a display portion 912, an operation portion 913, an earpiece 914, and the like. Alternatively, headphones or a wireless earpiece can be sued instead of the earpiece 914. By applying the liquid crystal display device described in FIGS. 22A and 22B or the EL display device described in FIGS. 23A and 23B to the display portion 912, even in the case where the screen size is about 0.3 inches to 2 inches, an image with high precision and a large amount of text information can be displayed.

FIG. 24C is an external view of an electronic book 921. This electronic book 921 includes a display portion 922 and an operation switch 923. A modem may be incorporated into the electronic book 921, or the semiconductor device 211 in FIG. 21 may be incorporated so that the electronic book 921 has a structure by which information can be transmitted/received wirelessly. By applying the liquid crystal display device described in FIGS. 22A and 22B or the EL display device described in FIGS. 23A and 23B to the display portion 922, a display with high image quality can be performed.

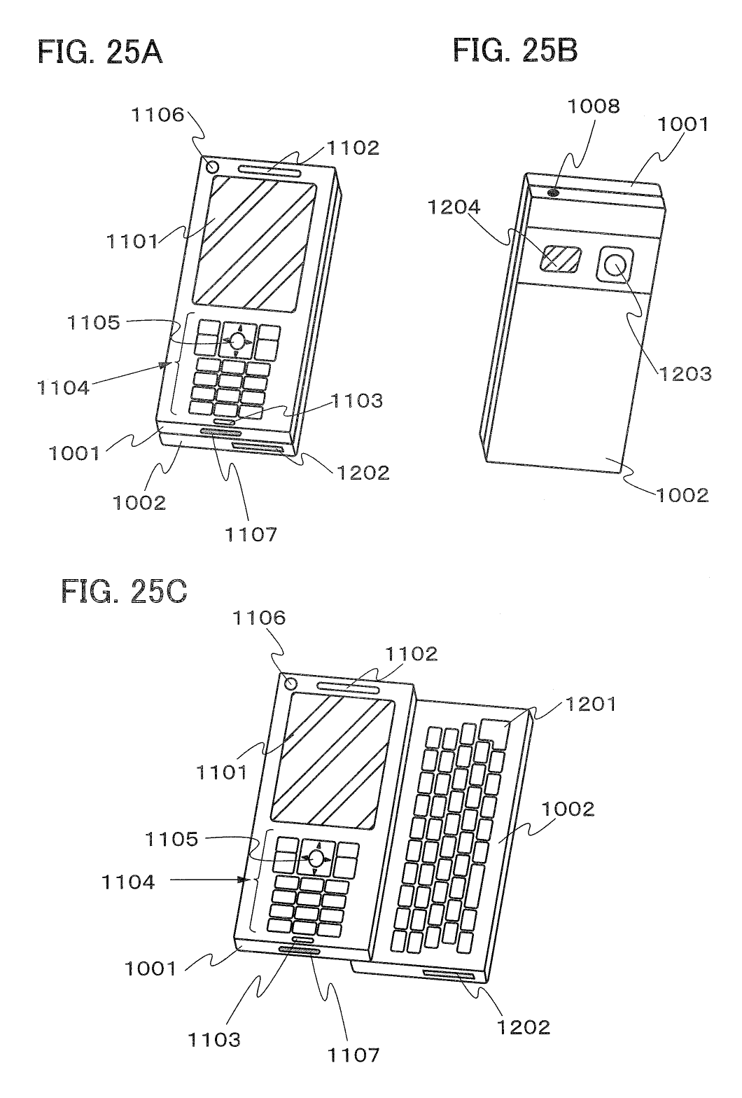

FIGS. 25A to 25C illustrate an example of a phone which is different from the mobile phone illustrated in FIG. 24A. FIGS. 25A to 25C illustrate an example of a structure of a smartphone to which the present invention is applied. FIG. 25A is a front view, FIG. 25B is a rear view, and FIG. 25C is a development view. The smartphone has two housings 1001 and 1002. The smartphone 1000 has both a function of a mobile phone and a function of a portable information terminal, and incorporates a computer provided to conduct a variety of data processing in addition to verbal communication (voice calls); therefore, it is called smartphone.

The smartphone 1000 has the two housings 1001 and 1002. The housing 1001 includes a display portion 1101, a speaker 1102, a microphone 1103, operation keys 1104, a pointing device 1105, a front camera lens 1106, an external connection terminal 1107, an earphone terminal 1108 and the like, while the housing 1002 includes a keyboard 1201, an external memory slot 1202, a rear camera lens 1203, a light 1204 and the like. In addition, an antenna is incorporated in the housing 1001.

Further, in addition to the above structure, the smartphone may incorporate a non-contact IC chip, a small size memory device, or the like.

The housing 1001 and housing 1002 (FIG. 25A) which are put together to be lapped with each other are developed by sliding as illustrated in FIG. 25C. In the display portion 1101, the display device described in the above embodiment mode can be incorporated, and display direction can be changed depending on a use mode. Because the front camera lens 1106 is provided in the same plane as the display portion 1101, the smartphone can be used as a videophone. A still image and a moving image can be taken by the rear camera lens 1203 and the light 1204 by using the display portion 1101 as a viewfinder. The speaker 1102 and the microphone 1103 can be used for uses of videophone, recording, playback and the like without being limited to verbal communication. With use of the operation keys 1104, operation of incoming and outgoing calls, simple information input of electronic mail or the like, scrolling of a screen, cursor motion and the like are possible. If much information is needed to be treated, such as documentation, use as a portable information terminal, and the like, the use of the keyboard 1201 is convenient. Further, when the housing 1001 and housing 1002 (FIG. 25A) which are put together to be lapped with each other are developed by sliding as illustrated in FIG. 25C, and used as a portable information terminal, smooth operation can be conducted by using the keyboard 1201 or the pointing device 1105. The external connection terminal 1107 can be connected to an AC adaptor and various types of cables such as a USB cable, and charging and data communication with a personal computer or the like are possible. Moreover, a large amount of data can be stored by inserting a storage medium into the external memory slot 1202 and can be moved. In the rear surface of the housing 1002 (FIG. 25B), the rear camera lens 1203 and the light 1204 are provided, and a still image and a moving image can be taken by using the display portion 1101 as a viewfinder.

Further, the smartphone may include an infrared communication function, a USB port, a function of a television receiver or the like, in addition to the above-described functions.

This embodiment mode can be carried out in combination with any structure in the other embodiment modes and examples.

### EXAMPLE 1

Hereinafter, examples of the present invention will be described in more detail. However, the present invention is not limited by these examples, and it is obvious that the present invention is specified by the scope of claims. In Example 1, the surface roughness and crystallographic physical properties of a semiconductor layer of an SOI substrate as a substrate of the present invention before laser light irradiation and after laser light irradiation will be described.

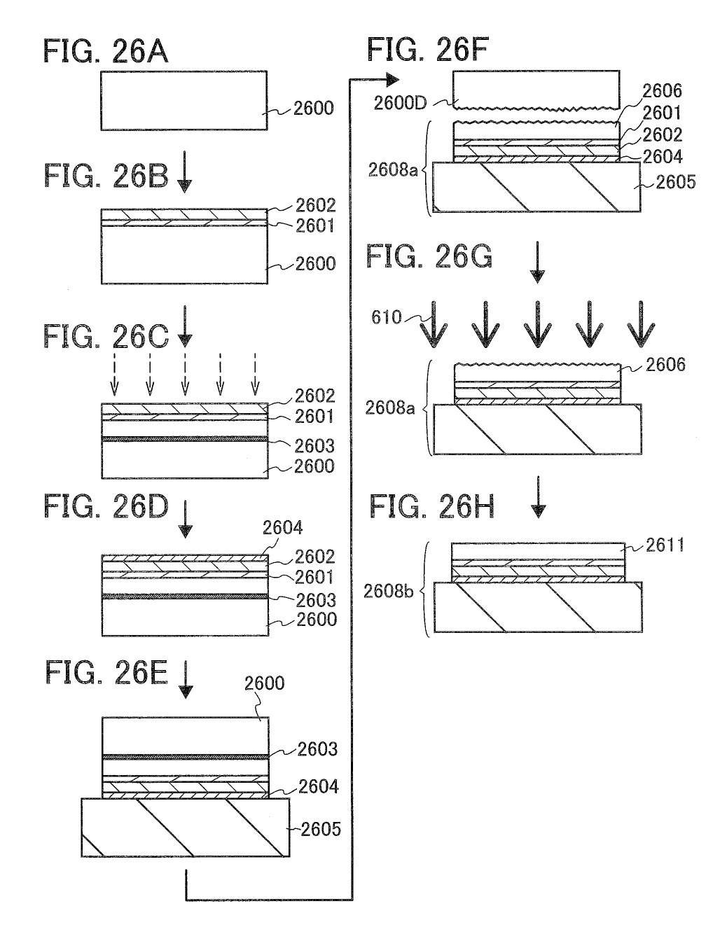

A manufacturing method of an SOI substrate of this example will be described with reference to FIGS. 26A to 26H. The manufacturing method shown in FIGS. 26A to 26H corresponds to the manufacturing method described in Embodiment Mode 2.

A single crystal silicon substrate (hereinafter, referred to as a c-Si substrate 2600) was prepared as a semiconductor substrate (see FIG. 26A). The c-Si substrate 2600 was a p-type silicon substrate of 5 inches in diameter, and the plane orientation and the side orientation thereof were (100) and <110> respectively.

The c-Si substrate 2600 was washed with pure water and dried. Then, a silicon oxynitride film 2601 was formed over the c-Si substrate 2600 with a parallel plate type plasma CVD apparatus, and a silicon nitride oxide film 2602 was formed over the silicon oxynitride film 2601 (see FIG. 26B).

The silicon oxynitride film 2601 and the silicon nitride oxide film 2602 were successively formed with the parallel plate type plasma CVD apparatus without exposing the c-Si substrate 2600 to air. At that time, film formation conditions were as follows. Here, before forming the silicon oxynitride film 2601, a step of removing an oxide film of the c-Si substrate 2600 by washing the c-Si substrate 2600 with a hydrofluoric acid for 60 seconds was performed.

<Silicon oxynitride film 2601>

| | |
|---|---|
| Thickness | 50 nm |
| Kind of gas (flow rate) | SiH₄ (4 sccm) |
| | N₂O (800 sccm) |
| Substrate temperature | 400° C. |
| Pressure | 40 Pa |
| RF frequency | 27 MHz |
| RF power | 50 W |
| Distance between electrodes | 15 mm |
| Electrode area | 615.75 cm² |

<Silicon nitride oxide film 2602>

| | |
|---|---|
| Thickness | 50 nm |
| Kind of gas (flow rate) | SiH₄ (10 sccm) |
| | NH₃ (100 sccm) |
| | N₂O (20 sccm) |
| | H₂ (400 sccm) |
| Substrate temperature | 300° C. |
| Pressure | 40 Pa |
| RF frequency | 27 MHz |
| RF power | 50 W |
| Distance between electrodes | 30 mm |
| Electrode area | 615.75 cm² |

As shown in FIG. 26C, hydrogen ions were added to the c-Si substrate 2600 with an ion doping apparatus to form an ion-added layer 2603. As a source gas, a 100% hydrogen gas was used, and without mass separation of ionized hydrogen, the ionized hydrogen was accelerated by electric field so as to be added into the c-Si substrate 2600. Detailed conditions were as follows.

| | |
|---|---|
| Source gas | H₂ |
| RF power | 150 W |
| Accelerating voltage | 40 kV |
| Dose | 1.75 × 10¹⁶ ions/cm² |

In the ion doping apparatus, three kinds of ion species that are H⁺, H₂⁺, and H₃⁺ are generated from the hydrogen gas, and the c-Si substrate 2600 is doped with all of the ion species. The proportion of H₃⁺ in the ion species generated from the hydrogen gas is about 80%.

After forming the ion added layer 2603, the c-Si substrate 2600 was washed with pure water, and a silicon oxide film 2604 having a thickness of 50 nm was formed over the silicon nitride oxide film 2602 with a plasma CVD apparatus. As a source gas for the silicon oxide film 2604, tetraethoxysilane (TEOS, chemical formula: Si(OC₂H₅)₄) and an oxygen gas were used. Film formation conditions of the silicon oxide film 2604 were as follows.

<Silicon oxide film 2604>

| | |
|---|---|
| Thickness | 50 nm |
| Kind of gas (flow rate) | TEOS (15 sccm) |
| | O₂ (750 sccm) |
| Substrate temperature | 300° C. |
| Pressure | 100 Pa |
| RF frequency | 27 MHz |
| RF power | 300 W |
| Distance between electrodes | 14 mm |
| Electrode area | 615.75 cm² |

A glass substrate 2605 was prepared. As the glass substrate 2605, an aluminosilicate glass substrate (product name: AN 100) manufactured by Asahi Glass Co., Ltd. was used. The glass substrate 2605 and the c-Si substrate 2600 over which the silicon oxide film 2604 is formed were washed. As washing treatment, ultrasonic cleaning in pure water was conducted, and then treatment with pure water containing ozone was conducted.

Next, as shown in FIG. 26E, by making the glass substrate 2605 and the c-Si substrate 2600 in close contact with each other, the glass substrate 2605 and the silicon oxide film 2604 were bonded. By this step, the glass substrate 2605 and the c-Si substrate 2600 were bonded to each other. This step was performed at room temperature without heat treatment.

Next, heat treatment was conducted in a diffusion furnace, and the c-Si substrate 2600 was separated at the ion-added layer 2603 as shown in FIG. 26D. First, heating was conducted at 600° C. for 20 minutes. Then, the heat temperature was increased to 650° C. and heating was conducted for 6.5 minutes. By this series of heat treatments, a crack was generated at the ion-added layer 2603 in the c-Si substrate 2600, so that the c-Si substrate 2600 was separated. By heating the c-Si substrate 2600 at equal to or higher than 600° C. in this step, crystallinity of a separated silicon layer becomes close to that of a single crystal.

After the heat treatments, the glass substrate 2605 and a c-Si substrate 2600′ were taken out from the diffusion furnace. Since the glass substrate 2605 and the c-Si substrate 2600 are in the sate of being separated from each other by the heat treatments, an SOI substrate 2608a in which the silicon layer 2606 separated from the c-Si substrate 2600 is fixed to the glass substrate 2605 is formed when the c-Si substrate 2600D is removed as shown in FIG. 26F. Note that the c-Si substrate 2600D corresponds to the c-Si substrate 2600 from which the silicon layer 2606 is separated.

The SOI substrate 2608 a has a structure in which the silicon oxide film 2604, the silicon nitride oxide film 2602, the silicon oxynitride film 2601, and the silicon layer 2606 are stacked in this order over the glass substrate 2605. In this example, the thickness of the silicon layer 2606 was approximately 120 nm.

Next, as shown in FIG. 26G, the silicon layer 2606 of the SOI substrate 2608 a was irradiated with laser beam 2610, thereby forming an SOI substrate 2608b which includes a silicon layer 2611. The silicon layer 2611 illustrated in FIG. 26H corresponds to the silicon layer 2606 after irradiation with the laser beam 2610. Through the above-described process, an SOI substrate 2608b shown in FIG. 26H is formed. A silicon layer 2612 of the SOI substrate 2608b corresponds to the recrystallized silicon layer 2611 which was partially melted by the irradiation with the laser beam.

The specification of the laser used for irradiation with the laser beam 2610 of FIG. 26G is as follows.

<Specification of laser>
XeCl excimer laser

| | |
|---|---|
| Wavelength | 308 nm |
| Pulse width | 25 nanoseconds (nsec) |
| Repetition rate | 30 Hz |

The laser beam 2610 was a linear beam whose cross section is linear and which was formed by an optical system including a cylindrical lens or the like. The c-Si substrate 2600 was moved relative to the laser beam 2610 while irradiation with the laser beam 2610 was conducted. At this time, the scanning speed of the laser beam 2610 was set at 1.0 mm/sec, and the same region was irradiated with 12 shots of the laser beam 2610.

Further, the atmosphere for the laser beam 2610 was set to be an air atmosphere or a nitrogen atmosphere. In this example, a nitrogen atmosphere was formed in such a manner that while irradiation with the laser beam 2610 is conducted in an air atmosphere, a nitrogen gas is blown to the irradiation surface.

The present inventors investigated the effect of irradiation with the laser beam 2610 on planarity and recovery of the crystallinity of the silicon layer 2611 by changing the energy density of the laser beam 2610 in the range of from about 350 mJ/cm² to about 750 mJ/cm². Specific values of the energy density are listed below.

347 mJ/cm²

387 mJ/cm²

431 mJ/cm²

477 mJ/cm²

525 mJ/cm²

572 mJ/cm²

619 mJ/cm²

664 mJ/cm²

706 mJ/cm²

743 mJ/cm²

The planarity of the surface of the silicon layer 2611 and the crystallinity of the silicon layer 2611 were analyzed by observation with an optical microscope, an atomic force microscope (AFM), and a scanning electron microscope (SEM), by observation of an electron back scatter diffraction pattern (EBSP), and by Raman spectroscopy.

The effect on planarization can be evaluated by images observed with a dynamic force mode (DFM) AFM (hereinafter referred to as DFM images), the measurement values showing surface roughnesses obtained from the DFM images, brightness change of dark field images observed with an optical microscope, images observed with a SEM (hereinafter referred to as SEM images), and Raman intensities.

The effect on crystallinity improvement can be evaluated with Raman shifts, full widths at half maximum (FWHM) of Raman spectra, and EBSP images.

First, the effect on planarization by laser irradiation is described, and then, the effect on crystallinity improvement is described.

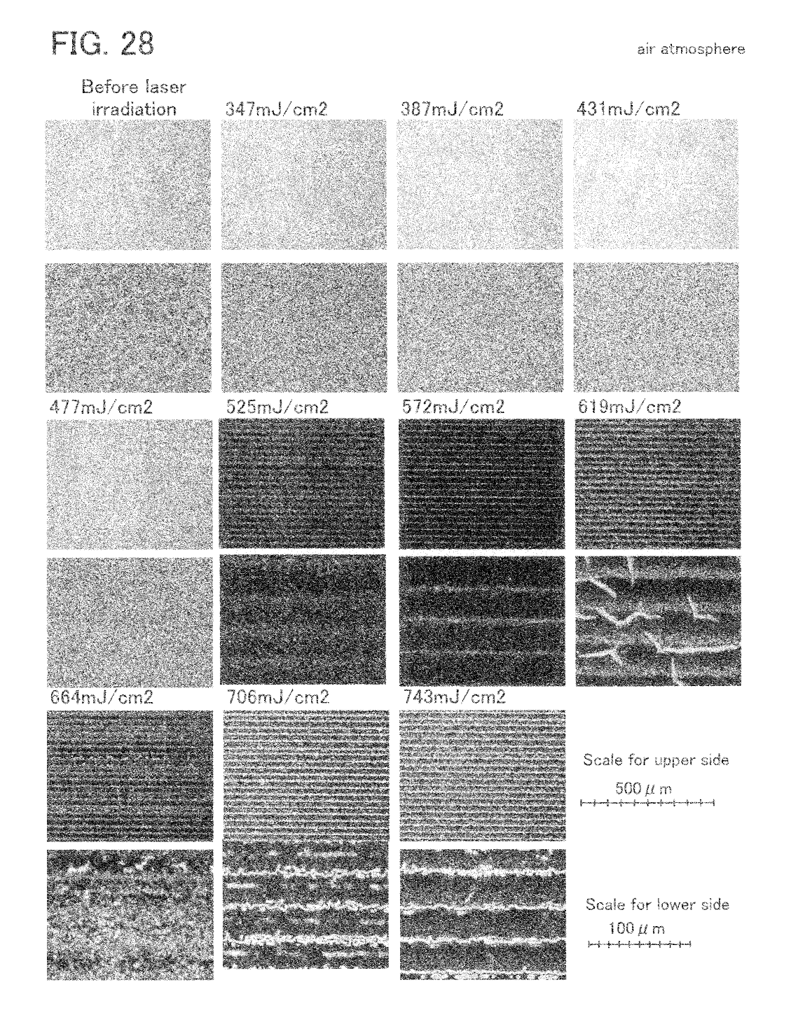

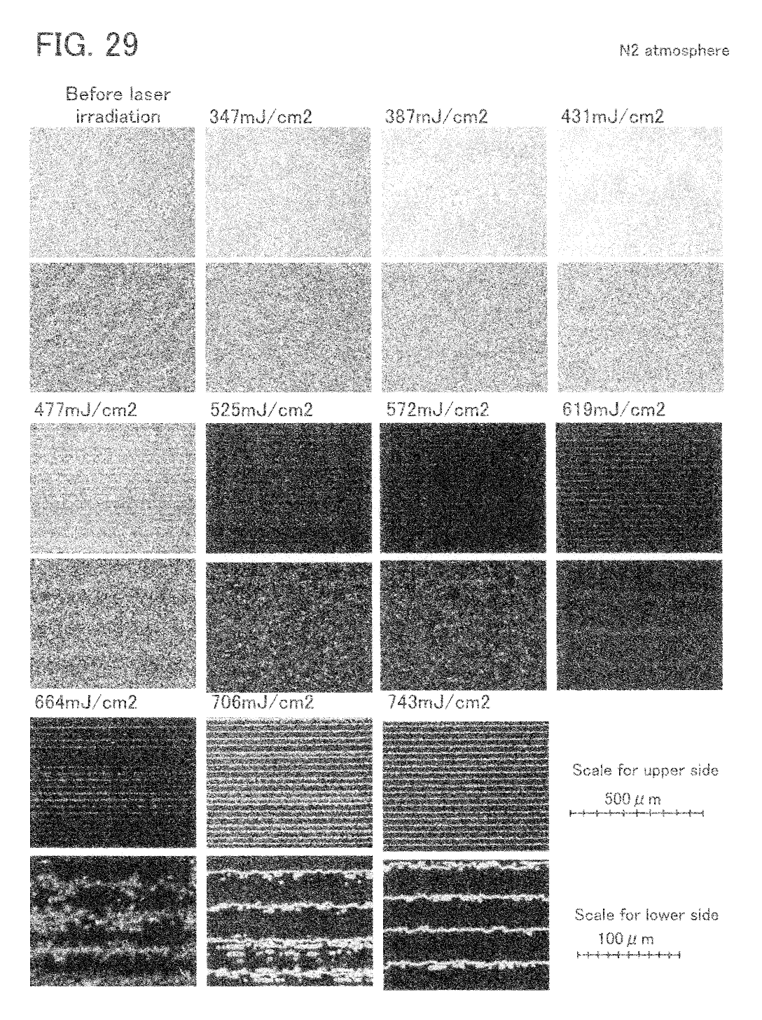

FIG. 28 shows dark field images of the silicon layer 2611 irradiated with the laser light in an air atmosphere, which are observed with an optical microscope. FIG. 29 shows dark field images of the silicon layer 2611 irradiated with the laser light in a nitrogen atmosphere, which are observed with an optical microscope. FIG. 28 and FIG. 29 also show dark field images of the silicon layer 2606 before laser light irradiation. Further, from the dark field images of FIG. 28 and FIG. 29, it is found that by adjusting the energy density, the planarity of the silicon layer can be improved by laser light irradiation in both an air atmosphere and a nitrogen atmosphere.

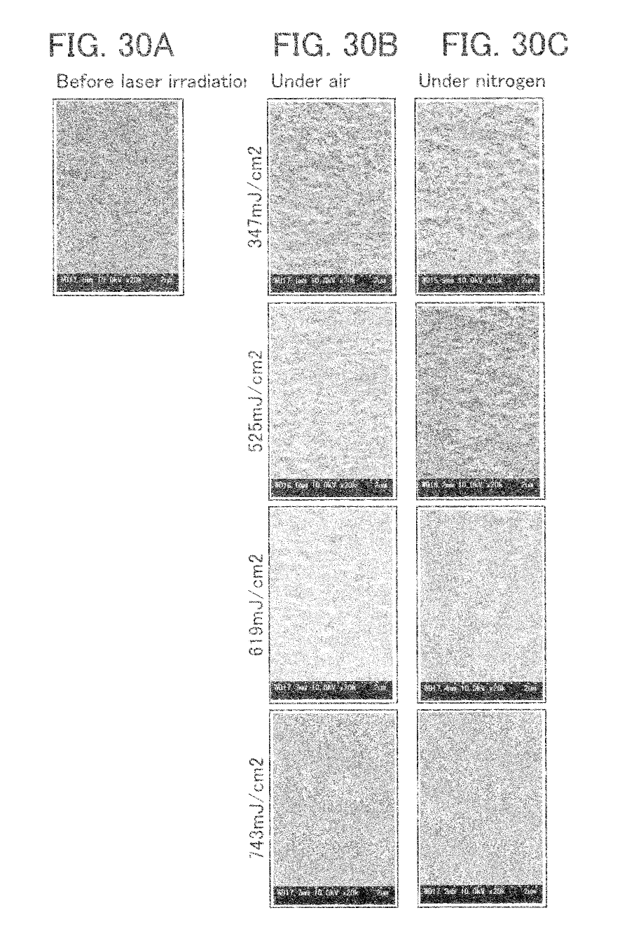

FIGS. 30A to 30C are SEM images. FIG. 30A is a SEM image of the silicon layer 2606 before laser light irradiation. FIG. 30B is a SEM image of the silicon layer 2611 which is processed in an air atmosphere. FIG. 30C is a SEM image of the silicon layer 2611 which is processed in a nitrogen atmosphere.

In this example, an excimer laser was used as the laser. It is known that at a surface of a polycrystalline silicon film formed by crystallizing an amorphous silicon film with an excimer laser, a ridge (a projection and a depression) with a height close to the thickness of the polycrystalline silicon film is formed. However, from the SEM images of FIGS. 30B and 30C, it was found that almost no large ridges are generated at the silicon layer 2611. In other words, it was found that a beam of a pulsed laser such as an excimer laser is effective for planarization of the silicon layer 2606.

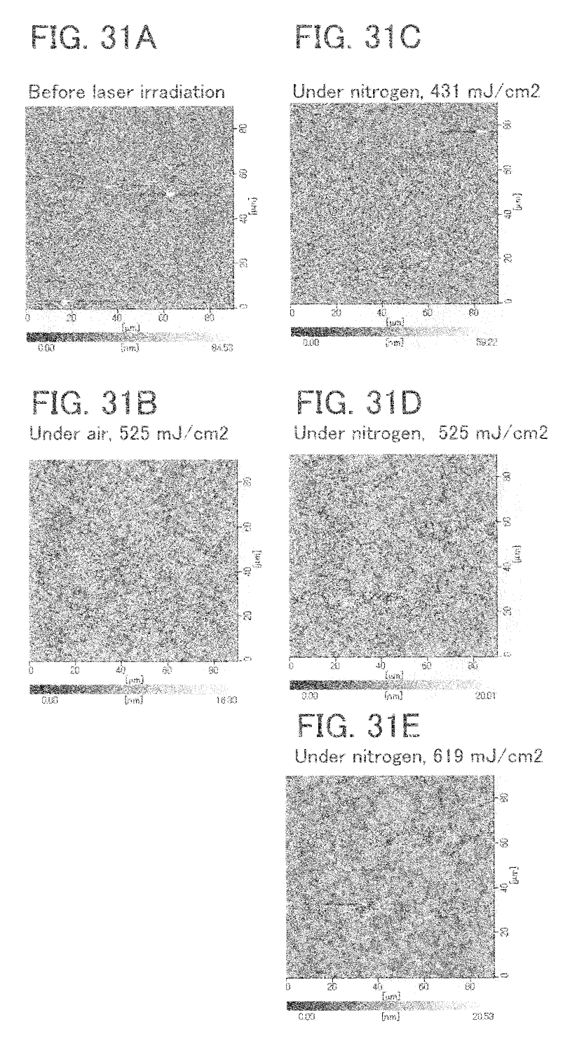

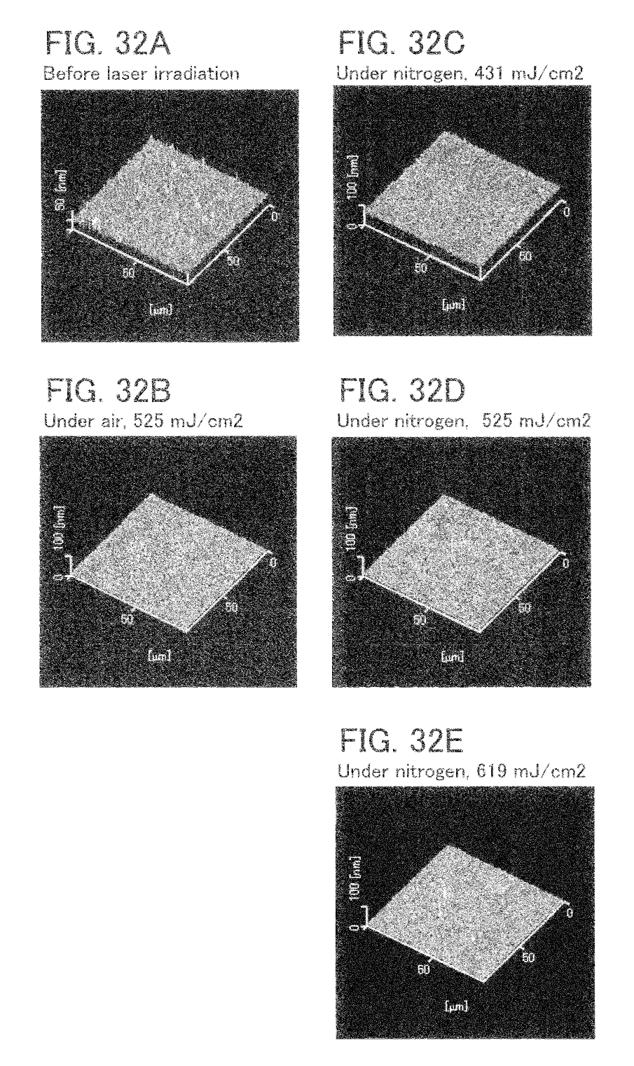

FIGS. 31A to 31E show DFM images observed with an AFM. FIG. 3A is an DFM image of the silicon layer 2606 before laser light irradiation. FIGS. 31B to 31E are DFM images of the silicon layer 2611 after laser light irradiation, and the irradiation atmosphere and the energy density of laser light were varied in FIGS. 31B to 31E. FIGS. 32A to 32E correspond to bird's eye views of FIGS. 31A to 31E.

Table 1 shows surface roughnesses calculated by the DFM images of FIGS. 31A to 31E. In Table 1, Ra denotes average surface roughness, Rms denotes the root mean square of surface roughness, and P−V denotes the value of the largest difference in height between peak and valley.

TABLE 1
Surface roughnesses of the silicon layers.

| | | Energy density^{b} | Ra | Rms | P-V |
|---|---|---|---|---|---|
| Silicon layer | Atmosphere | [mJ/cm²] | [nm] | [nm] | [nm] |
| 606^{a} | — | — | 7.2 | 11.5 | 349.2 |
| 611 | nitrogen | 431 | 5.4 | 7.0 | 202.8 |
| 611 | air | 525 | 1.9 | 2.5 | 33.7 |
| 611 | nitrogen | 525 | 2.3 | 3.0 | 38.1 |
| 611 | nitrogen | 619 | 1.9 | 2.8 | 145.7 |

^{a}Before laser light irradiation.
^{b}Energy density of the laser light.

The Ra of the silicon layer 2606 before laser light irradiation is equal to or more than 7 nm and the Rms thereof is equal to or more than 11 nm; these values are close to the values of a polycrystalline silicon film formed by crystallizing amorphous silicon having a thickness of about 60 nm with an excimer laser. The present inventors have already found that, when using such a polycrystalline silicon film, the thickness of an applicable gate insulating layer is larger than the polycrystalline silicon film. Therefore, even when the silicon layer 2606 is thinned, it is difficult to form a gate insulating layer having a thickness of equal to or less than 10 nm on the surface of the silicon layer 2606. Accordingly, it is difficult to manufacture a transistor with high performance, which utilizes characteristics of thinned single crystal silicon.

On the other hand, the Ra of the silicon layer 2611 irradiated with the laser light is decreased to about 2 nm, and the Rms thereof is decreased to about 2.5 nm to 3 nm. Therefore, by thinning the silicon layer 2611 having such planarity, a transistor with high performance, which utilizes characteristics of a thinned single crystal silicon layer can be manufactured.

Hereinafter, crystallinity improvement by laser light irradiation will be described.

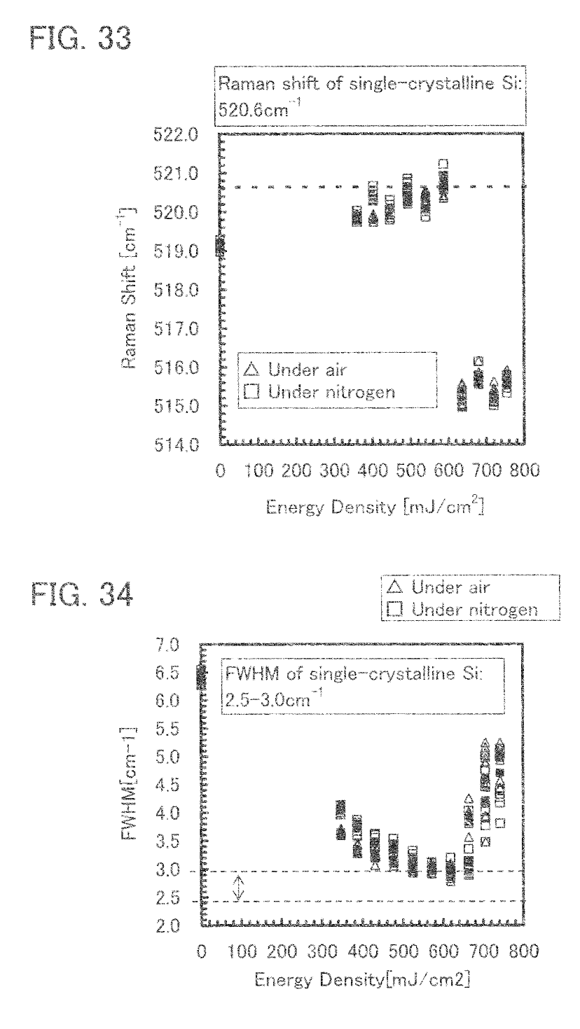

FIG. 33 is a graph showing Raman shifts of the silicon layer 2606 before laser light irradiation and the silicon layer 2611 after irradiation and showing variation of Raman shifts with respect to the energy density of the laser beam. As the wavenumber of the Raman shift of the silicon layer is closer to 520.6 cm⁻¹ that is the wavenumber of the Raman shift of single crystal silicon, the silicon layer has a higher crystallinity. From the graph of FIG. 33, it was found that by adjusting the energy density, crystallinity of the silicon layer 2611 can be improved by laser light irradiation in an air atmosphere and a nitrogen atmosphere.

FIG. 34 is a graph showing full widths at half maximum of Raman spectra of the silicon layer 2606 before laser irradiation and the silicon layer 2611 after irradiation and showing variation of the FWHMs with respect to the energy density of the laser beam 2610. As the wavenumber of the FWHM of the silicon layer is closer to 2.5 to 3.0 cm⁻¹ that is the wavenumber of the FWHM of single crystal silicon, the silicon layer has a higher crystallinity. From the graph of FIG. 34, it was found that by adjusting the energy density, crystallinity of the silicon layer 2611 can be improved by laser irradiation in an air atmosphere and a nitrogen atmosphere.

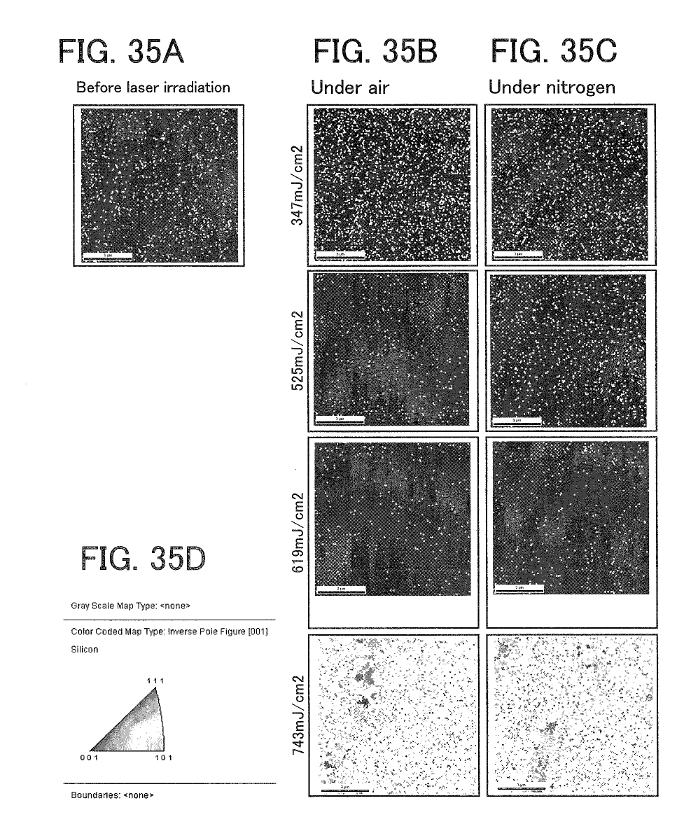

FIGS. 35A to 35C are inverse pole figure (IPF) maps obtained from the measurement data of the EBSP of the silicon layer surface. FIG. 35D is a color code map showing the relationship between colors of the IPF maps and crystal orientation, in which the orientation of each crystal is color-coded. FIGS. 35A, 35B, and 35C are IPF maps of the silicon layer 2606 before laser light irradiation, the silicon layer 2611 after laser light irradiation in an air atmosphere, and the silicon layer 2611 after laser light irradiation in a nitrogen atmosphere, respectively.

According to the IPF maps of FIGS. 35A to 35C, when the energy density is in a range of 380 mJ/cm² to 620 mJ/cm², the plane orientation of the silicon layer is not disordered from before laser light irradiation to after laser light irradiation; the plane orientation of the surface of the silicon layer 2611 is (100) which is the same as the plane orientation of the used c-Si substrate 2600; and crystal grain boundaries do not exist. This can be understood by the fact that most part of the IPF maps is expressed by the color which exhibits (100) direction in the color code map of FIG. 35D (red color in the color code map). Since the crystal orientation of IPF maps is disordered at an energy density of 743 mJ/cm² in both an air atmosphere and a nitrogen atmosphere, it is considered that the silicon layer 2611 was completely melted and crystals are grown in a disordered orientation.

From Table 1 and FIGS. 28 to 35D, it was found that planarity of a silicon layer which is separated from a single crystal silicon substrate can be improved and at the same time, crystallinity thereof can be recovered by laser light irradiation in an air atmosphere and a nitrogen atmosphere. In this example, it was found that the energy density of the laser light with which the improvement in planarity and recovery of crystallinity can be realized at the same time is equal to or higher than 500 mJ/cm² and equal to or lower than 600 mJ/cm² in the case of the air atmosphere and is equal to or higher than 400 mJ/cm² and equal to or lower than 600 mJ/cm² in the case of the nitrogen atmosphere, and that the applicable range of energy density is wider in the case of the nitrogen atmosphere than the case of the air atmosphere.

Further, the irradiation condition of a laser beam in FIG. 26G was changed and the concentration of hydrogen ions in a film was measured by SIMS (a secondary ion mass spectrometry method). The specification of the laser used for irradiation with the laser beam 2610 of FIG. 26G is as follows.

<Laser specification>
XeCl excimer laser

| | |
|---|---|
| Wavelength | 308 nm |
| Pulse width | 25 nanoseconds (nsec) |
| Repetition rate | 30 Hz |

The laser beam 2610 is a linear beam whose beam spot was linear and which was formed by an optical system including a cylindrical lens or the like. The c-Si substrate 2600 was moved relative to the laser beam 2610 while irradiation with the laser beam 2610 was conducted. At this time, the scanning speed of the laser beam 2610 was 1.0 mm/sec and the beam width was 340 μm, and the same region was irradiated with ten shots of the laser beam 2610. In this case, the overlapping percentage of the laser beams 2610 repeatedly delivered to the same region was 90%.

Further, the atmosphere for the laser beam 2610 was set to be an air atmosphere or a nitrogen atmosphere. In this example, the nitrogen atmosphere was formed in such a manner that while irradiation with the laser beam 2610 was conducted in an air atmosphere, a nitrogen gas was blown to the irradiation surface.

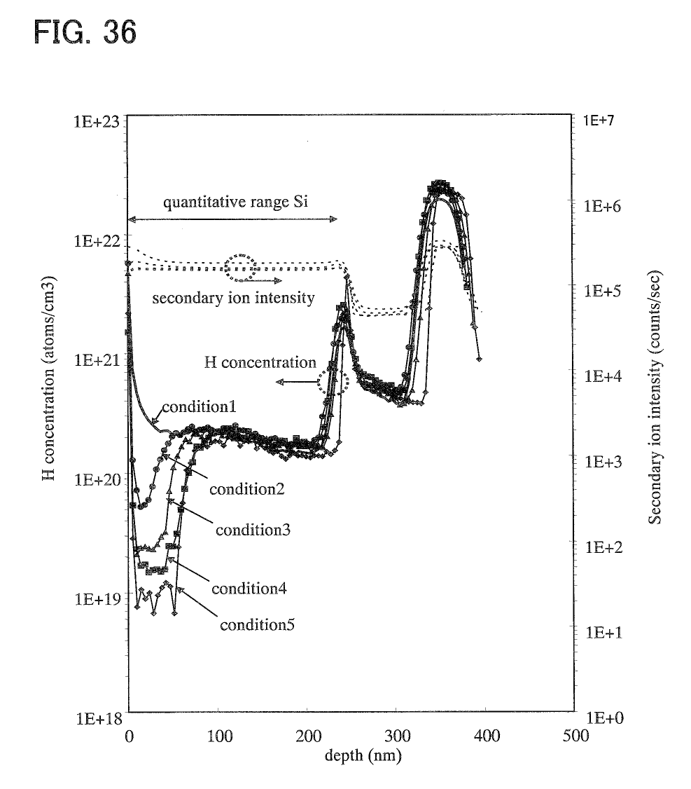

The present inventors examined by SIMS (a secondary ion mass spectrometry method) a hydrogen concentration in the silicon layer 2611 obtained by irradiation with the laser beam 2610 in an air atmosphere or a nitrogen atmosphere with the energy density of the laser beam 2610 changed in the range of about 350 mJ/cm² to 750 mJ/cm². In FIG. 36, the vertical axis shows concentration (atoms/cm³), while the horizontal axis shows depth (nm) to which the sample was etched. For comparison, an ion concentration in the case where laser irradiation was not conducted was examined by SIMS (a secondary ion mass spectrometry method). In FIG. 36, in the range of the depth direction represented by “quantitative range Si”, hydrogen concentration in the silicon layer 2611 was quantified. The silicon layer whose hydrogen concentration was quantified as shown in FIG. 36 was formed over a silicon oxynitride layer which had a thickness of 50 nm and was formed over a silicon nitride oxide layer, the silicon nitride oxide layer had a thickness of 50 nm and was formed over a silicon oxide layer, the silicon oxide layer had a thickness of 100 nm and was formed using TEOS. In addition, specific values of the energy density of the laser beam 2610 with which the silicon layer was irradiated and the atmospheres for laser irradiation are as follows.
no laser irradiation, air atmosphere (Condition 1)
449.0 mJ/cm², nitrogen atmosphere (Condition 2)
543.1 mJ/cm², nitrogen atmosphere (Condition 3)
543.1 mJ/cm², air atmosphere (Condition 4)
637.3 mJ/cm², nitrogen atmosphere (Condition 5)

In FIG. 36, a heavy broken line shows data of the condition 1 of no laser irradiation and air atmosphere; a broken line with circles shows data of the condition 2 of 449.0 mJ/cm2 and nitrogen atmosphere; a broken line with triangles shows data of the condition 3 of 543.1 mJ/cm and nitrogen atmosphere; a broken line with squares shows data of the condition 4 of 543.1 mJ/cm² and air atmosphere; and a broken line with rhombi shows data of the condition 5 of 637.3 mJ/cm² and nitrogen atmosphere. As shown in FIG. 36, it is found that the hydrogen concentration was reduced in the surface of the silicon layer and a region in the thickness direction by laser irradiation, regardless of the energy density. The reduction of the hydrogen concentration caused by the laser irradiation was not seen in the condition 1 of no laser irradiation, and thus it can be said that the hydrogen concentration was reduced because hydrogen was vaporized as a result of melting of the silicon layer by laser irradiation. Further, in the quantitative silicon layer, it is found that distribution of the hydrogen concentration in the surface and the region in the depth direction of the silicon layer becomes smaller under the conditions of laser irradiation, but the hydrogen concentration was kept constant at about 100 nm in the depth direction of the silicon layer. It can be said that the difference in the hydrogen concentration in the quantitative silicon layer elucidates to what degree the silicon layer is melted in the depth direction by laser irradiation. In other words, it is found that the surface and a portion in the depth direction of the silicon layer are melted by laser irradiation.

The present inventors examined a shift amount of drain current to gate voltage of a thin film transistor formed using a silicon layer which is recrystallized by being partially melted by laser irradiation. For comparison, the present inventors also examined a shift amount of drain current to gate voltage of a thin film transistor formed using a silicon layer which was not irradiated with a laser beam. Each thin film transistor was a staggered type transistor, and a gate length and a gate width of each thin film transistor and a thickness of a gate insulating film were 10 μm, 8 μm, and 110 nm, respectively. In addition, the energy density of the laser beam 2610 delivered to the silicon layer was 500 mJ/cm² and the atmosphere for laser irradiation was an air atmosphere.

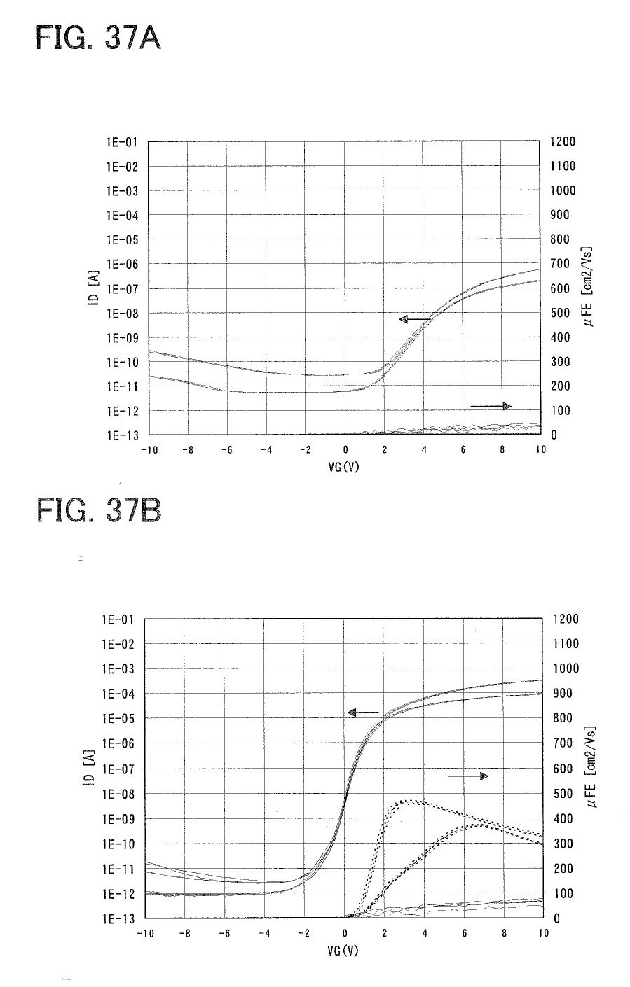

FIGS. 37A and 37B show measurement data of a shift amount of drain current with respect to gate voltage in thin film transistors. FIG. 37A shows measurement data of the thin film transistor formed using a silicon layer which was not irradiated with a laser beam, and FIG. 37B shows measurement data of the thin film transistor formed using a silicon layer which was partially melted and recrystallized. As apparent from FIGS. 37A and 37B, it is found that the thin film transistor of FIG. 37B, which had surface planarity of the silicon layer improved by laser irradiation and had crystallinity thereof improved by recrystallization, has more excellent characteristics with small subthreshold swing (S factor) and high mobility.

This example can be carried out in combination with any structure in the other embodiment modes.

### EXAMPLE 2

In this example, an ion irradiation method in forming a damaged layer is considered.

In the embodiment modes described above, in forming a damaged layer, a single crystal semiconductor substrate is irradiated with ions that are derived from hydrogen (H) (hereafter referred to as “hydrogen ion species”). More specifically, a hydrogen gas or a gas which contains hydrogen in its composition is used as a source material; a hydrogen plasma is generated; and a single crystal semiconductor substrate is irradiated with the hydrogen ion species in the hydrogen plasma.

### (Ions in Hydrogen Plasma)

In such a hydrogen plasma as described above, hydrogen ion species such as H⁺ ions, H₂⁺ ions, and H₃⁺ ions are present. Here are listed reaction equations for reaction processes (formation processes, destruction processes) of the hydrogen ion species.

e+H→e+H⁺+e (1)

e+H₂→e+H₂⁺+e (2)

e+H₂→e+(H₂)*→e+H+H (3)

e+H₂⁺→e+(H₂⁺)*→e+H⁺+H (4)

H₂⁺+H₂→H₃⁺+H (5)

H₂⁺+H₂→H⁺+H+H₂ (6)

e+H₃⁺→e+H⁺+H+H (7)

e+H₃⁺→H₂+H (8)

e+H₃⁺→H+H+H (9)

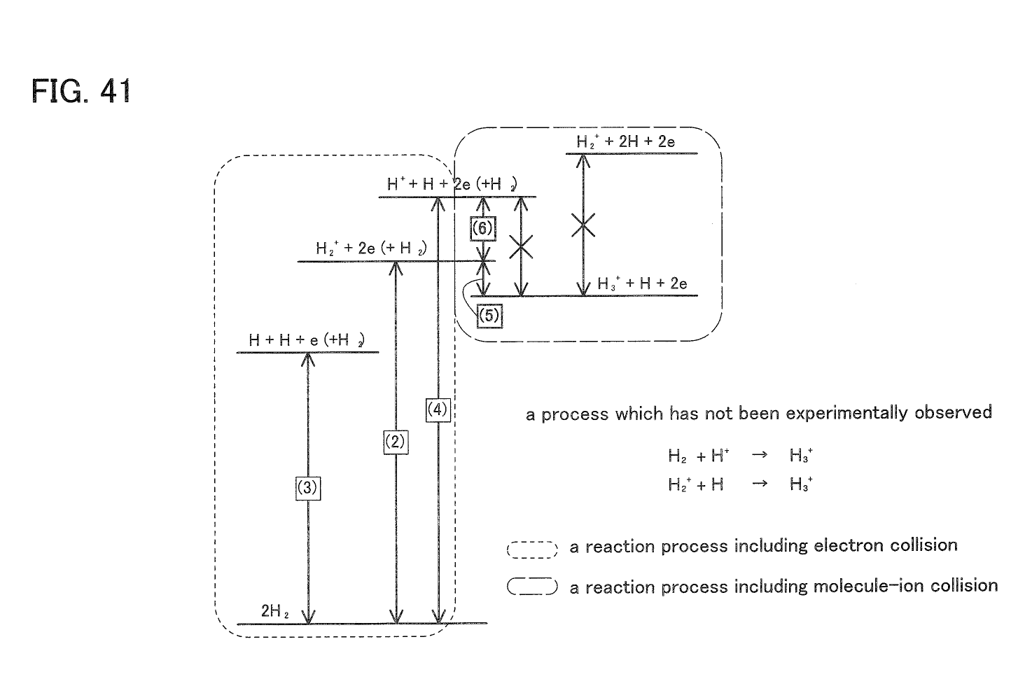

FIG. 41 is an energy diagram which schematically shows some of the above reactions. Note that the energy diagram shown in FIG. 41 is merely a schematic diagram and does not depict the relationships of energies of the reactions exactly.

### (H₃⁺ Ion Formation Process)

As shown above, H₃⁺ ions are mainly produced through the reaction process that is represented by the reaction equation (5). On the other hand, as a reaction that competes with the reaction equation (5), there is the reaction process represented by the reaction equation (6). For the number of H₃⁺ ions to increase, at the least, it is necessary that the reaction of the reaction equation (5) occur more often than the reaction of the reaction equation (6) (note that, because there are also other reactions, (7), (8), and (9), through which the number of H₃⁺ ions is decreased, the number of H₃⁺ ions is not necessarily increased even if the reaction of the reaction equation (5) occurs more often than the reaction of the reaction equation (6)). In contrast, when the reaction of the reaction equation (5) occurs less often than the reaction of the reaction equation (6), the proportion of H₃⁺ ions in a plasma is decreased.

The amount of increase in the product on the right-hand side (rightmost side) of each reaction equation given above depends on the density of a source material on the left-hand side (leftmost side) of the reaction equation, the rate coefficient of the reaction, and the like. Here, it is experimentally confirmed that, when the kinetic energy of an H₂⁺ ion is lower than about 11 eV, the reaction of the reaction equation (5) is the main reaction (that is, the rate coefficient of the reaction equation (5) is sufficiently higher than the rate coefficient of the reaction equation (6)) and that, when the kinetic energy of an H₂⁺ ion is higher than about 11 eV, the reaction of the reaction equation (6) is the main reaction.

A force is exerted on a charged particle by an electric field, and the charged particle gains kinetic energy. The kinetic energy corresponds to the amount of decrease in potential energy due to an electric field. For example, the amount of kinetic energy a given charged particle gains before colliding with another particle is equal to the difference between a potential energy at a potential before the charged particle moves and a potential energy at a potential before the collision. That is, in a situation where a charged particle can travel a long distance in an electric field without colliding with another particle, the kinetic energy (or the average thereof) of the charged particle tends to be higher than that in a situation where the charged particle cannot. Such a tendency toward an increase in kinetic energy of a charged particle can be shown in a situation where the mean free path of a particle is long, that is, in a situation where pressure is low.

Even in a situation where the mean free path is short, the kinetic energy of a charged particle is high if the charged particle can gain a high amount of kinetic energy while traveling through the path. That is, it can be said that, even in the situation where the mean free path is short, the kinetic energy of a charged particle is high if the potential difference is large.

This is applied to H₂⁺ ions. Assuming that an electric field is present as in a plasma generation chamber, the kinetic energy of an H₂⁺ ion is high in a situation where the pressure inside the chamber is low and the kinetic energy of an H₂⁺ ion is low in a situation where the pressure inside the chamber is high. That is, because the reaction of the reaction equation (6) is the main reaction in the situation where the pressure inside the chamber is low, the number of H₃⁺ ions tends to be decreased, and because the reaction of the reaction equation (5) is the main reaction in the situation where the pressure inside the chamber is high, the number of H₃⁺ ions tends to be increased. In addition, in a situation where an electric field in a plasma generation region is high, that is, in a situation where the potential difference between given two points is large, the kinetic energy of an H₂⁺ ion is high, and in the opposite situation, the kinetic energy of an H₂⁺ ion is low. That is, because the reaction of the reaction equation (6) is the main reaction in the situation where the electric field is high, the number of H₃⁺ ions tends to be decreased, and because the reaction of the reaction equation (5) is the main reaction in a situation where the electric field is low, the number of H₃⁺ ions tends to be increased.

### (Differences Depending on Ion Source)

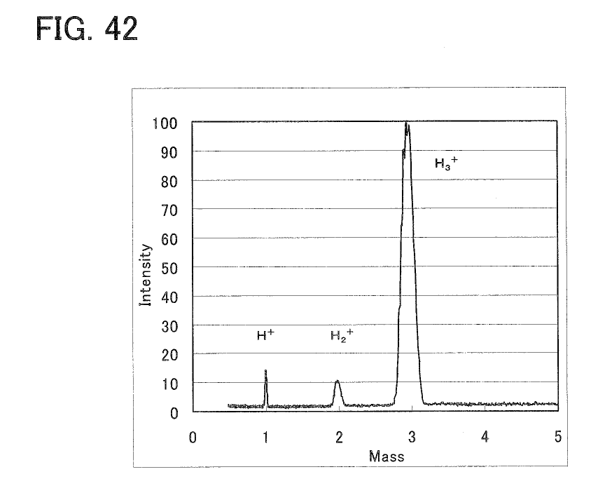

Here, an example, in which the proportions of hydrogen ion species (particularly, the proportion of H₃⁺ ions) are different, is described. FIG. 42 is a graph showing the results of mass spectrometry of ions that are generated from a 100% hydrogen gas (with the pressure of an ion source of 4.7×10⁻² Pa). Note that this mass spectrometry was performed by measurement of ions that were extracted from the ion source. The horizontal axis represents ion mass. In the spectrum, the mass 1 peak, the mass 2 peak, and the mass 3 peak correspond to H⁺ ions, H₂⁺ ions, and H₃⁺ ions, respectively. The vertical axis represents the intensity of the spectrum, which corresponds to the number of ions. In FIG. 42, the number of ions with different masses is expressed as a relative proportion where the number of ions with a mass of 3 is defined as 100. It can be seen from FIG. 42 that the ratio between ion species that are generated from the ion source, i.e., the ratio between H⁺ ions, H₂⁺ ions, and H₃⁺ ions, is about 1:1:8. Note that ions at such a ratio can also be generated by an ion doping apparatus which has a plasma source portion (ion source) that generates a plasma, an extraction electrode that extracts an ion beam from the plasma, and the like.

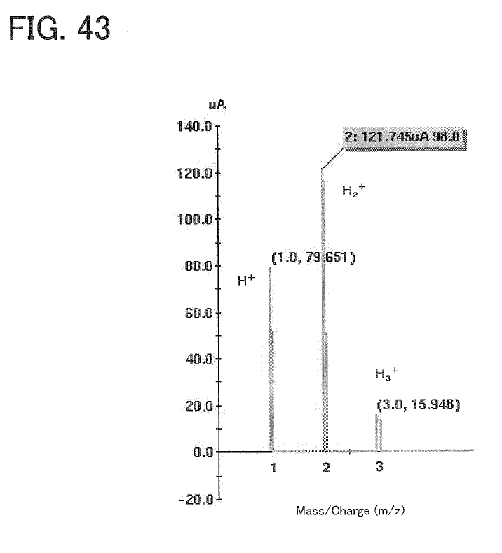

FIG. 43 is a graph showing the results of mass spectrometry of ions that are generated from PH₃ when an ion source different from that for the case of FIG. 42 is used and the pressure of the ion source is about 3×10⁻³ Pa. The results of this mass spectrometry focus on the hydrogen ion species. In addition, the mass spectrometry was performed by measurement of ions that were extracted from the ion source. As in FIG. 42, the horizontal axis represents ion mass, and the mass 1 peak, the mass 2 peak, and the mass 3 peak correspond to H⁺ ions, H₂⁺ ions, and H₃⁺ ions, respectively. The vertical axis represents the intensity of a spectrum corresponding to the number of ions. It can be seen from FIG. 43 that the ratio between ion species in a plasma, i.e., the ratio between H⁺ ions, H₂⁺ ions, and H₃⁺ ions, is about 37:56:7. Note that, although FIG. 43 shows the data obtained when the source gas is PH₃, the ratio between the hydrogen ion species is about the same when a 100% hydrogen gas is used as a source gas, as well.

In the case of the ion source from which the data shown in FIG. 43 is obtained, H₃⁺ ions, of H⁺ ions, H₂⁺ ions, and H₃⁺ ions, is generated at a proportion of only about 7%. On the other hand, in the case of the ion source from which the data shown in FIG. 42 is obtained, the proportion of H₃⁺ ions can be up to 50% or higher (under the aforementioned conditions, about 80%). This is thought to result from the pressure and electric field inside a chamber, which is clearly shown in the above consideration.

### (H₃⁺ Ion Irradiation Mechanism)

When a plasma that contains a plurality of kinds of ions as shown in FIG. 42 is generated and a single crystal semiconductor substrate is irradiated with the generated plurality of kinds of ions without any mass separation being performed, the surface of the single crystal semiconductor substrate is irradiated with each of H⁺ ions, H₂⁺ ions, and H₃⁺ ions. In order to reproduce the mechanism, from the irradiation with ions to the formation of an ion-introduced region, the following five types of models are considered.

Model 1, where the hydrogen ion species used for irradiation is H⁺ ions, which are still H⁺ ions (or H) after the irradiation.

Model 2, where the hydrogen ion species used for irradiation is H₂⁺ ions, which are still H₂⁺ ions (or H₂) after the irradiation.

Model 3, where the hydrogen ion species used for irradiation is H₂⁺ ions, which each split into two H atoms (or H⁺ ions) after the irradiation.

Model 4, where the hydrogen ion species used for irradiation is H₃⁺ ions, which are still H₃⁺ ions (or H₃) after the irradiation.

Model 5, where the hydrogen ion species used for irradiation is H₃⁺ ions, which each split into three H atoms (or H⁺ ions) after the irradiation.

(Comparison of Simulation Results with Measured Values)

Based on the above models, the irradiation of a silicon substrate with hydrogen ion species was simulated. As simulation software, SRIM, the Stopping and Range of Ions in Matter (an improved version of TRIM, the Transport of Ions in Matter, which is simulation software for ion introduction processes by a Monte Carlo method) was used. Note that, for the calculation, a calculation based on Model 2 was performed with the H₂⁺ ions replaced by H⁺ ions that each have twice the mass. In addition, a calculation based on Model 4 was performed with the H₃⁺ ions replaced by H⁺ ions that each have three times the mass. Furthermore, a calculation based on Model 3 was performed with the H₂⁺ ions replaced by H⁺ ions that each has half the kinetic energy, and a calculation based on Model 5, with the H₃⁺ ions replaced by H⁺ ions that each have one-third the kinetic energy.

Note that SRIM is software intended for amorphous structures, but SRIM can be applied to cases where irradiation with the hydrogen ion species is performed with high energy at a high dose. This is because the crystal structure of a silicon substrate changes into a non-single-crystal structure due to the collision of the hydrogen ion species with Si atoms.

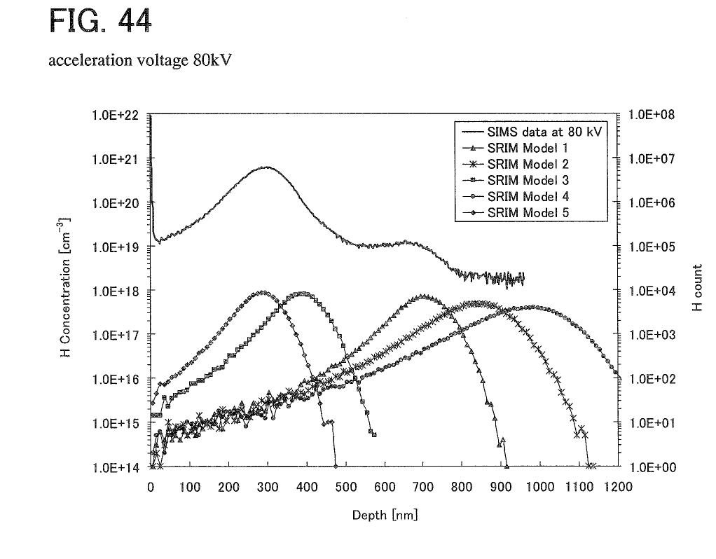

FIG. 44 shows the calculation results obtained when irradiation with the hydrogen ion species (irradiation with 100,000 atoms for H) is performed using Models 1 to 5. FIG. 44 also shows the hydrogen concentration (secondary ion mass spectrometry (SIMS) data) in a silicon substrate irradiated with the hydrogen ion species of FIG. 42. The results of calculations performed using Models 1 to 5 are expressed on the vertical axis (right axis) as the number of hydrogen atoms, and the SIMS data is expressed on the vertical axis (left axis) as the concentration of hydrogen atoms. The horizontal axis represents depth from the surface of a silicon substrate. If the SIMS data, which is measured values, is compared with the calculation results, Models 2 and 4 obviously do not match the peaks of the SIMS data and a peak corresponding to Model 3 cannot be observed in the SIMS data. This shows that the contribution of each of Models 2 to 4 is relatively small. Considering that the kinetic energy of ions is on the order of kiloelectron volts whereas the H—H bond energy is only about several electron volts, it is thought that the contribution of each of Models 2 and 4 is small because H₂⁺ ions and H₃⁺ ions mostly split into H⁺ ions or H ions by colliding with Si atoms.

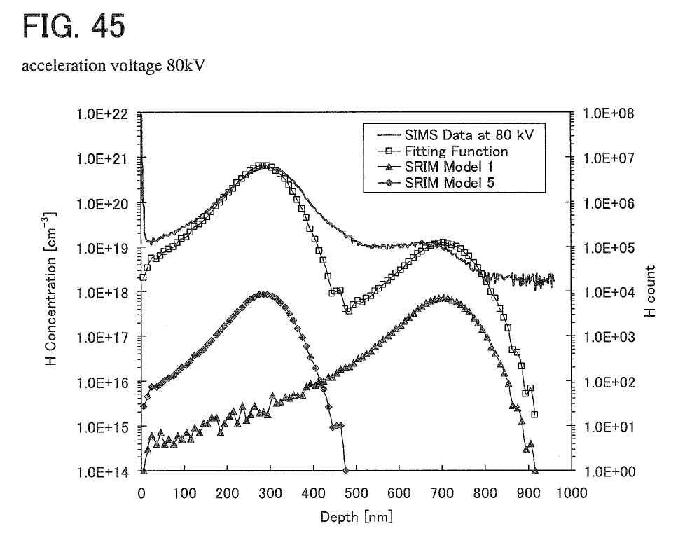

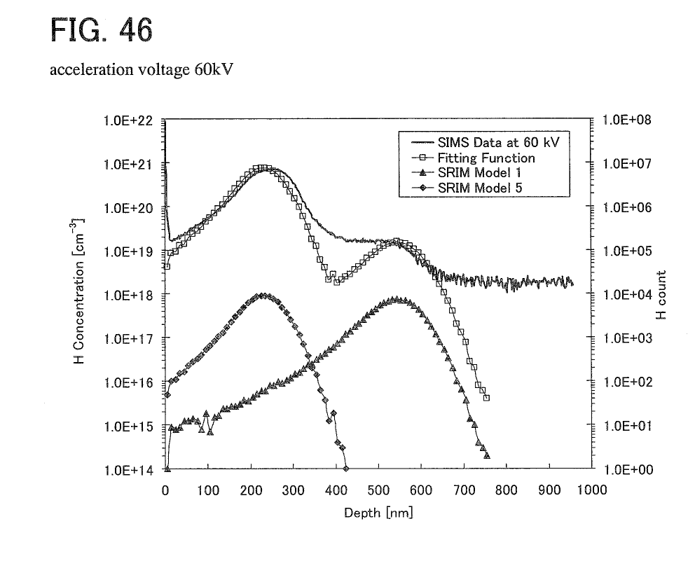

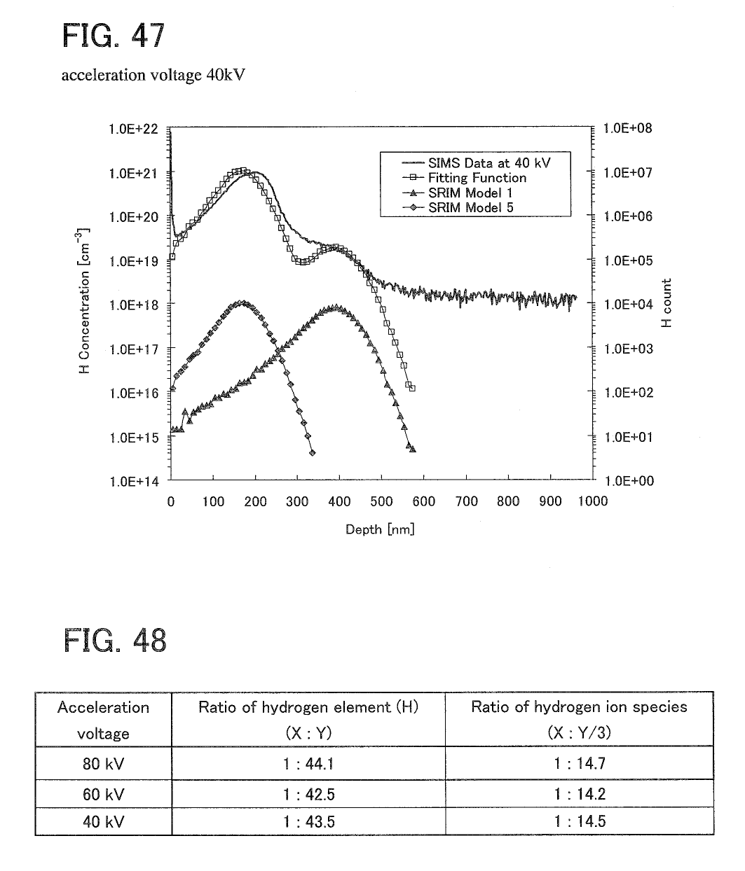

As a result of the consideration above, Models 2 to 4 will not be considered hereinafter. FIGS. 45 to 47 each show the calculation results obtained when irradiation with the hydrogen ion species (irradiation with 100,000 atoms for H) is performed using Models 1 and 5. FIGS. 25 to 27 also each show the hydrogen concentration (SIMS data) in a silicon substrate irradiated with the hydrogen ion species of FIG. 42, and the simulation results fitted to the SIMS data (hereinafter referred to as a fitting function). Here, FIG. 45 shows the case where the accelerating voltage is 80 kV; FIG. 46, the case where the accelerating voltage is 60 kV; and FIG. 47, the case where the accelerating voltage is 40 kV. Note that the results of calculations performed using Models 1 and 5 are expressed on the vertical axis (right axis) as the number of hydrogen atoms, and the SIMS data and the fitting function are expressed on the vertical axis (left axis) as the density of hydrogen atoms. The horizontal axis represents depth from the surface of a silicon substrate.

The fitting function is obtained using the calculation formula given below, in consideration of Models 1 and 5. Note that, in the calculation formula, X and Y represent fitting parameters and V represents volume.

(Fitting Function)=X/V×(Data of Model 1)+Y/V×(Data of Model 5)

In consideration of the ratio between hydrogen ion species used for actual irradiation (H⁺ ions:H₂⁺ ions:H₃⁺ ions is about 1:1:8), the contribution of H₂⁺ ions (i.e., Model 3) should also be considered; however, Model 3 is excluded from the consideration given here for the following reasons:

Because the amount of hydrogen introduced through the irradiation process represented by Model 3 is lower than that introduced through the irradiation process of Model 5, there is no significant influence even if Model 3 is excluded from the consideration (no peak appears in the SIMS data either).

Model 3, the peak position of which is close to that of Model 5, is likely to be obscured by channeling (movement of atoms due to crystal lattice structure) that occurs in Model 5. That is, it is difficult to estimate fitting parameters for Model 3. This is because this simulation assumes amorphous silicon and the influence due to crystallinity is not considered.

FIG. 48 lists the aforementioned fitting parameters. At any of the accelerating voltages, the ratio of the amount of H introduced according to Model 1 to that introduced according to Model 5 is about 1:42 to 1:45 (the amount of H in Model 5, when the amount of H in Model 1 is defined as 1, is about 42 to 45), and the ratio of the number of hydrogen ions used for irradiation, H⁺ ions (Model 1) to that of H₃⁺ ions (Model 5) is about 1:14 to 1:15 (the number of H₃⁺ ions in Model 5, when the number of H⁺ ions in Model 1 is defined as 1, is about 14 to 15). Considering that Model 3 is not considered and the calculation assumes amorphous silicon, it can be said that values close to that of the ratio between hydrogen ion species used for actual irradiation (H⁺ ions:H₂⁺ ions:H₃⁺ ions is about 1:1:8) is obtained.

### (Effects of Use of H₃⁺Ions)

A plurality of benefits resulting from H₃⁺ can be enjoyed by irradiation of a substrate with hydrogen ion species with a higher proportion of H₃⁺ ions as shown in FIG. 42. For example, because H₃⁺ ions each split into H⁺, H, or the like to be introduced into a substrate, ion introduction efficiency can be improved compared with the case of irradiation mainly with H⁺ ions or H₂⁺ ions. This leads to an improvement in SOI substrate production efficiency. In addition, because the kinetic energy of an H⁺ ion or H after an H₃⁺ ion splits similarly tends to be low, H₃⁺ ions are suitable for manufacture of thin semiconductor layers.

Note that, an ion doping apparatus that is capable of irradiation with the hydrogen ion species as shown in FIG. 42 is preferably used in order to efficiently perform irradiation with H₃⁺ ions. This is because ion doping apparatuses are inexpensive and excellent for use in large-area treatment and by irradiation with H₃⁺ ions by use of such an ion doping apparatus, significant effects such as an increase in area, a reduction in costs, and an improvement in production efficiency can be obtained. On the other hand, if first priority is given to irradiation with H₃⁺ ions, there is no need to interpret the present invention as being limited to the use of an ion irradiation apparatus.

This application is based on Japanese Patent Application serial no. 2007-285559 filed with Japan Patent Office on Nov. 1, 2007, the entire contents of which are hereby incorporated by reference.

What is claimed is:

1. A method for manufacturing a semiconductor substrate including a supporting substrate and a single crystal semiconductor layer over the supporting substrate, comprising the steps of:
forming a damaged layer in a single crystal semiconductor substrate at a predetermined depth by adding ions to the single crystal semiconductor substrate;
forming a buffer layer over the single crystal semiconductor substrate;
closely attaching the single crystal semiconductor substrate and the supporting substrate with the buffer layer interposed therebetween;
separating a portion of the single crystal semiconductor substrate from the supporting substrate by using the damaged layer as a cleavage plane by heating the single crystal semiconductor substrate; and
irradiating the single crystal semiconductor layer with a laser beam from a single crystal semiconductor substrate side to melt a region in a depth direction from a surface of the single crystal semiconductor layer which is irradiated with the laser beam and to recrystallize the single crystal semiconductor layer.

2. The method according to claim 1, wherein a hydrogen gas is used as a source gas for formation of the damaged layer;
wherein the damaged layer is formed by exciting the hydrogen gas to generate a plasma including H₃⁺, accelerating ions included in the plasma, and adding the ions to the single crystal semiconductor substrate.

3. The method according to claim 1, wherein the supporting substrate has a strain point of from 650° C. to 690° C.

4. The method according to claim 1, wherein the supporting substrate is a glass substrate.

5. The method according to claim 1, wherein a cross-sectional shape of the laser beam is a linear shape, a square shape or a rectangular shape.

6. A semiconductor device including a thin film transistor formed using a semiconductor substrate manufactured by the method according to claim 1.

7. An electronic device including the semiconductor device according to claim 6.

8. A method for manufacturing a semiconductor substrate including a supporting substrate and a single crystal semiconductor layer over the supporting substrate, comprising the steps of:
forming a damaged layer in a single crystal semiconductor substrate at a predetermined depth by adding ions to the single crystal semiconductor substrate;
forming a buffer layer over the single crystal semiconductor substrate;
closely attaching the single crystal semiconductor substrate and the supporting substrate with the buffer layer interposed therebetween;
separating a portion of the single crystal semiconductor substrate from the supporting substrate by using the damaged layer as a cleavage plane by heating the single crystal semiconductor substrate; and
irradiating, in an inert gas atmosphere, the single crystal semiconductor layer with a laser beam from a single crystal semiconductor substrate side to melt a region in a depth direction from a surface of the single crystal semiconductor layer which is irradiated with the laser beam and to recrystallize the single crystal semiconductor layer.

9. The method according to claim 8, wherein a hydrogen gas is used as a source gas for formation of the damaged layer;
wherein the damaged layer is formed by exciting the hydrogen gas to generate a plasma including H₃⁺, accelerating ions included in the plasma, and adding the ions to the single crystal semiconductor substrate.

10. The method according to claim 8, wherein the supporting substrate has a strain point of from 650° C. to 690° C.

11. The method according to claim 8, wherein the supporting substrate is a glass substrate.

12. The method according to claim 8, wherein a cross-sectional shape of the laser beam is a linear shape, a square shape or a rectangular shape.

13. A semiconductor device including a thin film transistor formed using a semiconductor substrate manufactured by the method according to claim 8.

14. An electronic device including the semiconductor device according to claim 13.

15. A method for manufacturing a semiconductor substrate including a supporting substrate and a single crystal semiconductor layer over the supporting substrate, comprising the steps of:
forming an insulating layer in contact with the supporting substrate;
forming a damaged layer in a single crystal semiconductor substrate at a predetermined depth by adding ions to the single crystal semiconductor substrate;
forming a buffer layer in contact with the insulating layer;
closely attaching the single crystal semiconductor substrate and the supporting substrate with the buffer layer interposed therebetween;
separating a portion of the single crystal semiconductor substrate from the supporting substrate by using the damaged layer as a cleavage plane by heating the single crystal semiconductor substrate; and
irradiating, in an inert gas atmosphere, the single crystal semiconductor layer with a laser beam from a single crystal semiconductor substrate side to melt a region in a depth direction from a surface of the single crystal semiconductor layer which is irradiated with the laser beam and to recrystallize the single crystal semiconductor layer.

16. The method according to claim 15, wherein a hydrogen gas is used as a source gas for formation of the damaged layer;
wherein the damaged layer is formed by exciting the hydrogen gas to generate a plasma including H₃⁺, accelerating ions included in the plasma, and adding the ions to the single crystal semiconductor substrate.

17. The method according to claim 15, wherein the supporting substrate has a strain point of from 650° C. to 690° C.

18. The method according to claim 15, wherein the supporting substrate is a glass substrate.

19. The method according to claim 15, wherein a cross-sectional shape of the laser beam is a linear shape, a square shape or a rectangular shape.

20. The method according to claim 15, wherein the insulating layer comprises first and second insulating films.

21. A semiconductor device including a thin film transistor formed using a semiconductor substrate manufactured by the method according to claim 15.

22. An electronic device including the semiconductor device according to claim 21.
